(19) United States
(12) Patent Application Publication
(10) Pub. No.: US 2008/0292989 A1
(43) Pub. Date: Nov. 27, 2008

(54) POSITIVE WORKING PHOTOSENSITIVE COMPOSITION AND PATTERN FORMING METHOD USING THE SAME

(75) Inventor: Naoyuki NISHIKAWA, Shizuoka (JP)

Correspondence Address: SUGHRUE-265550, 2100 PENNSYLVANIA AVE. NW, WASHINGTON, DC, 20037-3213, US

(73) Assignee: FUJIFILM CORPORATION, Tokyo (JP)

(21) Appl. No.: 12/036,519

(22) Filed: Feb. 25, 2008

(30) Foreign Application Priority Data
Feb. 23, 2007 (JP) 2007-043473

(51) Int. Cl. G03F 7/004

(52) U.S. Cl. 430/287.1; 430/325

(57) ABSTRACT

A positive working photosensitive composition comprises: (A) a resin having a heterocyclic group containing plural sulfur atoms in a cyclic structure of the heterocyclic group, the resin decomposing by action of an acid to increase its solubility in an alkaline developer; and (B) a compound capable of generating an acid upon irradiation with actinic rays or radiation.

### BACKGROUND OF THE INVENTION

1. Field of the Invention

The present invention relates to a positive working photosensitive composition which is used in a manufacturing step of a semiconductor device such as IC, in the manufacture of a circuit board such as a liquid crystal and a thermal head and other fabrication steps and to a pattern forming method using the same. In more detail, the invention relates to a positive working photosensitive composition which is suitable in the case of using an exposure light source such as ultraviolet light of not longer than 250 nm and an electron beam or the like as an irradiation source and to a pattern forming method.

2. Description of the Related Art

A chemical amplification system photosensitive composition is a pattern forming material capable of generating an acid in an exposed area upon irradiation with radiation such as far ultraviolet light and changes solubility in a developing solution in an irradiated area and a non-irradiated area with actinic rays due to a reaction using this acid as a catalyst, thereby forming a pattern on a substrate.

In the case where a KrF excimer laser is used as an exposure light source, since a resin having small absorption chiefly in a region of 248 nm and having poly(hydroxystyrene) as a basic skeleton is used as the major component, a satisfactory pattern with high sensitivity and high resolution is formed, and a satisfactory system is revealed as compared with a related-art naphthoquinone/novolak resin system.

On the other hand, in the case where a light source having a shorter wavelength, for example, an ArF excimer laser (193 nm) is used as an exposure light source, a resist using an aliphatic group-containing (meth)acrylic ester based resin having small absorption at 193 nm and a resist having an alicyclic aliphatic group introduced thereinto for the purpose of imparting anti-etching properties are proposed (see, for example, JP-A-2000-122294, JP-A-2006-104289, JP-A-8-305023 and JP-A-10-115925). However, even these disclosed compositions are still insufficient in the formation of a fine pattern of especially not more than 100 nm, and in particular, an improvement in the line edge roughness performance of a line pattern has been demanded. Here, the “line edge roughness” refers to a shape in which an edge at an interface between a line pattern of a resist and a substrate fluctuates irregularly in a direction vertical to the line direction due to characteristics of the resist. When this pattern is observed from the upper side, the edge is seen unevenly (from about ±several nm to several tens nm). Since this unevenness is transferred onto the substrate by the etching step, when the unevenness is large, failure in electric characteristics is caused, resulting in a reduction of the yield.

On the other hand, as a measure for realizing a finer pattern in the future, a High-NA liquid immersion exposure system for filling a medium with high refractive index between a lens of an exposure device and a resist film and achieving the exposure is thought, and the realization of a resist material having a higher refractive index than that of related-art resist films is being demanded (see, for example, 3rd International Symposium on Immersion Lithography Proceedings, RP-7).

### SUMMARY OF THE INVENTION

Problems that the invention is to solve are to provide a positive working photosensitive composition having improved line edge roughness in the formation of a fine pattern of not more than 100 nm and a pattern forming method using the same. Also, since a resist film with high refractive index can be formed, the invention is to provide a positive working photosensitive composition which is especially suitable for the liquid immersion exposure and a pattern forming method using the same.

The invention is as follows.

(1) A positive working photosensitive composition comprising:

(A) a resin having a heterocyclic group containing plural sulfur atoms in a cyclic structure of the heterocyclic group, the resin decomposing by action of an acid to increase its solubility in an alkaline developer; and

(B) a compound capable of generating an acid upon irradiation with actinic rays or radiation.

(2) The positive working photosensitive composition as set forth in (1), wherein the heterocyclic group is a polycyclic heterocyclic group.

(3) The positive working photosensitive composition as set forth in (2), wherein the resin (A) has at least one repeating unit selected from a repeating unit represented by the following general formula (I) and a repeating unit represented by the following general formula (II).

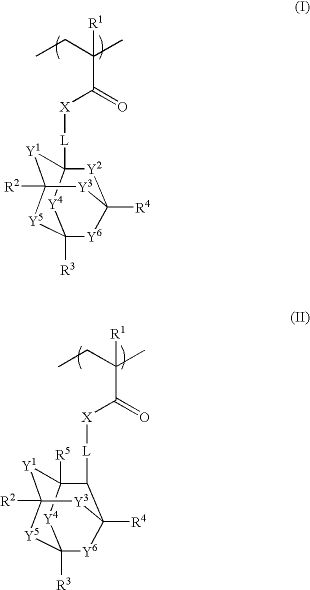

In the general formulae (I) and (II),

X represents an oxygen atom or a sulfur atom,

L represents a single bond or a divalent connecting group,

Y¹ to Y⁶ each independently represents —CH₂—, —CH(R⁶)—, —C(R⁶)₂—, an oxygen atom or a sulfur atom, provided that at least two of Y¹ to Y⁶ represent a sulfur atom,

R¹ represents a hydrogen atom, an alkyl group or a halogen atom,

R² to R⁵ each independently represents a hydrogen atom or an alkyl group, and

R⁶ represents an alkyl group.

(4) A pattern forming method comprising: forming a photosensitive film by the positive working photosensitive composition as set forth in any one of (1) to (3); and exposing and developing the photosensitive film.

### DETAILED DESCRIPTION OF THE INVENTION

Best modes for carrying out the invention are hereunder described.

In this specification, with respect to the expressions of a group (atomic group), any expression not explicitly showing “substituted” or “unsubstituted” includes both one not having a substituent and one having a substituent. For example, the term “alkyl group” includes not only an alkyl group not having a substituent (unsubstituted alkyl group) but an alkyl group having a substituent (substituted alkyl group).

(A) Resin having a heterocyclic group containing plural sulfur atoms in a cyclic structure thereof, which decomposes by the action of an acid to increase its solubility in an alkaline developer:

The positive working photosensitive composition of the invention contains a resin having a heterocyclic group containing plural sulfur atoms in a cyclic structure thereof, which decomposes by the action of an acid to increase its solubility in an alkaline developer (this resin being also referred to as “component (A)”).

Though the heterocyclic group containing plural sulfur atoms in a cyclic structure thereof may be contained in any of the principal chain, side chain or terminal end of a high-molecular weight compound constituting the resin, it is preferably contained in the side chain. Examples of the heterocyclic group containing plural sulfur atoms in a cyclic structure thereof include a monocyclic heterocyclic group and a polycyclic heterocyclic group, with a polycyclic heterocyclic group being preferable. The heterocyclic group may have a substituent on a ring thereof. When the heterocyclic group has a substituent on a ring thereof, preferred examples of the substituent include an alkyl group having from 1 to 6 carbon atoms, a hydroxyl group, a thiol group, an amide group, an alkoxy group having from 1 to 6 carbon atoms and an alkylthio group having from 1 to 6 carbon atoms.

Preferred examples of the heterocyclic group containing plural sulfur atoms in a monocyclic cyclic structure thereof include a 5-membered to 20-membered ring heterocyclic group containing plural sulfur atoms. The number of sulfur atoms contained in the monocyclic cyclic structure is preferably from 2 to 10, and more preferably from 2 to 6. Specific examples of the heterocyclic group containing plural sulfur atoms in a monocyclic cyclic structure thereof which is preferably used in the invention are given below, but it should not be construed that the invention is limited thereto.

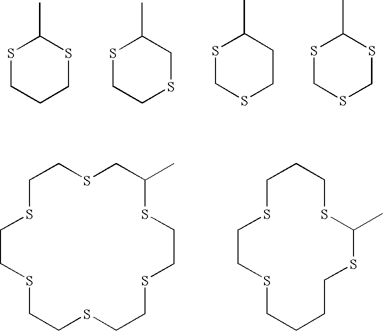

Each of the foregoing heterocyclic groups may have a substituent on a ring thereof. Also, each of the heterocyclic groups may form a ring containing a hetero atom other than a sulfur atom, for example, an oxygen atom and a nitrogen atom.

Preferred examples of the heterocyclic group containing plural sulfur atoms in a polycyclic cyclic structure thereof include a heterocyclic group containing plural sulfur atoms in a polycyclic cyclic structure thereof formed by connection of 5-membered to 6-membered rings each other. The number of rings is preferably from 2 to 4, and more preferably from 2 to 3. The number of sulfur atoms contained in the polycyclic cyclic structure is preferably from 2 to 10, and more preferably from 2 to 6. Specific examples of the heterocyclic group containing plural sulfur atoms in the polycyclic cyclic structure thereof which is preferably used in the invention are given below, but it should not be construed that the invention is limited thereto.

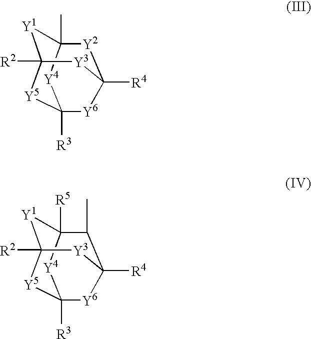

In the general formulae (III) and (IV),

Y¹ to Y⁶ each independently represents —CH₂—, —CH(R⁶)—, —C(R⁶)₂—, an oxygen atom or a sulfur atom, provided that at least two of Y¹ to Y⁶ represent a sulfur atom,

R² to R⁵ each independently represents a hydrogen atom or an alkyl group, and

R⁶ represents an alkyl group.

In the general formulae (III) and (IV),

Y¹ to Y⁶ are each preferably —CH₂—, —CH(R⁶)—, —C(R⁶)₂— or a sulfur atom.

Also, two, three or four of Y¹ to Y⁶ are preferably a sulfur atom.

R² to R⁵ are each preferably a hydrogen atom or an alkyl group having from 1 to 6 carbon atoms, and more preferably a hydrogen atom or a methyl group.

R⁶ is preferably an alkyl group having from 1 to 6 carbon atoms, and more preferably a methyl group.

It is preferable that the resin as the component (A) has at least one repeating unit selected from a repeating unit represented by the following general formula (I) and a repeating unit represented by the following general formula (II).

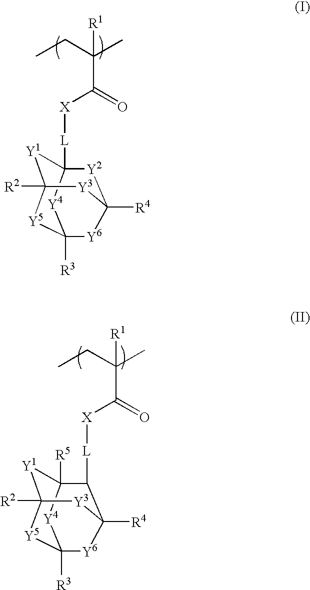

In the general formulae (I) and (II),

X represents an oxygen atom or a sulfur atom,

L represents a single bond or a divalent connecting group,

R¹ represents a hydrogen atom, an alkyl group or a halogen atom, and

Y¹ to Y⁶ and R² to R⁵ are synonymous with Y¹ to Y⁶ and R² to R⁵ in the general formulae (III) and (IV).

In the general formulae (I) and (II), examples of the divalent connecting group represented by L include an alkylene group having from 1 to 20 carbon atoms and a divalent connecting group in which an alkylene group having from 1 to 20 carbon atoms and at least one group selected from an oxy group, a thio group and a carbonyl group are bound each other.

R¹ is preferably a hydrogen atom, an alkyl group having from 1 to 6 carbon atoms or a halogen atom, and more preferably a hydrogen atom or a methyl group.

Each of the foregoing heterocyclic groups may have a substituent on a ring thereof. Also, each of the heterocyclic groups may form a ring containing a hetero atom other than a sulfur atom, for example, an oxygen atom and a nitrogen atom.

It is preferable that the resin as the component (A) has a repeating unit having a heterocyclic group containing plural sulfur atoms in a cyclic structure thereof.

The repeating unit having a heterocyclic group containing plural sulfur atoms in a cyclic structure thereof can be, for example, formed by using a polymerizable compound as described below.

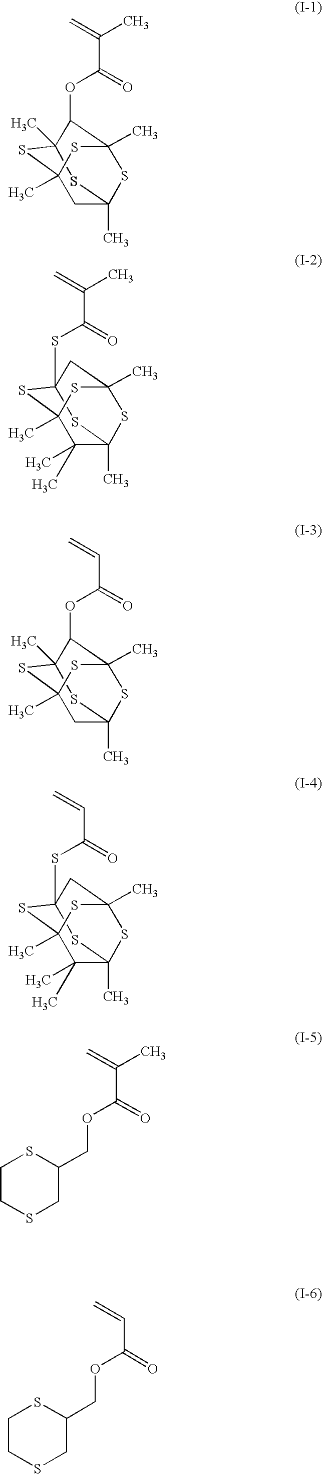

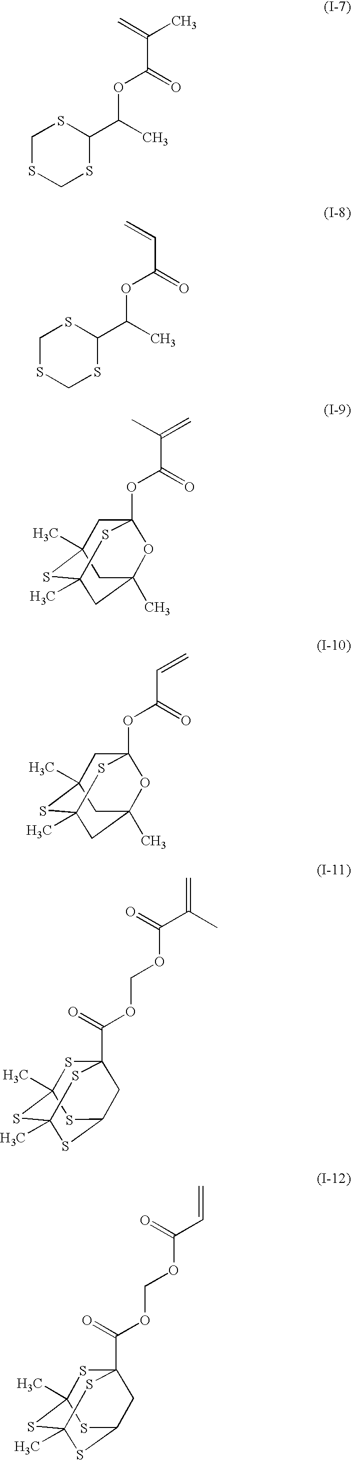

It is preferable that the resin as the component (A) has a group which decomposes by the action of an acid to become an alkali-soluble group (hereinafter also referred to as “acid-decomposable group”) in either one or both of the principal chain and the side chain of the resin. Above all, a resin having an acid-decomposable group in a side chain thereof is more preferable.

The acid-decomposable group is preferably a group resulting from substitution of a hydrogen atom of a —COOH group or an —OH group with a group capable of being split off by an acid.

Examples of the group capable of being split off by an acid include —C(R₃₆)(R₃₇)(R₃₈), —C(R₃₆)(R₃₇)(OR₃₉) and —C(R₀₁)(R₀₂)(OR₃₉).

In the formulae, R₃₆ to R₃₉ each independently represents an alkyl group, a cycloalkyl group, an aryl group, an aralkyl group or an alkenyl group. R₃₆ and R₃₇ may be taken together to form a ring.

R₀₁ to R₀₂ each independently represents a hydrogen atom, an alkyl group, a cycloalkyl group, an aryl group, an aralkyl group or an alkenyl group.

It is preferable that the resin as the component (A) is a resin having at least one member selected from the group consisting of a repeating unit having a partial structure containing an alicyclic hydrocarbon represented by any of the following general formulae (pI) to (pV) and a repeating unit represented by the following general formula (II-AB).

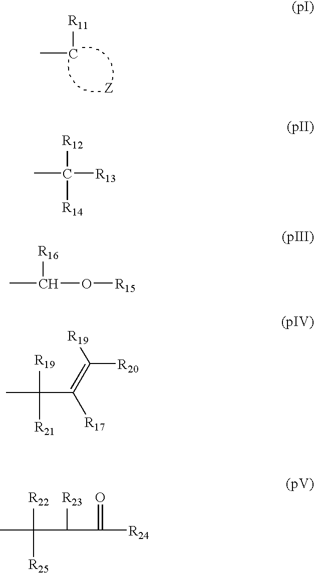

In the general formulae (pI) to (pV),

R₁₁ represents a methyl group, an ethyl group, an n-propyl group, an isopropyl group, an n-butyl group, an isobutyl group or a sec-butyl group; and Z represents an atomic group necessary for forming a cycloalkyl group together with a carbon atom,

R₁₂ to R₁₆ each independently represents a linear or branched alkyl group or a cycloalkyl group, provided that at least one of R₁₂ to R₁₄ or either R₁₅ or R₁₆ represents a cycloalkyl group,

R₁₇ to R₂₁ each independently represents a hydrogen atom, a linear or branched alkyl group or a cycloalkyl group, provided that at least one of R₁₇ to R₂₁ represents a cycloalkyl group; and that either R₁₉ or R₂₁ represents a linear or branched alkyl group or a cycloalkyl group, and

R₂₂ to R₂₅ each independently represents a hydrogen atom, a linear or branched alkyl group or a cycloalkyl group, provided that at least one of R₂₂ to R₂₅ represents a cycloalkyl group; and that R₂₃ and R₂₄ may be taken together to form a ring.

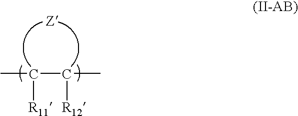

In the general formula (II-AB),

R₁₁′ and R₁₂′ each independently represents a hydrogen atom, a cyano group, a halogen atom or an alkyl group, and

Z′ represents an atomic group for forming an alicyclic structure together with the bound two carbon atoms (C—C).

The general formula (II-AB) is preferably the following general formula (II-AB1) or (II-AB2).

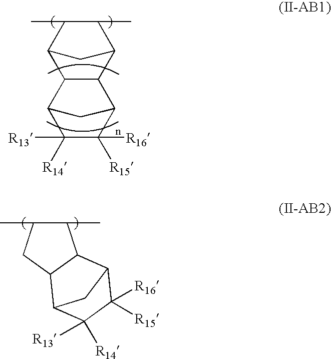

In the general formulae (II-AB1) and (II-AB2),

R₁₃′ to R₁₆′ each independently represents a hydrogen atom, a halogen atom, a cyano group, —COOH, —COOR₅, a group which decomposes by the action of an acid, —C(═O)—X-A′-R₁₇′, an alkyl group or a cycloalkyl group, provided that at least two of R₁₃′ to R₁₆′ may be taken together to form a ring,

R₅ represents an alkyl group, a cycloalkyl group or a group having a lactone structure,

X represents an oxygen atom, a sulfur atom, —NH—, —NHSO₂— or —NHSO₂NH—,

A′ represents a single bond or a divalent connecting group,

R₁₇′ represents —COOH, —COOR₅, —CN, a hydroxyl group, an alkoxy group, —CO—NH—R₆, —CO—NH—SO₂—R₆ or a group having a lactone structure,

R₆ represents an alkyl group or a cycloalkyl group, and

n represents 0 or 1.

In the general formulae (pI) to (pV), the alkyl group represented by R₁₂ to R₂₅ is preferably a linear or branched alkyl group having from 1 to 4 carbon atoms, for example, a methyl group, an ethyl group, an n-propyl group, an isopropyl group, an n-butyl group, an isobutyl group and a sec-butyl group.

In R₁₂ to R₂₅, the cycloalkyl group or the cycloalkyl group formed by Z and a carbon atom may be monocyclic or polycyclic. Specific examples thereof include groups having a monocyclo, bicyclo, tricyclo or tetracyclo structure having 5 or more carbon atoms. The carbon atom number is preferably from 6 to 30, and especially preferably from 7 to 25.

Preferred examples of the cycloalkyl group include an adamantyl group, a noradamantyl group, a decalin residue, a tricyclodecanyl group, a tetracyclododecanyl group, a norbornyl group, a cedrol group, a cyclopentyl group, a cyclohexyl group, a cycloheptyl group, a cyclooctyl group, a cyclodecanyl group and a cyclododecanyl group. Of these, an adamantyl group, a norbornyl group, a cyclohexyl group, a cyclopentyl group, a tetracyclododecanyl group and a tricyclodecanyl group are more preferable.

Each of these alkyl group and cycloalkyl group may further have a substituent. Examples of the substituent which each of these alkyl group and cycloalkyl group may further have include an alkyl group (having from 1 to 4 carbon atoms), a halogen atom, a hydroxyl group, an alkoxy group (having from 1 to 4 carbon atoms), a carboxyl group and an alkoxycarbonyl group (having from 2 to 6 carbon atoms). Examples of a substituent which each of the foregoing alkyl group, alkoxy group and alkoxycarbonyl group or the like may further have include a hydroxyl group, a halogen atom and an alkoxy group.

The structures represented by the general formulae (pI) to (pV) in the foregoing resin can be used for protecting the alkali-soluble group. Examples of the alkali-soluble group include various groups which are known in this technical field.

Specific examples thereof include structures resulting from substitution of a hydrogen atom of a carboxylic group, a sulfonic group, a phenol group or a thiol group with the structure represented by any of the general formulae (PI) to (pV). Of these, structures resulting from substitution of a hydrogen atom of a carboxylic group or a sulfonic group with the structure represented by any of the general formulae (pI) to (pV) are preferable.

The repeating unit having an alkali-soluble group protected by the structure represented by any of the general formulae (pI) to (pV) is preferably a repeating unit represented by the following general formula (pA).

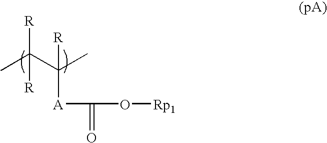

In the general formula (pA),

R represents a hydrogen atom, a halogen atom or a linear or branched alkyl group having from 1 to 4 carbon atoms. Plural Rs may be the same or different.

A represents a single group selected from the group consisting of a single bond, an alkylene group, an ether group, a thioether group, a carbonyl group, an ester group, an amide group, a sulfonamide group, a urethane group and a urea group or a combination of two or more of these groups. A is preferably a single bond.

Rp₁ represents a group represented by any of the general formulae (pI) to (pV).

The repeating unit represented by the general formula (pA) is most preferably a repeating unit derived from a 2-alkyl-2-adamantyl (meth)acrylate or a dialkyl-(1-adamantyl)methyl (meth)acrylate.

Specific examples of the repeating unit represented by the general formula (pA) are given below, but it should not be construed that the invention is limited thereto.

(In the formulae, Rx represents H, CH₃, CF₃ or CH₂OH; and Rxa and Rxb each represents an alkyl group having from 1 to 4 carbon atoms.)

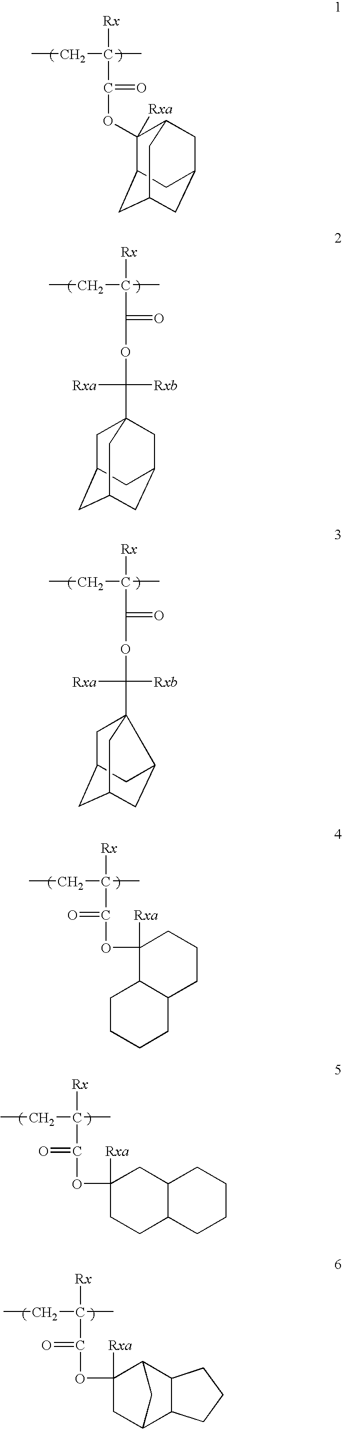

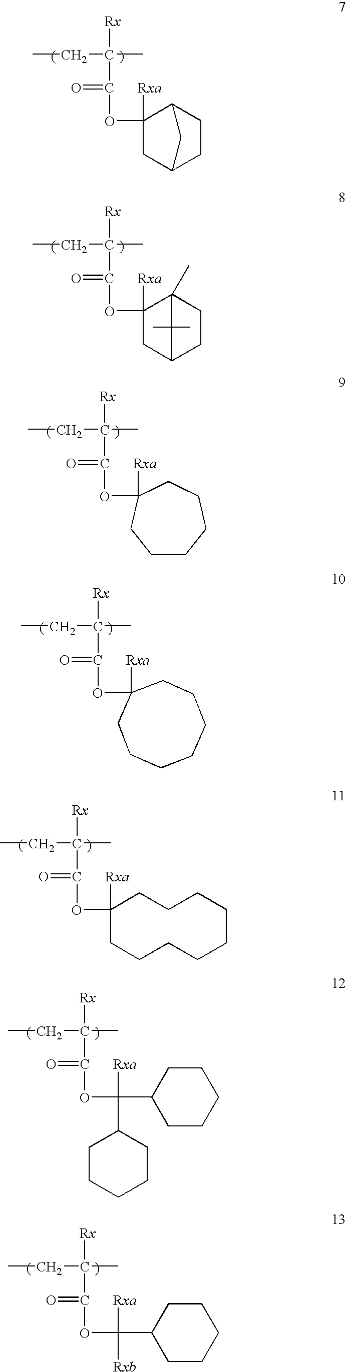

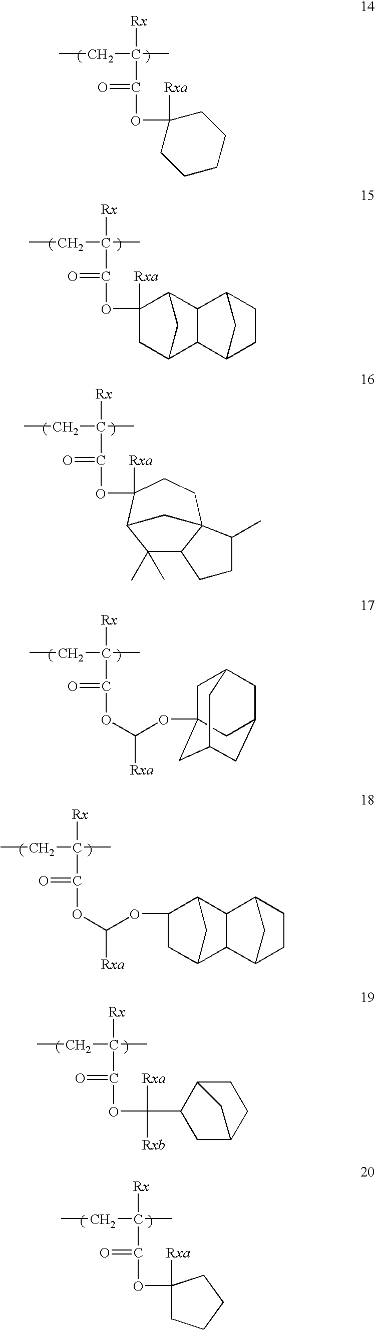

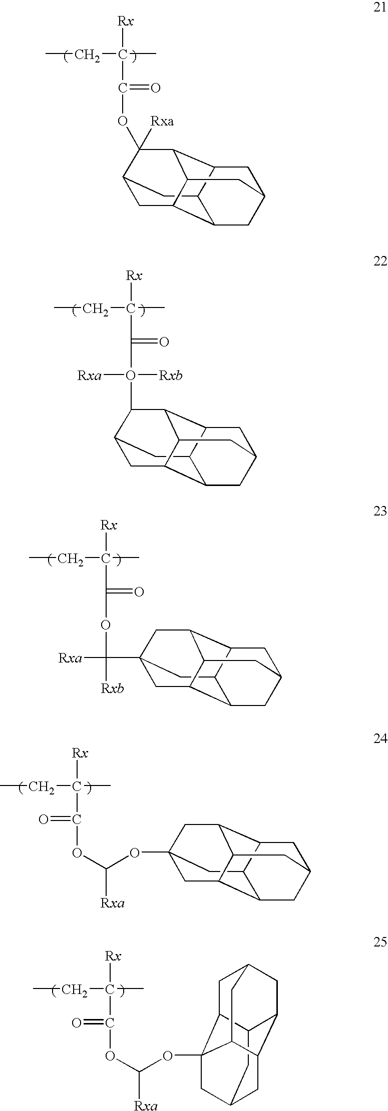

In the foregoing general formula (II-AB), examples of the halogen atom represented by R₁₁′ and R₁₂′ include a chlorine atom, a bromine atom, a fluorine atom and an iodine atom.

Examples of the alkyl group represented by R₁₁′ and R₁₂′ include a linear or branched alkyl group having from 1 to 10 carbon atoms.

The atomic group for forming an alicyclic structure represented by Z′ is an atomic group for forming a repeating unit having an optionally substituted alicyclic hydrocarbon structure. Above all, an atomic group which forms a repeating unit having a bridging alicyclic hydrocarbon structure is preferable.

Examples of the skeleton of the alicyclic hydrocarbon to be formed include those which are the same as in the alicyclic hydrocarbon group represented by R₁₂ to R₂₅ in the foregoing general formulae (pI) to (pV).

The skeleton of the alicyclic hydrocarbon structure may have a substituent. As such a substituent, R₁₃′ to R₁₆′ in the foregoing general formula (II-AB1) or (II-AB2) can be exemplified.

In the alicyclic hydrocarbon based acid-decomposable resin of the invention, the group which decomposes by the action of an acid can have at least one repeating unit among repeating units having a partial structure containing an alicyclic hydrocarbon represented by any of the foregoing general formulae (pI) to (pV), repeating units represented by the general formula (II-AB) and repeating units of a copolymerization component as described later.

The various substituents represented by R₁₃′ to R₁₆′ in the general formula (II-AB1) or (II-AB2) can also be a substituent of from the atomic group for forming an alicyclic hydrocarbon structure to the atomic group Z for forming a bridging alicyclic hydrocarbon structure in the foregoing general formula (II-AB).

Specific examples of the repeating unit represented by the general formula (II-AB1) or (II-AB2) are given below, but it should not be construed that the invention is limited thereto.

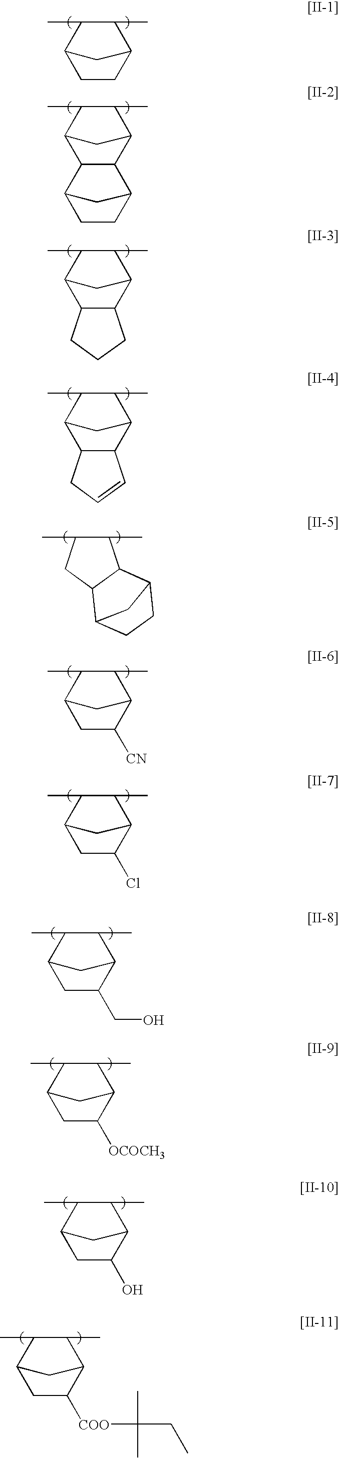

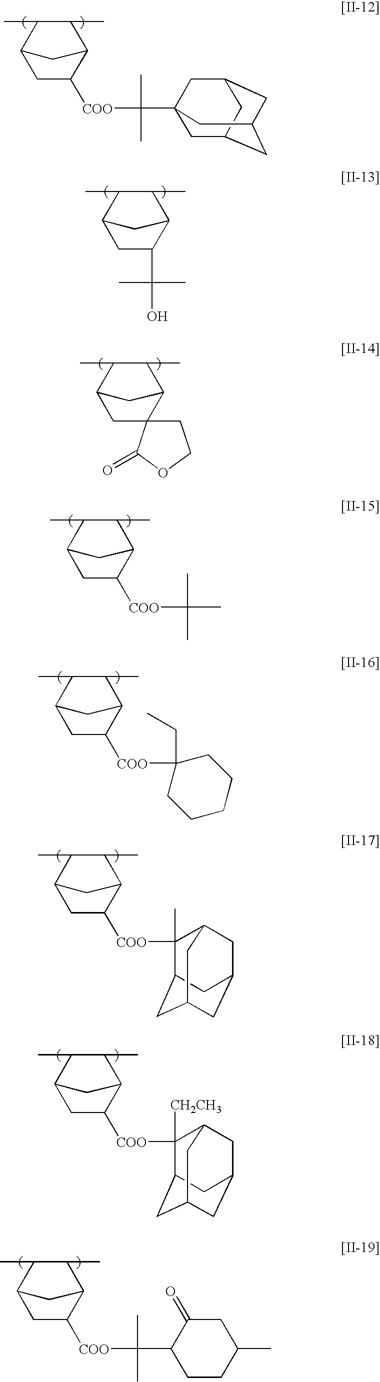

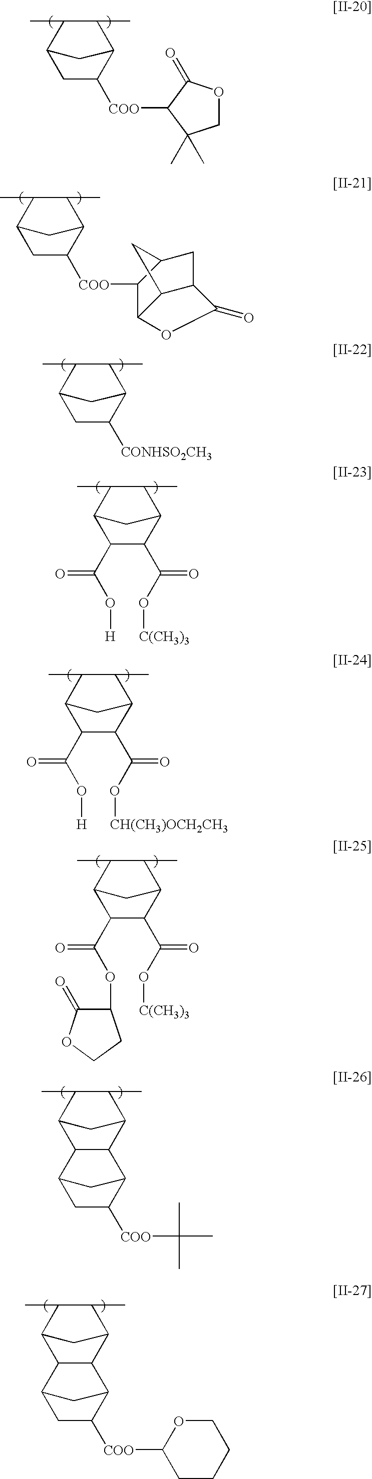

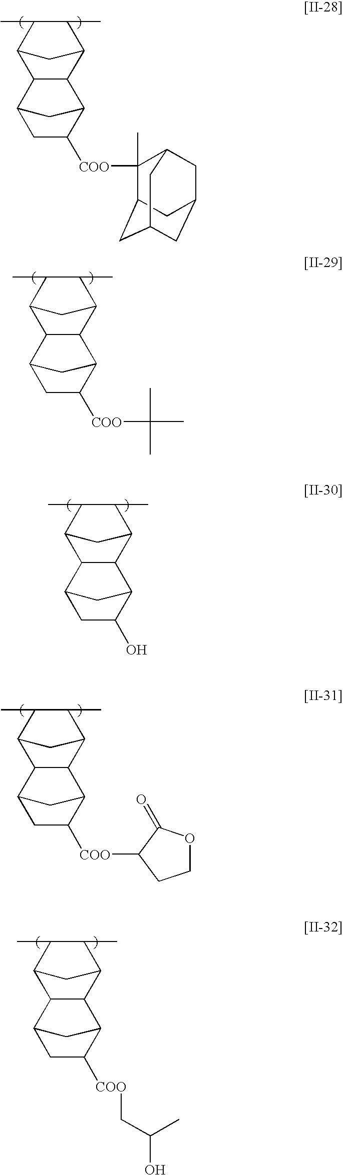

It is preferable that the resin as the component (A) has a repeating unit having a group having a lactone structure. Any group is useful as the group having a lactone structure so far as it has a lactone structure. Preferred examples thereof include a group having a 5-membered to 7-membered ring lactone structure, and a group in which a 5-membered to 7-membered ring lactone structure is fused with other ring structure in a form of forming a bicyclo structure or a spiro structure is preferable. As the group having a lactone structure, a group having a lactone structure represented by any of the following general formulae (LC1-1) to (LC1-16) is more preferable. Also, the group having a lactone structure may be bound directly to the principal chain. Above all, (LC1-1), (LC1-4), (LC1-5), (LC1-6), (LC1-13) and (LC1-14) are preferable as the lactone structure, and by using a specified lactone structure, the line edge roughness and development defect become satisfactory.

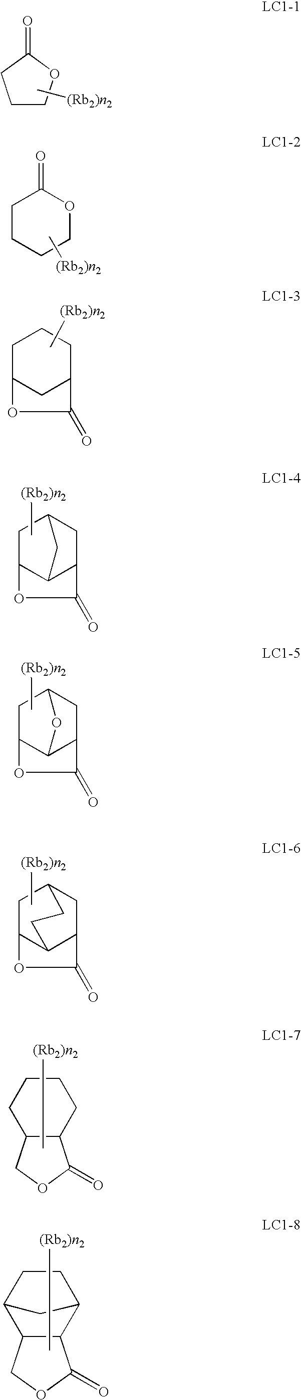

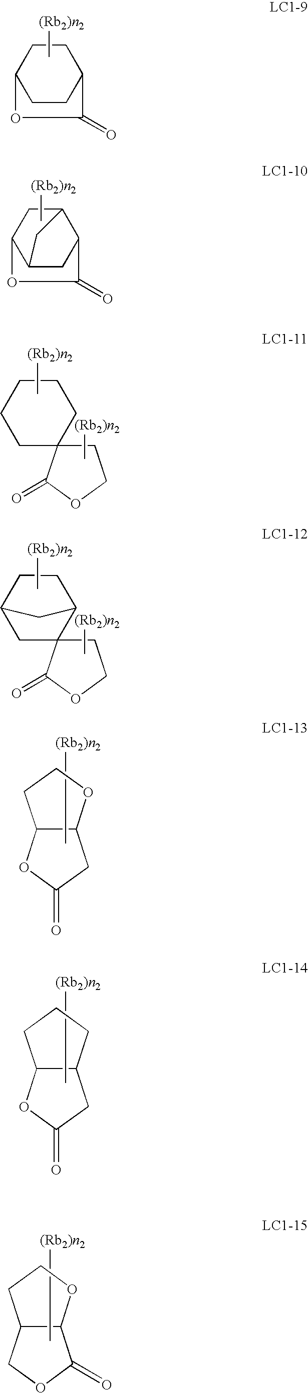

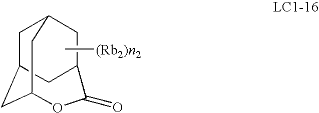

The lactone structure moiety may or may not have a substituent (Rb₂). Preferred examples of the substituent (Rb₂) include an alkyl group having from 1 to 8 carbon atoms, a cycloalkyl group having from 3 to 7 carbon atoms, an alkoxy group having from 1 to 8 carbon atoms, an alkoxycarbonyl group having from 1 to 8 carbon atoms, a carboxyl group, a halogen atom, a hydroxyl group, a cyano group and an acid-decomposable group. n₂ represents an integer of from 0 to 4. When n₂ is 2 or more, the plural existing substituents (Rb₂) may be the same or different; and the plural existing substituents (Rb₂) may be taken together to form a ring.

Examples of the repeating unit having a group having a lactone structure represented by any of the general formulae (LC1-1) to (LC1-16) include a repeating unit in which at least one of R₁₃′ to R₁₆′ in the foregoing general formula (II-AB1) or (II-AB2) is a group having a lactone structure represented by any of the general formulae (LC1-1) to (LC1-16) (for example, R₅ of —COOR₅ is a group having a lactone structure represented by any of the general formulae (LC1-1) to (LC1-16)) and a repeating unit represented by the following general formula (AI).

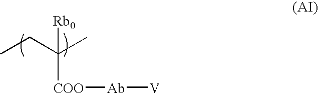

In the general formula (AI),

Rb₀ represents a hydrogen atom, a halogen atom or an alkyl group having from 1 to 4 carbon atoms. Preferred examples of a substituent which the alkyl group represented by Rb₀ may have include a hydroxyl group and a halogen atom.

Examples of the halogen atom represented by Rb₀ include a fluorine atom, a chlorine atom, a bromine atom and an iodine atom.

Rb₀ is preferably a hydrogen atom or a methyl group.

Ab represents a single bond, an alkylene group, a divalent connecting group having a monocyclic or polycyclic alicyclic hydrocarbon structure, an ether group, an ester group, a carbonyl group, a carboxyl group or a divalent group composed of a combination thereof.

Ab is preferably a single bond or a connecting group represented by -Ab₁-CO₂—. Ab₁ represents a linear or branched alkylene group or a monocyclic or polycyclic cycloalkylene group, and preferably a methylene group, an ethylene group, a cyclohexyl group, an adamantyl group or a norbornyl group.

V represents a group having a lactone structure represented by any of the general formulae (LC1-1) to (LC1-16).

With respect to the repeating unit having a lactone structure, optical isomers usually exist, and any optical isomer is useful. Also, one kind of an optical isomer may be used singly, and a mixture of plural optical isomers may be used. In the case of chiefly using one kind of an optical isomer, its optical purity (ee) is preferably 90 or more, and more preferably 95 or more.

Specific examples of the repeating unit having a lactone structure are given below, but it should not be construed that the invention is limited thereto.

(In the formulae, Rx represents H, CH₃, CH₂OH or CF₃.)

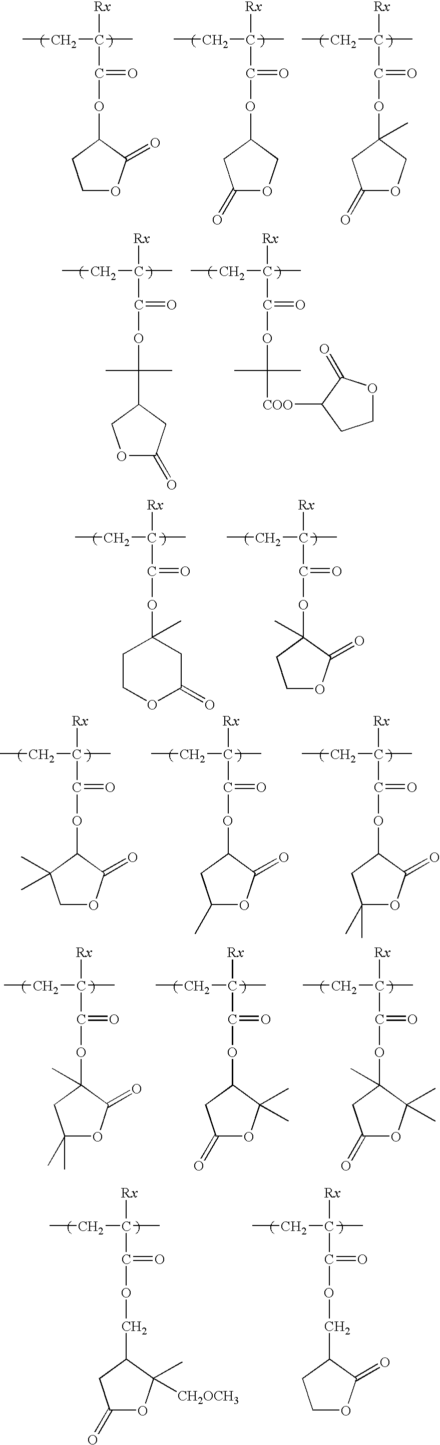

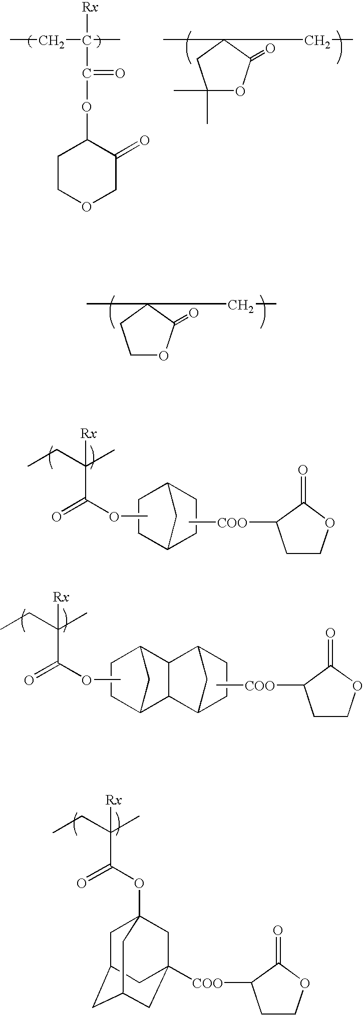

(In the formulae, Rx represents H, CH₃, CH₂OH or CF₃.)

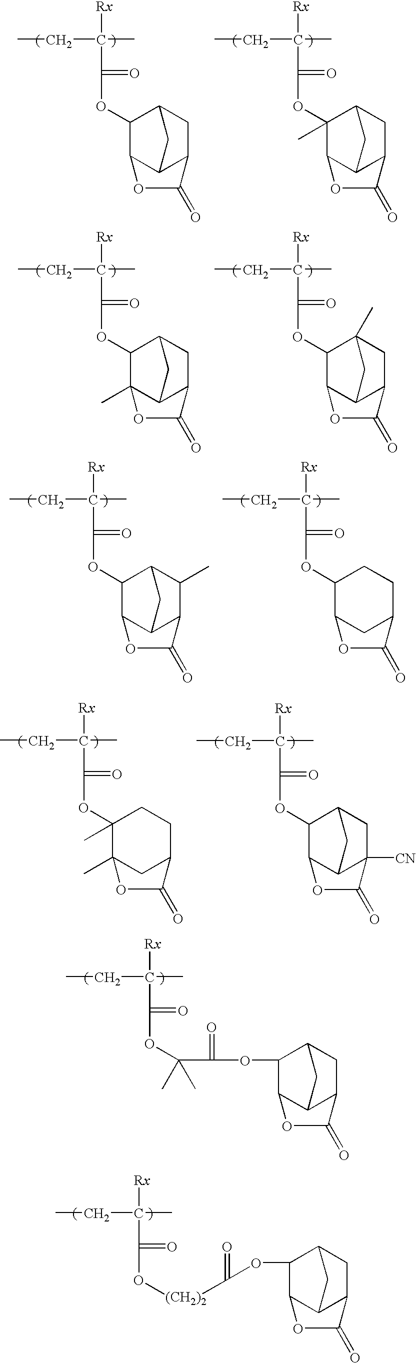

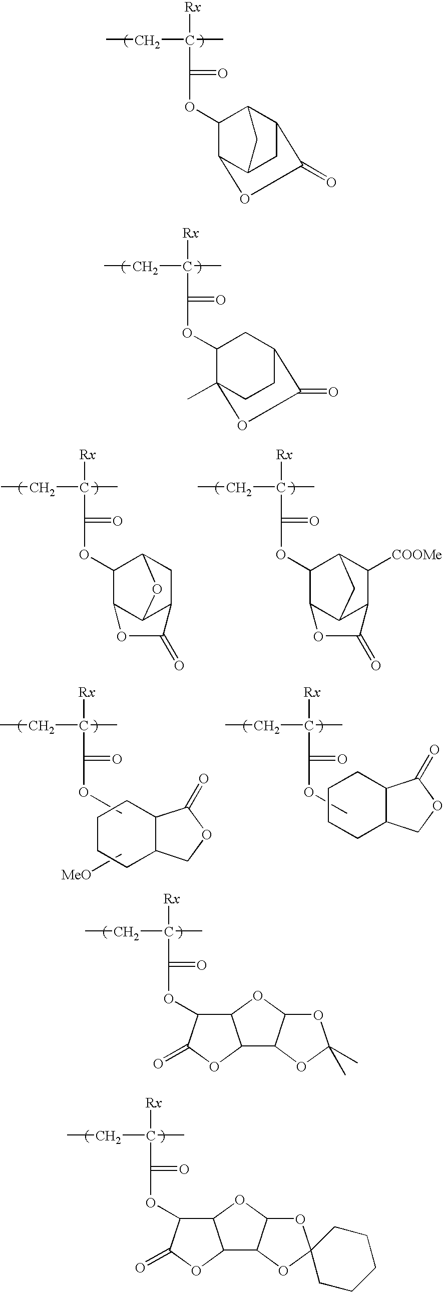

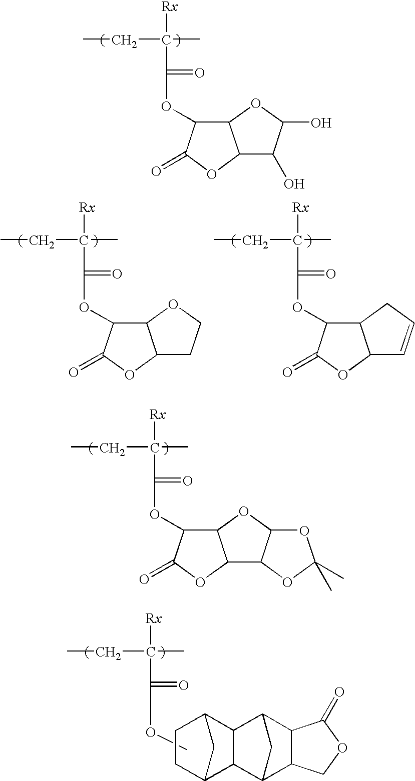

(In the formulae, Rx represents H, CH₃, CH₂OH or CF₃.)

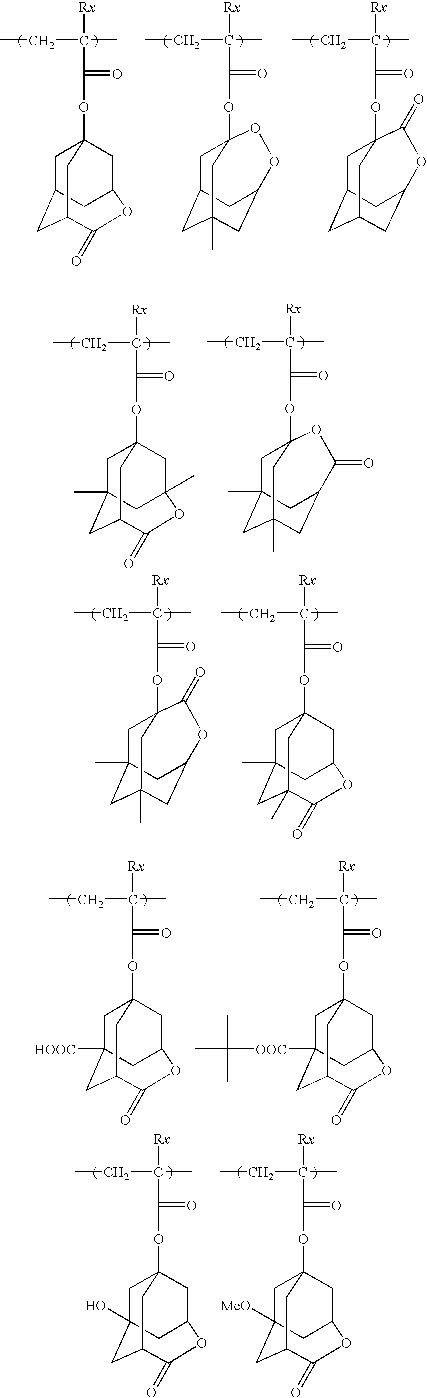

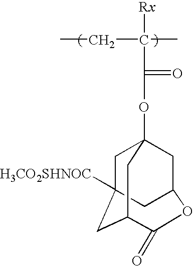

It is preferable that the resin as the component (A) has a repeating unit having a group having a polar group-substituted alicyclic hydrocarbon structure. According to this, the adhesiveness to a substrate and the affinity with a developing solution are enhanced. Preferred examples of the alicyclic hydrocarbon structure of the polar group-substituted alicyclic hydrocarbon structure include an adamantyl group, a diamantyl group and a norbornane group. Preferred examples of the polar group include a hydroxyl group and a cyano group. Preferred examples of the polar group-substituted alicyclic hydrocarbon structure include groups represented by the following general formulae (VIIa) to (VIId).

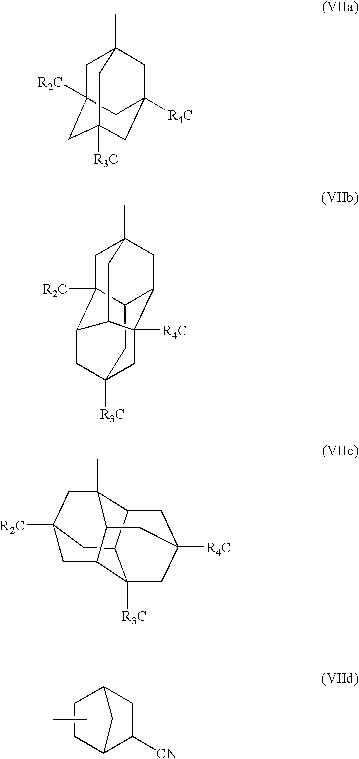

In the general formulae (VIIa) to (VIIc),

R_{2C} to R_{4C} each independently represents a hydrogen atom, a hydroxyl group or a cyano group, provided that at least one of R_{2C} to R_{4C} represents a hydroxyl group or a cyano group. It is preferable that one or two of R_{2C} to R_{4C} are a hydroxyl group, with the remainder being a hydrogen atom. In the general formula (VIa), it is more preferable that two of R_{2C} to R_{4C} are a hydroxyl group, with the remainder being a hydrogen atom.

Examples of the repeating unit represented by any of the general formulae (VIIa) to (VIId) include a repeating unit in which at least one of R₁₃′ to R₁₆′ in the foregoing general formula (II-AB1) or (II-AB2) is a group represented by any of the general formulae (VIIa) to (VIId) (for example, R₅ of —COOR₅ is a group represented by any of the general formulae (VIA) to (VIId)) and a repeating unit represented by any of the following general formulae (AIIa) to (AIId).

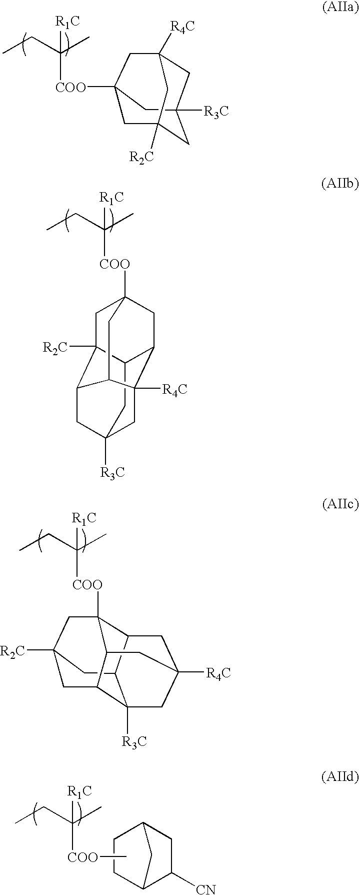

In the general formulae (AIIa) to (AIId),

R_{1C} represents a hydrogen atom, a methyl group, a trifluoromethyl group or a hydroxymethyl group.

Specific examples of the repeating unit represented by any of the general formulae (AIIa) to (AIId) are given below, but it should not be construed that the invention is limited thereto.

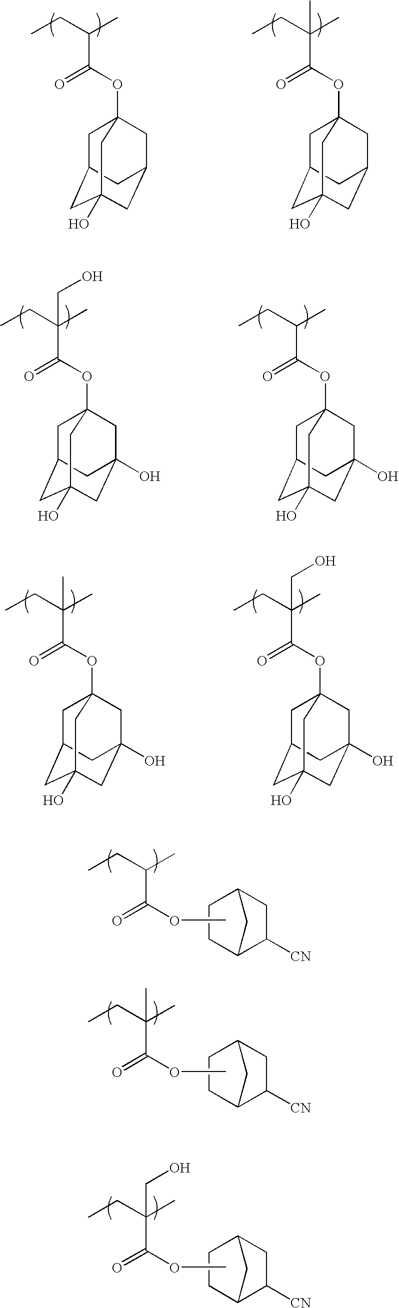

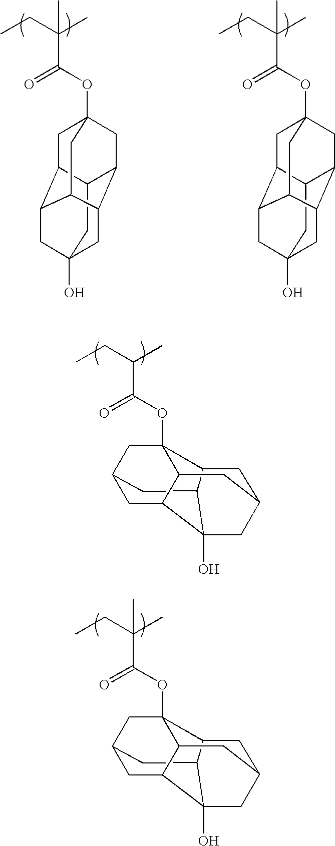

The resin as the component (A) may have a repeating unit represented by the following general formula (VIII).

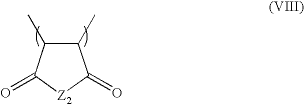

In the general formula (VIII),

Z₂ represents —O— or —N(R₄₁)—; R₄₁ represents a hydrogen atom, a hydroxyl group, an alkyl group or —OSO₂—R₄₂; and R₄₂ represents an alkyl group, a cycloalkyl group or a camphor residue. The alkyl group represented by R₄₁ and R₄₂ may be substituted with a halogen atom (preferably a fluorine atom) or the like.

Specific examples of the repeating unit represented by the general formula (VIII) are given below, but it should not be construed that the invention is limited thereto.

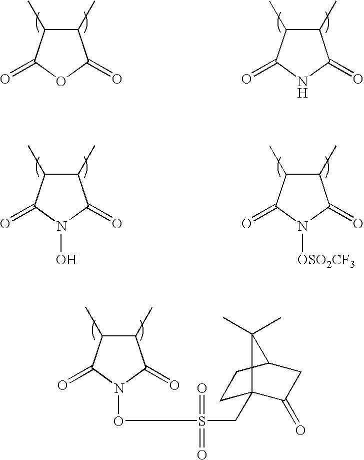

The resin as the component (A) preferably has a repeating unit having an alkali-soluble group, and more preferably has a repeating unit having a carboxyl group. When the resin as the component (A) contains such a repeating unit, the resolution in a contact hole application increases. As the repeating unit having a carboxyl group, any of a repeating unit in which a carboxyl group is bound directly to the principal chain of the resin, for example, a repeating unit derived from acrylic acid or methacrylic acid; a repeating unit in which a carboxyl group is bound to the principal chain of the resin via a connecting group; and a repeating unit to be introduced into the terminal end of a polymer chain using an alkali-soluble group-containing polymerization initiator or a chain transfer agent at the time of polymerization is useful. The connecting group may have a monocyclic or polycyclic hydrocarbon structure. Above all, a repeating unit derived from acrylic acid or methacrylic acid is especially preferable.

The resin as the component (A) may further have a repeating unit having from one to three groups represented by the following general formula (F1). According to this, the line edge roughness performance is enhanced.

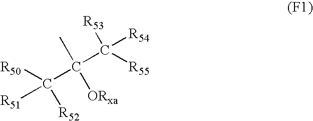

In the general formula (F1),

R₅₀ to R₅₅ each independently represents a hydrogen atom, a fluorine atom or an alkyl group, provided that at least one of R₅₀ to R₅₅ represents a fluorine atom or an alkyl group in which at least one hydrogen atom is substituted with a fluorine atom.

Rxa represents a hydrogen atom or an organic group (preferably an acid-decomposable protective group, an alkyl group, a cycloalkyl group, an acyl group or an alkoxycarbonyl group).

The alkyl group represented by R₅₀ to R₅₅ may be substituted with a halogen atom such as a fluorine atom, a cyano group or the like and is preferably an alkyl group having from 1 to 3 carbon atoms, for example, a methyl group and a trifluoromethyl group.

It is preferable that R₅₀ to R₅₅ are all a fluorine atom.

Preferred examples of the organic group represented by Rxa include an alkyl group, a cycloalkyl group, an acyl group, an alkylcarbonyl group, alkoxycarbonyl group, an alkoxycarbonylmethyl group, an alkoxymethyl group and a 1-alkoxyethyl group, each of which may have an acid-decomposable protective group or a substituent.

The repeating unit having the general formula (F1) is preferably a repeating unit represented by the following general formula (F2).

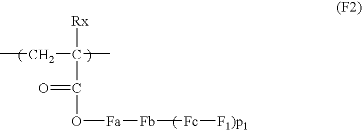

In the general formula (F2),

Rx represents a hydrogen atom, a halogen atom or an alkyl group having from 1 to 4 carbon atoms. Examples of a substituent which the alkyl group represented by Rx may have include a hydroxyl group and a halogen atom.

Fa represents a single bond or a linear or branched alkylene group (preferably a single bond).

Fb represents a monocyclic or polycyclic cyclic hydrocarbon group.

Fc represents a single bond or a linear or branched alkylene group (preferably a single bond or a methylene group).

F₁ represents a group represented by the general formula (F1).

p₁ represents from 1 to 3.

Preferred examples of the cyclic hydrocarbon group represented by Fb include a cyclopentyl group, a cyclohexyl group and a norbornyl group.

Specific examples of the repeating unit having the group represented by the general formula (F1) are given below, but it should not be construed that the invention is limited thereto.

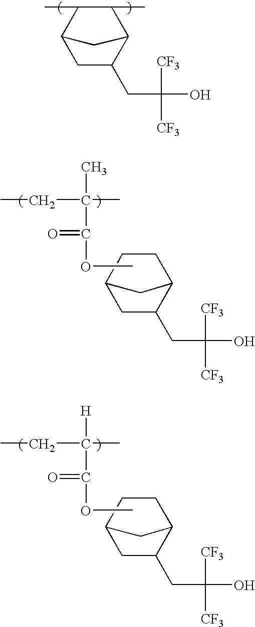

The resin as the component (A) may further contain a repeating unit having an alicyclic hydrocarbon structure and not exhibiting acid decomposability. According to this, the elution of a low-molecular weight component from a resist film into a liquid immersion solution at the time of liquid immersion exposure can be reduced. Examples of such a repeating unit include 1-adamantyl (meth)acrylate, tricyclodecanyl (meth)acrylate and cyclohexyl (meth)acrylate.

In the resin as the component (A), the content of the repeating unit having a heterocyclic group containing plural sulfur atoms in a cyclic structure thereof is preferably from 1 to 60% by mole, more preferably from 1 to 30% by mole, and further preferably from 1 to 15% by mole in the whole of the repeating units.

In the resin as the component (A), the content of the repeating unit having an acid-decomposable group is preferably from 10 to 60% by mole, more preferably from 20 to 50% by mole, and further preferably from 25 to 40% by mole in the whole of the repeating units.

In the resin as the component (A), the content of the repeating unit having a partial structure containing the alicyclic hydrocarbon represented by any of the general formulae (pI) to (pV) is preferably from 20 to 70% by mole, more preferably from 20 to 50% by mole, and further preferably from 25 to 40% by mole in the whole of the repeating units.

In the resin as the component (A), the content of the repeating unit represented by the general formula (II-AB) is preferably from 10 to 60% by mole, more preferably from 15 to 55% by mole, and further preferably from 20 to 50% by mole in the whole of the repeating units.

Also, though the content of the repeating structural unit on the basis of a monomer of the foregoing additional copolymerization component in the resin can be properly set up depending upon the desired performance of a resist, it is generally not more than 99% by mole, more preferably not more than 90% by mole, and further preferably not more than 80% by mole relative to the total molar number of the sum of the repeating structural unit having a partial structure containing the alicyclic hydrocarbon represented by any of the foregoing general formulae (pI) to (pV) and the repeating unit represented by the foregoing general formula (II-AB).

When the composition of the invention is used for ArF exposure, it is preferable that the resin does not have an aromatic group in view of the transparency to ArF light.

The resin as the component (A) can be synthesized according to the usual way (for example, radical polymerization). Examples of the general synthesis method include a batchwise polymerization method in which a monomer species and an initiator are dissolved in a solvent and the solution is polymerized upon heating; and a dropwise polymerization method in which a solution of a monomer species and an initiator is added dropwise in a heated solvent over from 1 to 10 hours, with a dropwise polymerization method being preferable. Examples of the reaction solvent include ethers (for example, tetrahydrofuran, 1,4-dioxane and diisopropyl ether), ketones (for example, methyl ethyl ketone and methyl isobutyl ketone), ester solvents (for example, ethyl acetate), amide solvents (for example, dimethylformamide and dimethylacetamide) and solvents capable of dissolving the composition of the invention therein as described later (for example, propylene glycol monomethyl ether acetate, propylene glycol monomethyl ether and cyclohexanone). It is more preferable that the polymerization is carried out by using the same solvent as the solvent used in the resist composition of the invention. According to this, it is possible to inhibit the generation of a particle at the preservation.

It is preferable that the polymerization reaction is carried out in an inert gas atmosphere such as nitrogen and argon. The polymerization is initiated by using a commercially available radical initiator (for example, an azo based initiator and a peroxide) as the polymerization initiator. An azo based initiator is preferable as the radical initiator, and an azo based initiator having an ester group, a cyano group or a carboxyl group is preferable. Preferred examples of the initiator include azobisisobutyronitrile, azobisdimethylvaleronitirle and dimethyl 2,2′-azobis(2-methylpropionate). If desired, the initiator is added supplementarily or dividedly; and after completion of the reaction, the reaction mixture is thrown into a solvent, and a desired polymer is recovered by a method such as powder or solid recovery. The reaction concentration is from 5 to 50% by mass, and preferably from 10 to 30% by mass. The reaction temperature is usually from 10° C. to 150° C., preferably from 30° C. to 120° C., and more preferably from 60° C. to 100° C.

A weight average molecular weight of the resin as the component (A) is preferably from 2,000 to 200,000 in terms of a value as reduced into polystyrene by the GPC method. By setting up the weight average molecular weight at 2,000 or more, the heat resistance and dry etching resistance can be enhanced; and by setting up the weight average molecular weight at not more than 200,000, not only the developability can be enhanced, but since the viscosity is low, the fabrication properties can be enhanced. The weight average molecular weight is more preferably from 2,500 to 50,000, and further preferably from 3,000 to 30,000. By adjusting the molecular weight, the heat resistance, resolving power and development defect of the composition and the like can be made satisfactory at the same time.

A degree of dispersion (Mw/Mn) of the resin as the component (A) is preferably from 1.0 to 3.0, more preferably from 1.2 to 2.5, and further preferably from 1.2 to 1.6. By adjusting the degree of dispersion at an appropriate range, the line edge roughness performance can be enhanced.

In the positive working photosensitive composition of the invention, a blending amount of the resin as the component (A) in the whole of the composition is preferably from 40 to 99.99% by mass, more preferably from 50 to 99% by mass, and further preferably from 80 to 96% by mass in the whole of the solids.

Specific examples of the resin as the component (A) are given below, but it should not be construed that the invention is limited thereto.

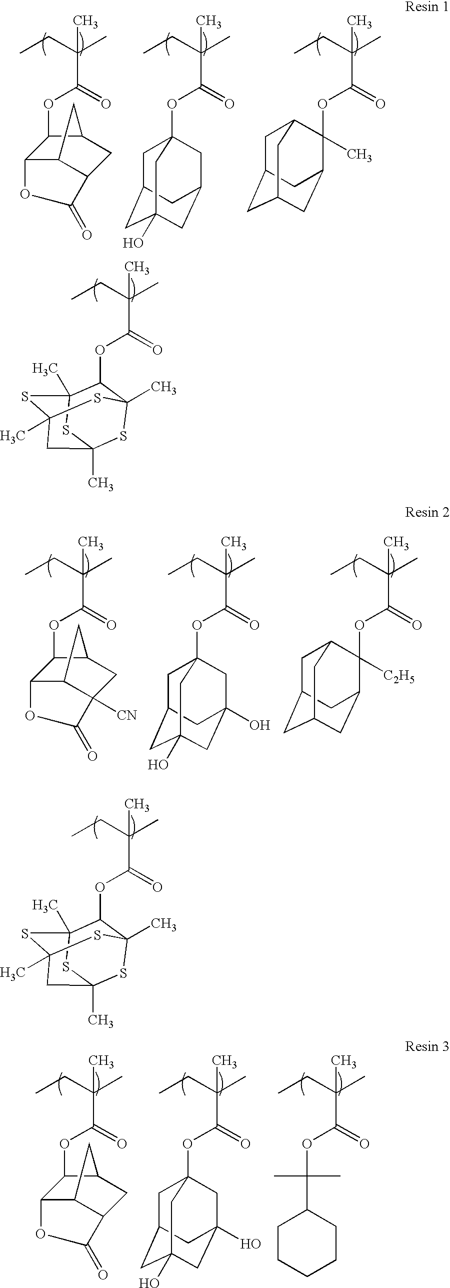

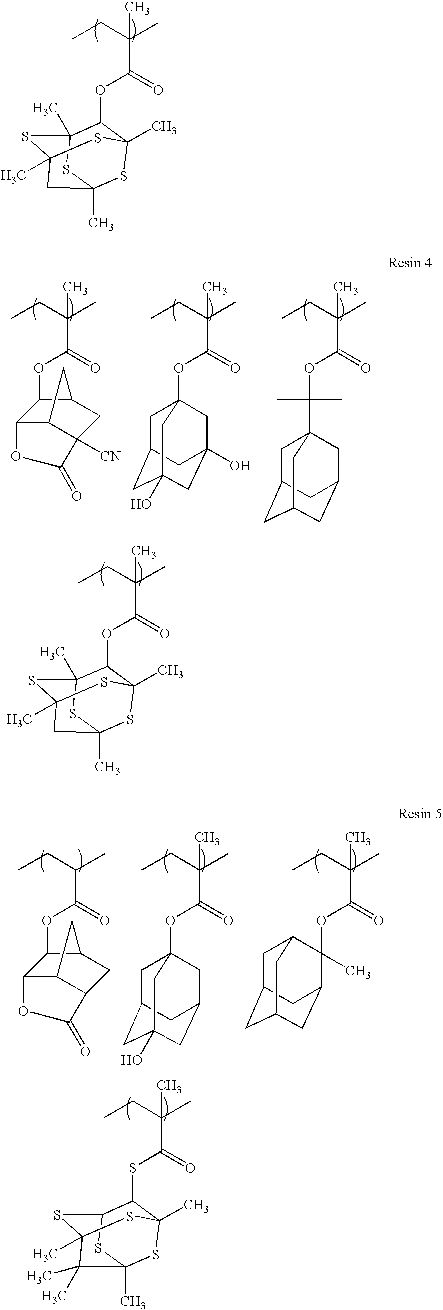

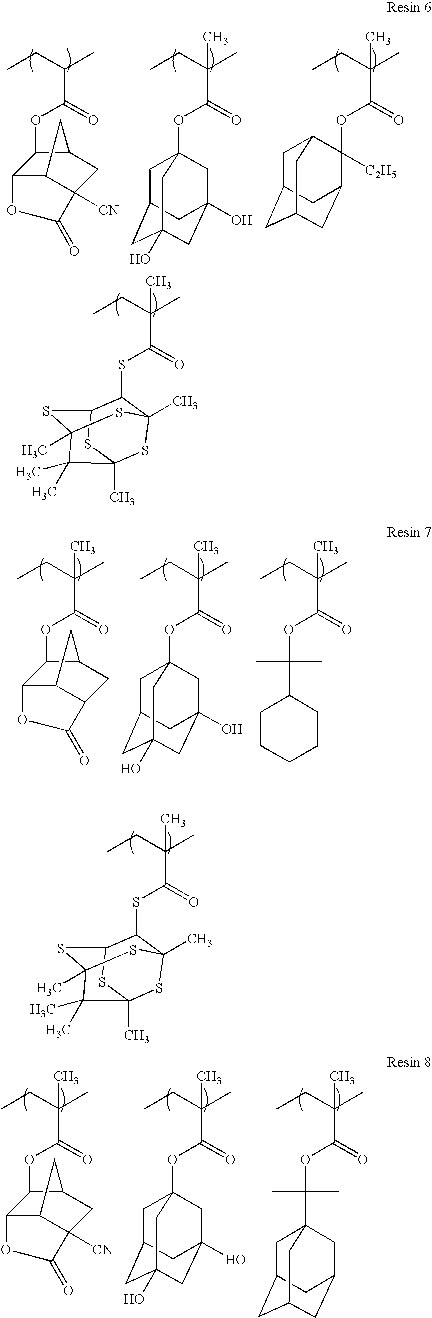

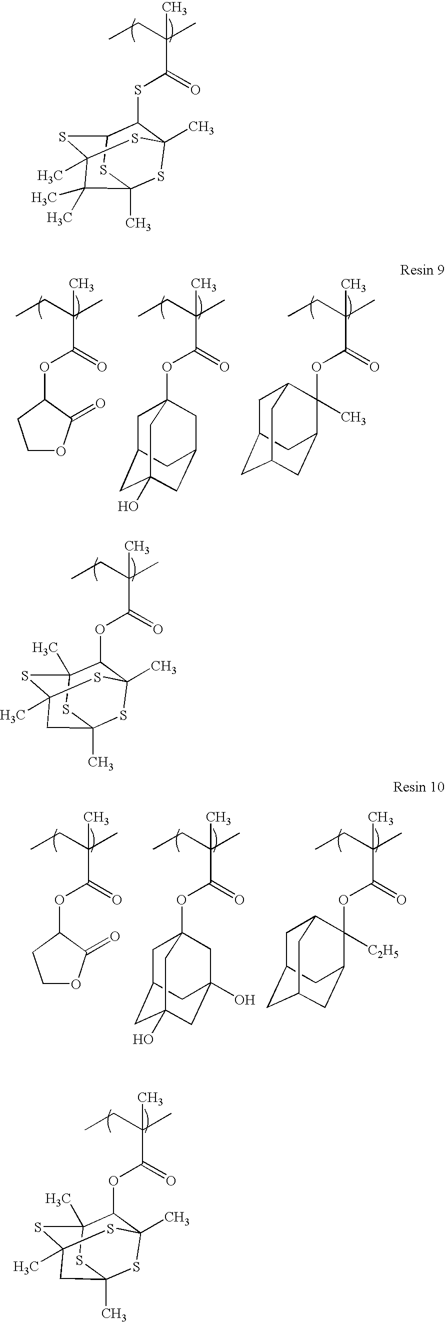

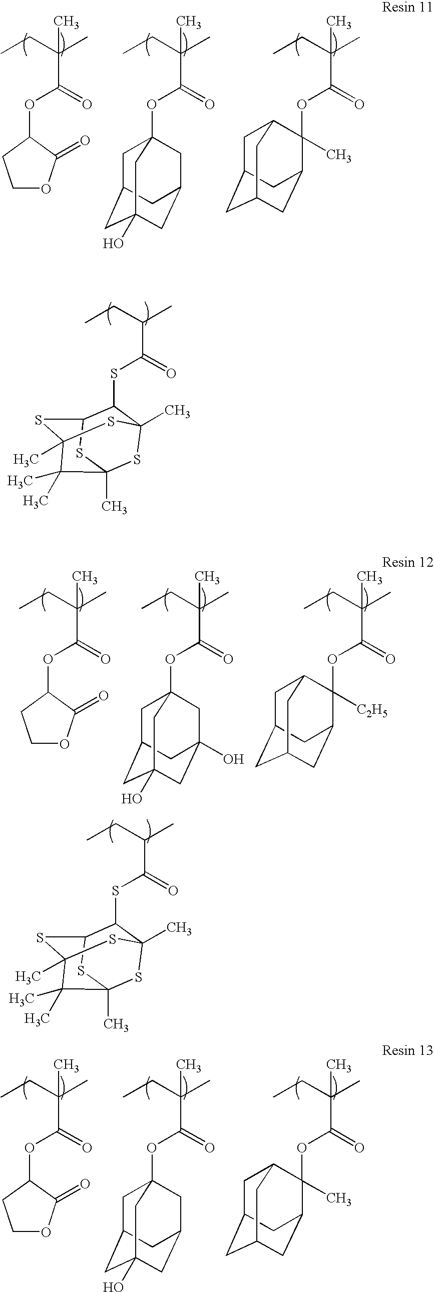

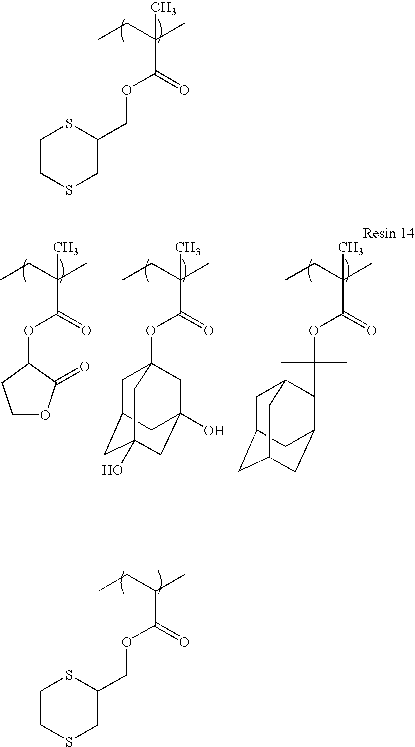

(B) Compound capable of generating an acid upon irradiation with actinic rays or radiation:

The positive working photosensitive composition of the invention contains a compound capable of generating an acid upon irradiation with actinic rays or radiation (hereinafter also referred to as “acid generator”).

As the generator, a photoinitiator for photo cationic polymerization, a photoinitiator of photo radical polymerization, a photo-decoloring agent for dyes, a photo-discoloring agent, a known compound capable of generating an acid upon irradiation with actinic rays or radiation as used in micro resists or the like and a mixture thereof can be properly chosen and used.

Examples thereof include a diazonium salt, a phosphonium salt, a sulfonium salt, an iodonium salt, imide sulfonate, oxime sulfonate, diazosulfone, disulfone and o-nitrobenzyl sulfonate.

Also, a compound in which such a group or compound capable of generating an acid upon irradiation with actinic rays or radiation is introduced into the principal chain or side chain of a polymer, for example, compounds described in U.S. Pat. No. 3,849,137, German Patent No. 3,914,407, JP-A-63-26653, JP-A-55-164824, JP-A-62-69263, JP-A-63-146038, JP-A-63-163452, JP-A-62-153853, JP-A-63-146029 and so on can be used.

Furthermore, compounds capable of generating an acid by light, as described in U.S. Pat. No. 3,779,778, European Patent No. 126,712 and so on can be used.

As a preferred compound of the acid generator, compounds represented by the following general formulae (ZI), (ZII) and (ZIII) can be exemplified.

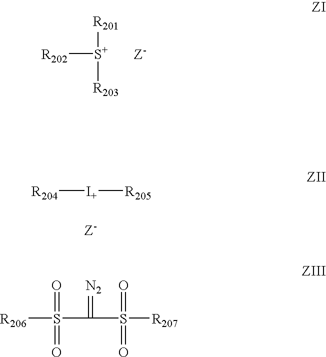

In the foregoing general formula (ZI),

R₂₀₁, R₂₀₂ and R₂₀₃ each independently represents an organic group.

The carbon atom number of the organic group represented by R₂₀₁, R₂₀₂ and R₂₀₃ is generally from 1 to 30, and preferably from 1 to 20.

Also, two of R₂₀₁ to R₂₀₃ may be taken together to form a ring structure and may contain an oxygen atom, a sulfur atom, an ester bond, an amide bond or a carbonyl group in the ring. Examples of the group which two of R₂₀₁ to R₂₀₃ are taken to form include an alkylene group (for example, a butylene group and a pentylene group).

Z⁻ represents a non-nucleic anion.

Examples of the non-nucleic anion represented by Z⁻ include a sulfonic anion, a carboxylic anion, a sulfonyl imide anion, a bis(alkylsulfonyl)imide anion and a tris(alkyl-sulfonyl)methyl anion.

The “non-nucleic anion” as referred to herein means an anion having extremely low ability to cause a nucleic reaction, and it is an anion capable of inhibiting the decomposition with time due to an intramolecular nucleic reaction. According to this, the stability with time of the resist is enhanced.

Examples of the sulfonic anion include an aliphatic sulfonic anion, an aromatic sulfonic anion and a camphor sulfonic anion.

Examples of the carboxylic anion include an aliphatic carboxylic anion, an aromatic carboxylic anion and an aralkyl carboxylic anion.

The aliphatic side in the aliphatic sulfonic anion may be an alkyl group or a cycloalkyl group and is preferably an alkyl group having from 1 to 30 carbon atoms or a cycloalkyl group having from 3 to 30 carbon atoms. Examples thereof include a methyl group, an ethyl group, a propyl group, an isopropyl group, an n-butyl group, an isobutyl group, a sec-butyl group, a pentyl group, a neopentyl group, a hexyl group, a heptyl group, an octyl group, a nonyl group, a decyl group, an undecyl group, a dodecyl group, a tridecyl group, a tetradecyl group, a pentadecyl group, a hexadecyl group, a heptadecyl group, an octadecyl group, a nonadecyl group, an eicosyl group, a cyclopropyl group, a cyclopentyl group, a cyclohexyl group, an adamantyl group, a norbornyl group and a boronyl group.

The aromatic group in the aromatic sulfonic anion is preferably an aryl group having from 6 to 14 carbon atoms, and examples thereof include a phenyl group, a tolyl group and a naphthyl group.

Each of the alkyl group, the cycloalkyl group and the aryl group in the aliphatic sulfonic anion and the aromatic sulfonic anion may have a substituent. Examples of the substituent in each of the alkyl group, the cycloalkyl group and the aryl group in the aliphatic sulfonic anion and the aromatic sulfonic anion include a nitro group, a halogen atom (for example, a fluorine atom, a chlorine atom, a bromine atom and an iodine atom), a carboxyl group, a hydroxyl group, an amino group, a cyano group, an alkoxy group (preferably one having from 1 to 15 carbon atoms), a cycloalkyl group (preferably one having from 3 to 15 carbon atoms), an aryl group (preferably one having from 6 to 14 carbon atoms), an alkoxycarbonyl group (preferably one having from 2 to 7 carbon atoms), an acyl group (preferably one having from 2 to 12 carbon atoms), an alkoxycarbonyloxy group (preferably one having from 2 to 7 carbon atoms), an alkylthio group (preferably one having from 1 to 15 carbon atoms), an alkylsulfonyl group (preferably one having from 1 to 15 carbon atoms), an alkyliminosulfonyl group (preferably one having from 2 to 15 carbon atoms), an aryloxysulfonyl group (preferably one having from 6 to 20 carbon atoms), an alkylaryloxysulfonyl group (preferably one having from 7 to 20 carbon atoms), a cycloalkylaryloxysulfonyl group (preferably one having from 10 to 20 carbon atoms), an alkyloxyalkyloxy group (preferably one having from 5 to 20 carbon atoms) and a cycloalkylalkyloxyalkyloxy group (preferably one having from 8 to 20 carbon atoms). With respect to the aryl group and ring structure which each of the groups has, an alkyl group (preferably one having from 1 to 15 carbon atoms) can be further exemplified as the substituent.

Examples of the aliphatic site in the aliphatic carboxylic anion include the same alkyl group and cycloalkyl group in the aliphatic sulfonic anion.

Examples of the aromatic group in the aromatic carboxylic anion include the same aryl group in the aromatic sulfonic anion.

The aralkyl group in the aralkyl carboxylic anion is preferably an aralkyl group having from 6 to 12 carbon atoms, and examples thereof include a benzyl group, a phenethyl group, a naphthylmethyl group and a naphthylethyl group.

Each of the alkyl group, the cycloalkyl group, the aryl group and the aralkyl group in the aliphatic carboxylic anion, the aromatic carboxylic anion and the aralkyl carboxylic anion may have a substituent. Examples of a substituent of each of the alkyl group, the cycloalkyl group, the aryl group and the aralkyl group in the aliphatic carboxylic anion, the aromatic carboxylic anion and the aralkyl carboxylic anion include the same halogen atom, alkyl group, cycloalkyl group, alkoxy group and alkylthio group in the aromatic sulfonic anion.

Examples of the sulfonylimide anion include a saccharin anion.

The alkyl group in the bis(alkylsulfonyl)imide anion and the tris(alkylsulfonyl)methyl anion is preferably an alkyl group having from 1 to 5 carbon atoms, and examples thereof include a methyl group, an ethyl group, a propyl group, an isopropyl group, an n-butyl group, an isobutyl group, a sec-butyl group, a pentyl group and a neopentyl group. Examples of a substituent of such an alkyl group include a halogen atom, a halogen atom-substituted alkyl group, an alkoxy group, an alkylthio group, an alkyloxysulfonyl group, an aryloxysulfonyl group and a cycloalkylaryloxysulfonyl group. Above all, a fluorine atom-substituted alkyl group is preferable.

Examples of other non-nucleic anion include fluorinated phosphorus, fluorinated boron and fluorinated antimony.

Preferred examples of the non-nucleic anion represented by Z⁻ include an aliphatic sulfonic anion in which the α-position of sulfonic acid is substituted with a fluorine atom, an aromatic sulfonic anion substituted with a fluorine atom or a group having a fluorine atom, a bis(alkylsulfonyl)imide anion in which the alkyl group thereof is substituted with a fluorine atom and a tris(alkylsulfonyl)methide anion in which the alkyl group thereof is substituted with a fluorine atom. The non-nucleic anion is more preferably a perfluoro aliphatic sulfonic anion having from 4 to 8 carbon atoms or a benzenesulfonic anion having a fluorine atom; and further preferably a nonafluorobutanesulfonic anion, a perfluorooctanesulfonic anion, a pentafluorobenzenesulfonic anion or a 3,5-bis(trifluoro-methyl)benzenesulfonic anion.

Examples of the organic group represented by R₂₀₁, R₂₀₂ and R₂₀₃ include corresponding groups in compounds (ZI-1), (ZI-2) and (ZI-3) as described later.

The compound may be a compound having a plural number of structures represented by the general formula (ZI). For example, the compound may be a compound having a structure in which at least one of R₂₀₁ to R₂₀₃ of a compound represented by the general formula (ZI) is bound to at least one of R₂₀₁ to R₂₀₃ of another compound represented by the general formula (ZI).

More preferred examples of the component (ZI) include compounds (ZI-1), (ZI-2) and (ZI-3) as described below.

The compound (ZI-1) is an aryl sulfonium compound in which at least one of R₂₀₁ to R₂₀₃ in the foregoing general formula (ZI) is an aryl group, namely a compound having an aryl sulfonium as a cation.

In the aryl sulfonium compound, all of R₂₀₁ to R₂₀₃ may be an aryl group, or a part of R₂₀₁ to R₂₀₃ may be an aryl group, with the remainder being an alkyl group or a cycloalkyl group.

Examples of the aryl sulfonium compound include a triaryl sulfonium compound, a diarylalkyl sulfonium compound, an aryldialkyl sulfonium compound, a diarylcycloalkyl sulfonium compound and an aryldicycloalkyl sulfonium compound.

The aryl group of the aryl sulfonium compound is preferably a phenyl group or a naphthyl group, and more preferably a phenyl group. The aryl group may be an aryl group having a heterocyclic structure having an oxygen atom, a nitrogen atom, a sulfur atom or the like. Examples of the aryl group having a heterocyclic structure include a pyrrole residue (a group formed when one hydrogen atom is lost from pyrrole), a furan residue (a group formed when one hydrogen atom is lost from furan), a thiophene residue (a group formed when one hydrogen atom is lost from thiophene), an indole residue (a group formed when one hydrogen atom is lost from indole), a benzofuran residue (a group formed when one hydrogen atom is lost from benzofuran) and a benzothiophene residue (a group formed when one hydrogen atom is lost from benzothiophene). In the case where the aryl sulfonium compound has two or more aryl groups, the two or more existing aryl groups may be the same or different.

The alkyl group or the cycloalkyl group which the aryl sulfonium compound optionally has is preferably a linear or branched alkyl group having from 1 to 15 carbon atoms or a cycloalkyl group having from 3 to 15 carbon atoms, respectively. Examples thereof include a methyl group, an ethyl group, a propyl group, an n-butyl group, a sec-butyl group, a t-butyl group, a cyclopropyl group, a cyclobutyl group and a cyclohexyl group.

Each of the aryl group, the alkyl group and the cycloalkyl group represented by R₂₀₁ to R₂₀₃ may have, as a substituent, an alkyl group (preferably one having from 1 to 15 carbon atoms), a cycloalkyl group (preferably one having from 3 to 15 carbon atoms), an aryl group (preferably one having from 6 to 14 carbon atoms), an alkoxy group (preferably one having from 1 to 15), a halogen atom, a hydroxyl group or a phenylthio group. Preferred examples of the substituent include a linear or branched alkyl group having from 1 to 12 carbon atoms, a cycloalkyl group having from 3 to 12 carbon atoms and a linear, branched or cyclic alkoxy group having from 1 to 12 carbon atoms; and more preferred examples thereof include an alkyl group having from 1 to 4 carbon atoms and an alkoxy group having from 1 to 4 carbon atoms. The substituent may be substituted on any one of three R₂₀₁ to R₂₀₃ or may be substituted on all of three R₂₀₁ to R₂₀₃. Also, in the case where R₂₀₁ to R₂₀₃ are an aryl group, it is preferable that the substituent is substituted at the p-position of the aryl group.

Next, the compound (ZI-2) is described.

The compound (ZI-2) is a compound in which R₂₀₁ to R₂₀₃ in the general formula (ZI) each independently represents an aromatic ring-free organic group. The “aromatic ring” as referred to herein also includes a hetero atom-containing aromatic ring.

The aromatic ring-free organic group represented by R₂₀₁ to R₂₀₃ generally has from 1 to 30 carbon atoms, and preferably from 1 to 20 carbon atoms.

R₂₀₁ to R₂₀₃ are each independently preferably an alkyl group, a cycloalkyl group, an allyl group or a vinyl group; more preferably a linear or branched 2-oxoalkyl group, a 2-oxocycloalkyl group or an alkoxycarbonylmethyl group; and especially preferably a linear or branched 2-oxoalkyl group.

Preferred examples of the alkyl group and the cycloalkyl group represented by R₂₀₁ to R₂₀₃ include a linear or branched alkyl group having from 1 to 10 carbon atoms (for example, a methyl group, an ethyl group, a propyl group, a butyl group and a pentyl group) and a cycloalkyl group having from 3 to 10 carbon atoms (for example, a cyclopentyl group, a cyclohexyl group and a norbornyl group). More preferred examples of the alkyl group include a 2-oxoalkyl group and an alkoxycarbonylmethyl group. More preferred examples of the cycloalkyl group include a 2-oxocycloalkyl group.

The 2-oxoalkyl group may be linear or branched, and preferred examples thereof include a group having >C═O at the 2-position of the foregoing alkyl group.

Preferred examples of the 2-oxocycloalkyl group include a group having >C═O at the 2-position of the foregoing cycloalkyl group.

Preferred examples of the alkoxy group in the alkoxycarbonylmethyl group include an alkoxy group having from 1 to 5 carbon atoms (for example, a methoxy group, an ethoxy group, a propoxy group, a butoxy group and a pentoxy group).

Each of R₂₀₁ to R₂₀₃ may be further substituted with a halogen atom, an alkoxy group (for example, one having from 1 to 5 carbon atoms), a hydroxyl group, a cyano group or a nitro group.

The compound (ZI-3) is a compound represented by the following general formula (ZI-3) and is a compound having a phenacyl sulfonium salt structure.

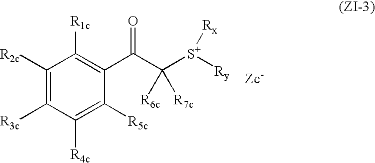

In the general formula (ZI-3),

R_{1c} to R_{5c} each independently represents a hydrogen atom, an alkyl group, a cycloalkyl group, an alkoxy group or a halogen atom.

R_{6c} and R_{7c} each independently represents a hydrogen atom, an alkyl group or a cycloalkyl group.

Rₓ and R_{y} each independently represents an alkyl group, a cycloalkyl group, an allyl group or a vinyl group.

Any two or more of R_{1c} to R_{5c}, R_{6c} and R_{7c}, and Rₓ and R_{y} may be taken together, respectively to form a ring structure. This ring structure may contain an oxygen atom, a sulfur atom, an ester bond or an amide bond. Examples of the group formed when any two or more of R_{1c} to R_{5c}, R_{6c} and R_{7c}, and Rₓ and R_{y} are taken together, respectively include a butylene group and a pentylene group.

Zc⁻ represents a non-nucleic anion, and examples thereof include the same non-nucleic anion as in Z⁻ in the general formula (ZI).

The alkyl group represented by R_{1c} to R_{7c} may be linear or branched; and examples thereof include an alkyl group having from 1 to 20 carbon atoms, and preferably a linear or branched alkyl group having from 1 to 12 carbon atoms (for example, a methyl group, an ethyl group, a linear or branched propyl group, a linear or branched butyl group and a linear or branched pentyl group). Examples of the cycloalkyl group include a cycloalkyl group having from 3 to 8 carbon atoms (for example, a cyclopentyl group and a cyclohexyl group).

The alkoxy group represented by R_{1c} to R_{5c} may be linear, branched or cyclic; and examples thereof include an alkoxy group having from 1 to 10 carbon atoms, and preferably a linear or branched alkoxy group having from 1 to 5 carbon atoms (for example, a methoxy group, an ethoxy group, a linear or branched propoxy group, a linear or branched butoxy group and a linear or branched pentoxy group) and a cyclic alkoxy group having from 3 to 8 carbon atoms (for example, a cyclopentyloxy group and a cyclohexyloxy group).

It is preferable that any one of R_{1c} to R_{5c} is a linear or branched alkyl group, a cycloalkyl group or a linear, branched or cyclic alkoxy group; and it is more preferable that the total sum of carbon atoms of R_{1c} to R_{5c} is from 2 to 15. According to this, it is possible to enhance the solvent solubility and to inhibit the generation of a particle at the preservation.

Examples of the alkyl group and the cycloalkyl group represented by Rₓ and R_{y} include the same alkyl group and cycloalkyl group as in R_{1c} to R_{7c}. Above all, a 2-oxoalkyl group, a 2-oxocycloalkyl group and an alkoxycarbonylmethyl group are more preferable.

Examples of the 2-oxoalkyl group and the 2-oxocycloalkyl group include a group having >C═O at the 2-position of each of the alkyl group and the cycloalkyl group represented by R_{1c} to R_{7c}.

Examples of the alkoxy group in the alkoxycarbonylmethyl group include the same alkoxy group represented by R_{1c} to R_{5c}.

Rₓ and R_{y} are each preferably an alkyl group or a cycloalkyl group each having 4 or more carbon atoms, more preferably an alkyl group or a cycloalkyl group each having 6 or more carbon atoms, and further preferably an alkyl group or a cycloalkyl group each having 8 or more carbon atoms.

In the general formulae (ZII) and (ZIII),

R₂₀₄ to R₂₀₇ each independently represents an aryl group, an alkyl group or a cycloalkyl group.

The aryl group represented by R₂₀₄ to R₂₀₇ is preferably a phenyl group or a naphthyl group, and more preferably a phenyl group. The aryl group represented by R₂₀₄ to R₂₀₇ may be an aryl group having a heterocyclic structure having an oxygen atom, a nitrogen atom, a sulfur atom or the like. Examples of the aryl group having a heterocyclic structure include a pyrrole residue (a group formed when one hydrogen atom is lost from pyrrole), a furan residue (a group formed when one hydrogen atom is lost from furan), a thiophene residue (a group formed when one hydrogen atom is lost from thiophene), an indole residue (a group formed when one hydrogen atom is lost from indole), a benzofuran residue (a group formed when one hydrogen atom is lost from benzofuran) and a benzothiophene residue (a group formed when one hydrogen atom is lost from benzothiophene).

Preferred examples of the alkyl group and the cycloalkyl group represented by R₂₀₄ to R₂₀₇ include a linear or branched alkyl group having from 1 to 10 carbon atoms (for example, a methyl group, an ethyl group, a propyl group, a butyl group and a pentyl group) and a cycloalkyl group having from 3 to 10 carbon atoms (for example, a cyclopentyl group, a cyclohexyl group and a norbornyl group).

Each of the aryl group, the alkyl group and the cycloalkyl group represented by R₂₀₄ to R₂₀₇ may have a substituent. Examples of the substituent which each of the aryl group, the alkyl group and the cycloalkyl group represented by R₂₀₄ to R₂₀₇ may have include an alkyl group (for example, one having from 1 to 15 carbon atoms), a cycloalkyl group (for example, one having from 3 to 15 carbon atoms), an aryl group (for example, one having from 6 to 15 carbon atoms), an alkoxy group (for example, one having from 1 to 15 carbon atoms), a halogen atom, a hydroxyl group and a phenylthio group.

Z⁻ represents a non-nucleic anion, and examples thereof include the same non-nucleic anion as in Z⁻ in the general formula (ZI).

As the acid generator, compounds represented by the following general formulae (ZIV), (ZV) and (ZVI) can be further exemplified.

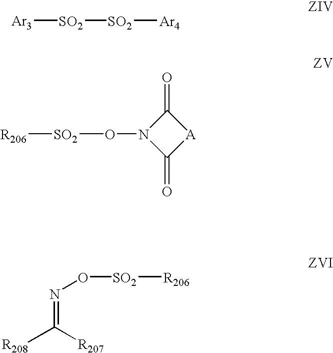

In the general formulae (ZIV) to (ZVI),

Ar₃ and Ar₄ each independently represents an aryl group,

R₂₀₆, R₂₀₇ and R₂₀₈ each independently represents an alkyl group, a cycloalkyl group or an aryl group, and

A represents an alkylene group, an alkenylene group or an arylene group.

Of the acid generators, the compounds represented by the general formulae (ZI) to (ZIII) are more preferable.

Also, the acid generator is preferably a compound capable of generating an acid having one sulfonic group or imide group; more preferably a compound capable of generating a monovalent perfluoroalkanesulfonic acid or a compound capable of generating a monovalent fluorine atom-substituted or fluorine atom-containing group-substituted aromatic sulfonic acid or a compound capable of generating a monovalent fluorine atom-substituted or fluorine atom-containing group-substituted imide acid; and further preferably a fluorine-substituted alkanesulfonic acid, a fluorine-substituted benzenesulfonic acid, a fluorine-substituted imide acid or a sulfonium salt of a fluorine-substituted methide acid. The acid generator which can be used is especially preferably a fluorine-substituted alkanesulfonic acid, a fluorine-substituted benzenesulfonic acid or a fluorine-substituted imide acid in which the generated acid has a pKa of not more than −1. According to this, the sensitivity is enhanced.

Especially preferred examples of the acid generator are given below.

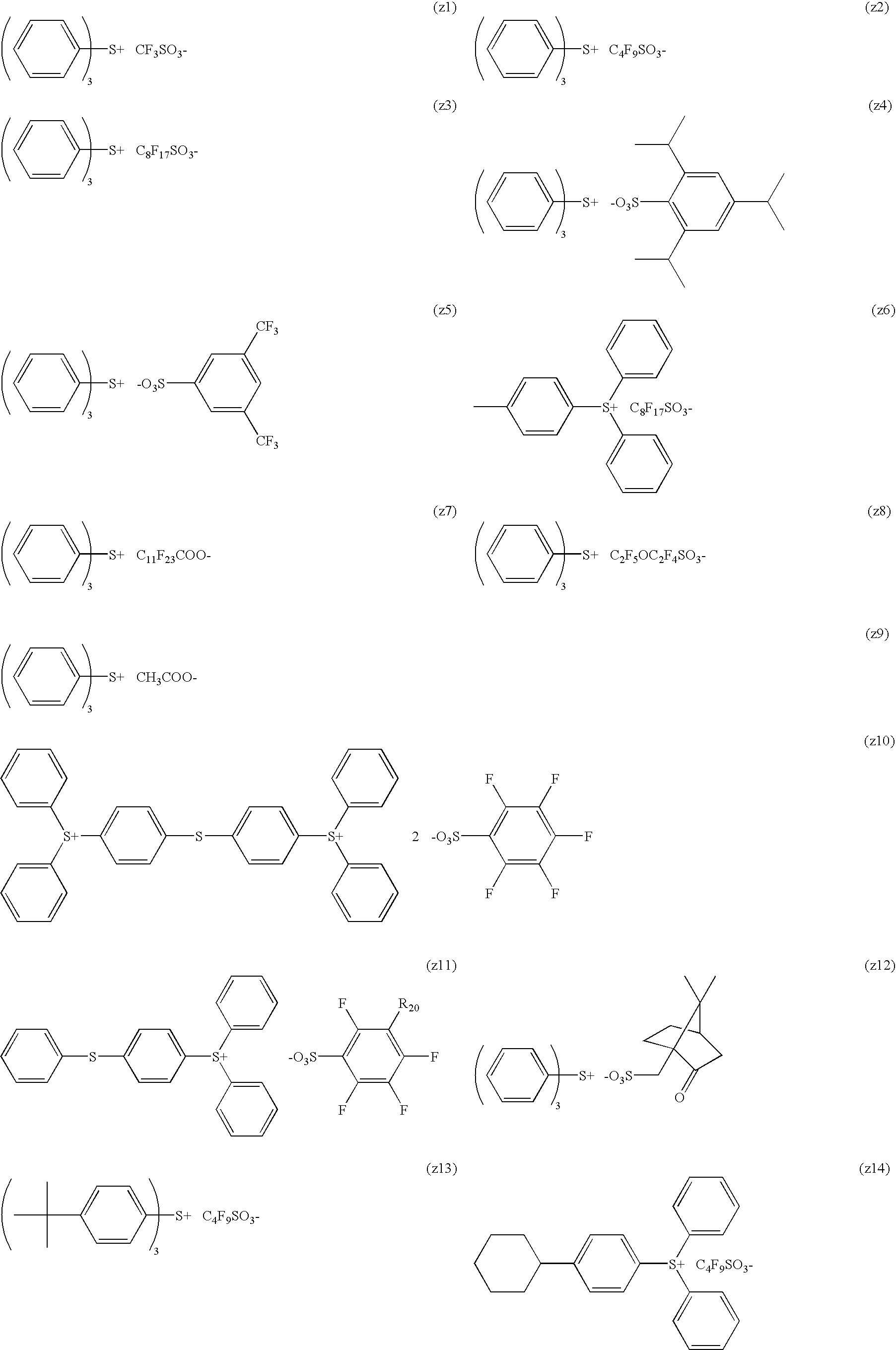

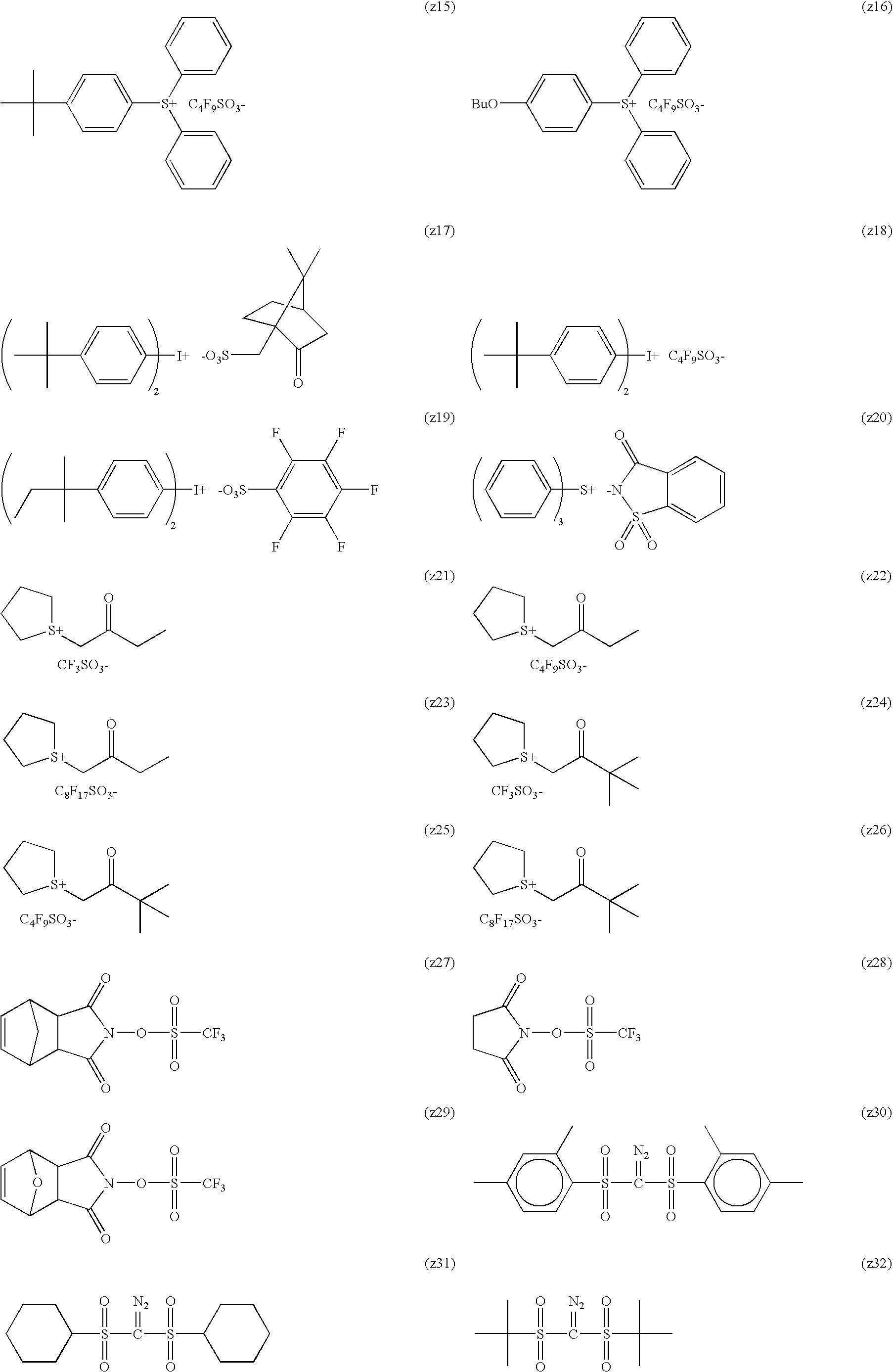

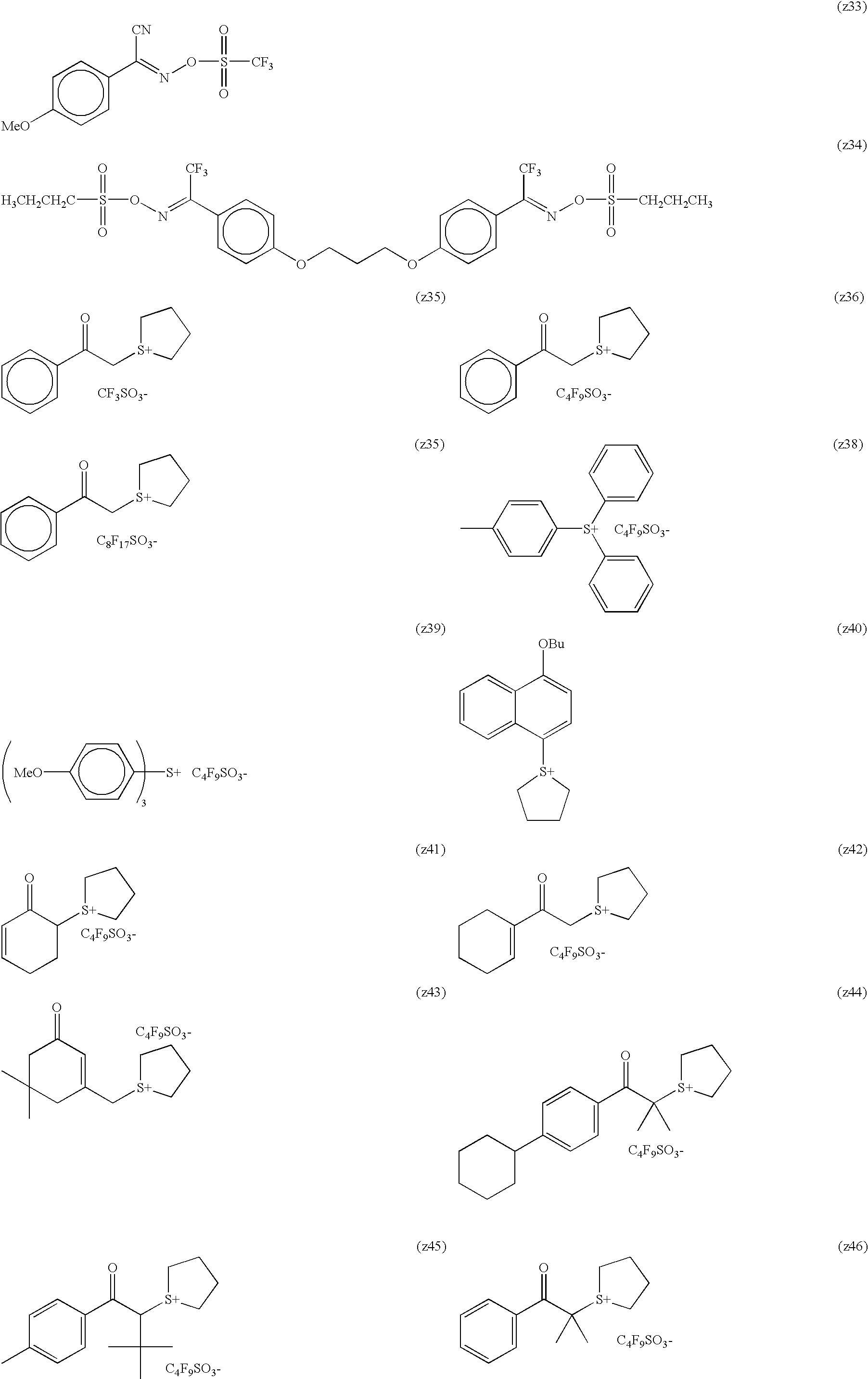

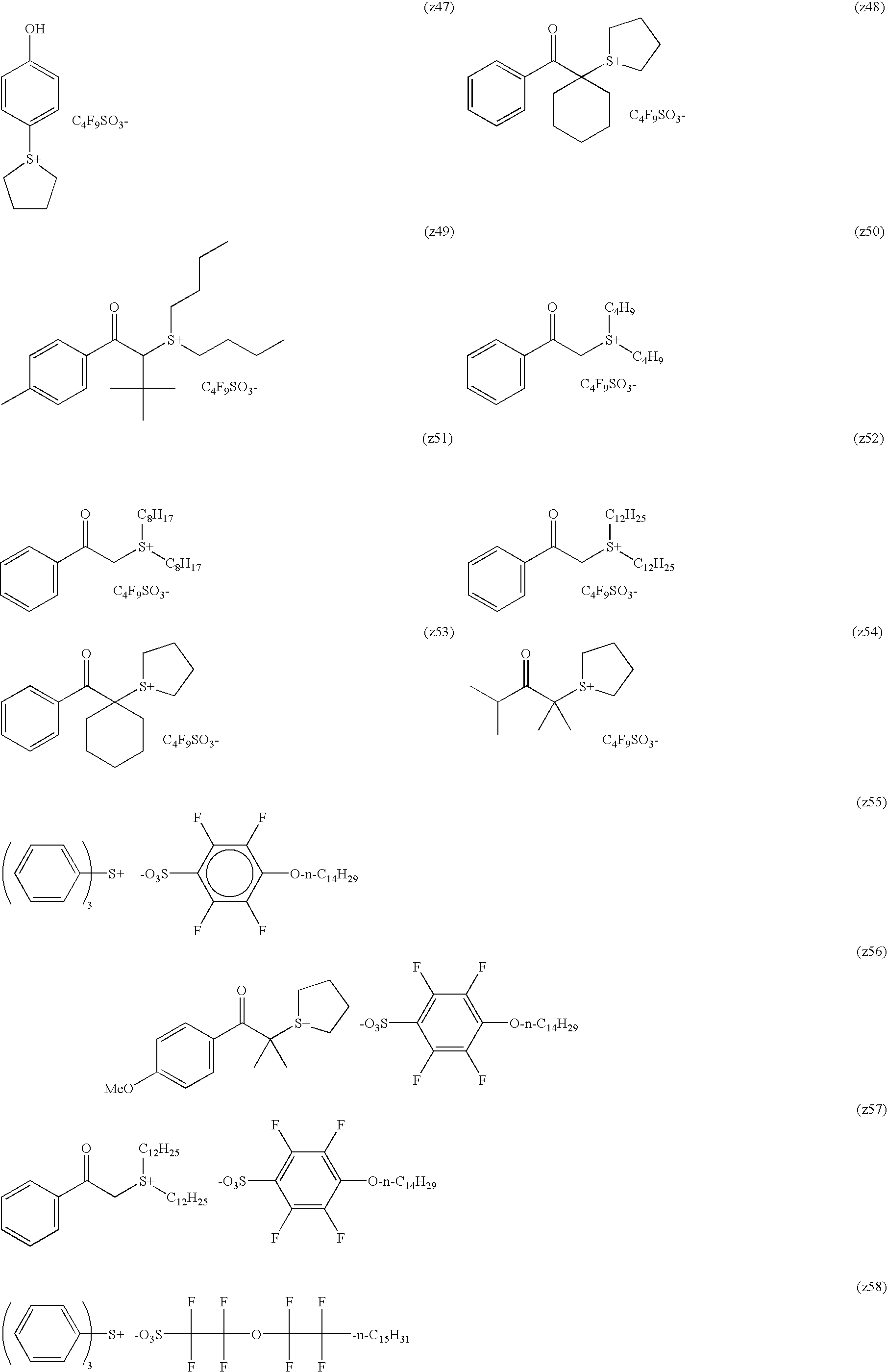

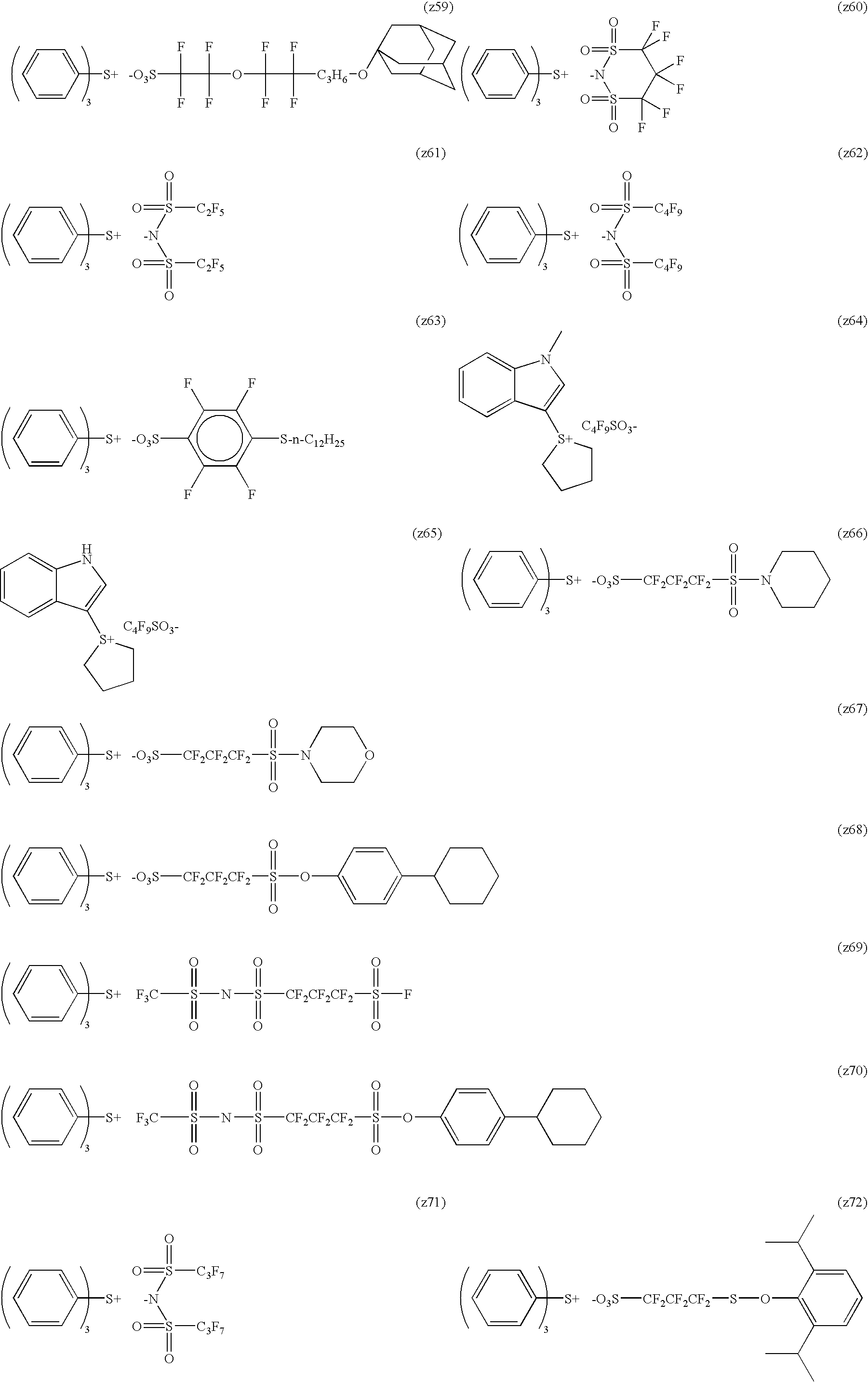

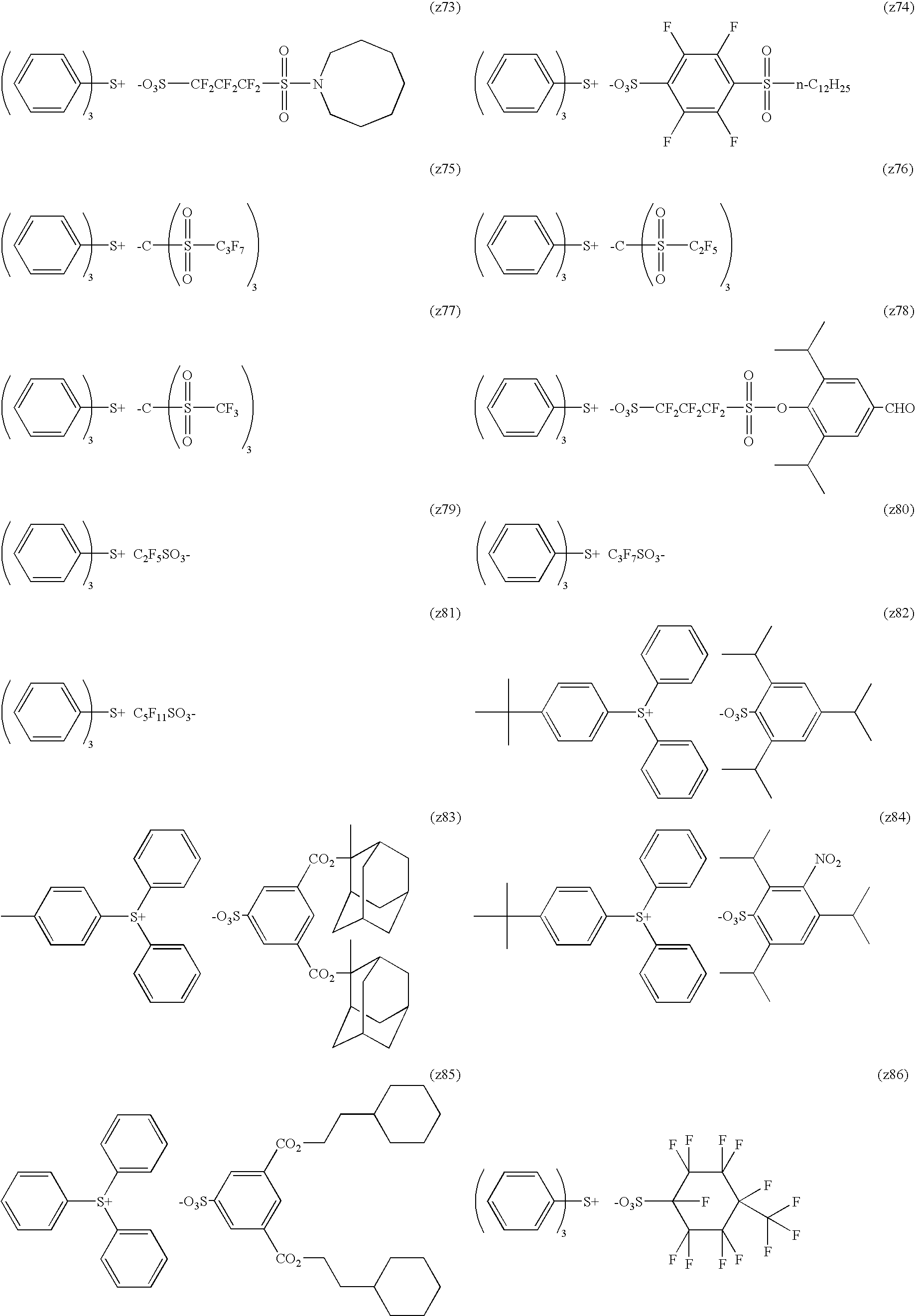

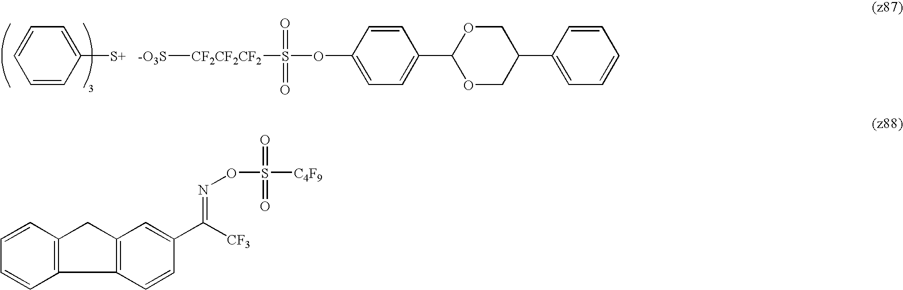

The acid generator can be used singly or in combination of two or more kinds thereof.

The content of the acid generator in the positive working photosensitive composition is preferably from 0.1 to 20% by mass, more preferably from 0.5 to 10% by mass, and further preferably from 1 to 7% by mass on the basis of the whole of the solids of the positive working photosensitive composition.

Basic Compound

For the purpose of reducing the change in performance with time from exposure to heating, it is preferable that the positive working photosensitive composition of the invention contains a basic compound.

Preferred examples of the basic compound include compounds having a structure represented by any of the following formulae (A) to (E).

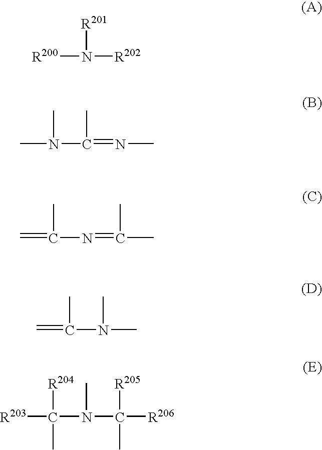

In the general formulae (A) to (E),

R²⁰⁰, R²⁰¹ and R²⁰² may be the same or different and each represents a hydrogen atom, an alkyl group (preferably one having from 1 to 20 carbon atoms), a cycloalkyl group (preferably one having from 3 to 20 carbon atoms) or an aryl group (preferably one having from 6 to 20 carbon atoms). Here, R²⁰¹ and R²⁰² may be taken together to form a ring.

With respect to the foregoing alkyl group, a substituent-containing alkyl group is preferably an aminoalkyl group having from 1 to 20 carbon atoms, a hydroxyalkyl group having from 1 to 20 carbon atoms or a cyanoalkyl group having from 1 to 20 carbon atoms.

R²⁰³, R²⁰⁴, R²⁰⁵ and R²⁰⁶ may be the same or different and each represents an alkyl group having from 1 to 20 carbon atoms.

It is more preferable that the alkyl group in these general formulae (A) to (E) is unsubstituted.

Preferred examples of the compound include guanidine, aminopyrrolidine, pyrazole, pyrazoline, piperazine, aminomorpholine, aminoalkyl morpholines and piperidine; and more preferred examples thereof include compounds having an imidazole structure, a diazabicyclo structure, an onium hydroxide structure, an onium carboxylate structure, a trialkylamine structure, an aniline structure or a pyridine structure, alkylamine derivatives having a hydroxyl group and/or an ether bond and aniline derivatives having a hydroxyl group and/or an ether bond.

Examples of the compound having an imidazole structure include imidazole, 2,4,5-triphenylimidazole and benzimidazole. Examples of the compound having a diazabicyclo structure include 1,4-diazabicyclo[2,2,2]octane, 1,5-di-azabicyclo[4,3,0]nona-5-ene and 1,8-diazabicyclo[5,4,0]undeca-7-ene. Examples of the compound having an onium hydroxide structure include triaryl sulfonium hydroxides, phenacyl sulfonium hydroxides, sulfonium hydroxides having a 2-oxoalkyl group, and specifically triphenyl sulfonium hydroxide, tris(t-butylphenyl)sulfonium hydroxide, bis-(t-butylphenyl)iodonium hydroxide, phenacylthiophenium hydroxide and 2-oxopropylthiophenium hydroxide. The compound having an onium carboxylate structure is a compound having an onium hydroxide structure in which an anion segment thereof is carboxylated; and examples thereof include an acetate, an adamantane-1-carboxylate and a perfluoroalkyl carboxylate. Examples of the compound having a trialkylamine structure include tri(n-butyl)amine and tri(n-octyl)amine. Examples of the aniline compound include 2,6-diisopropylaniline, N,N-dimethylaniline, N,N-dibutylaniline and N,N-dihexylaniline. Examples of the alkylamine derivative having a hydroxyl group and/or an ether bond include ethanolamine, diethanolamine, triethanolamine and tris(methoxyethoxyethyl)amine. Examples of the aniline derivative having a hydroxyl group and/or an ether bond include N,N-bis(hydroxyethyl)aniline.

These basic compounds are used singly or in combination of two or more kinds thereof.

The amount of the basic compound to be used is usually from 0.001 to 10% by mass, and preferably from 0.01 to 5% by mass on the basis of the solids of the positive working photosensitive composition.

A ratio of the acid generator and the basic compound to be used in the composition is preferably from 2.5/1 to 300/1 in terms of an acid generator/basic compound molar ratio. That is, it is preferable in view of the sensitivity and resolution that the molar ratio is 2.5/1 or more; and it is preferable in view of the inhibition of a reduction of the resolution to be caused due to thickening of the resist patter with time from the completion of exposure to the heat treatment that the molar ratio is not more than 300/1. The acid generator/basic compound molar ratio is more preferably from 5.0/1 to 200/1, and further preferably from 7.0/1 to 150/1.

Surfactant

It is preferable that the positive working photosensitive composition of the invention further contains a surfactant; and it is more preferable that the positive working photosensitive composition of the invention contains either one or two or more kinds of fluorine based and/or silicon based surfactants (for example, a fluorine based surfactant, a silicon based surfactant and a surfactant containing both a fluorine atom and a silicon atom).

When the positive working photosensitive composition of the invention contains the foregoing surfactant, it is possible to give a resist pattern with satisfactory sensitivity and resolution and with less adhesiveness and development defect at the time of use of an exposure light source of not more than 250 nm, and especially not more than 220 nm.

Examples of the fluorine based and/or silicon based surfactant include surfactants described in JP-A-62-36663, JP-A-61-226746, JP-A-61-226745, JP-A-62-170950, JP-A-63-34540, JP-A-7-230165, JP-A-8-62834, JP-A-9-54432, JP-A-9-5988, JP-A-2002-277862 and U.S. Pat. Nos. 5,405,720, 5,360,692, 5,529,881, 5,296,330, 5,436,098, 5,576,143, 5,294,511 and 5,824,451. The following commercially available surfactants can also be used as they are.

Examples of the commercially available surfactant which can be used include fluorine based surfactants and silicon based surfactants, for example, EFTOP EF301 and EFTOP EF303 (all of which are manufactured by Shin-Akita Kasei Co., Ltd.); FLUORAD FC430, FLUORAD FC431 and FLUORAD FC4430 (all of which manufactured by Sumitomo 3M Limited); MEGAFAC F171, MEGAFAC F173, MEGAFAC F176, MEGAFAC F189, MEGAFAC F113, MEGAFAC F110, MEGAFAC F177, MEGAFAC F120 and MEGAFAC R08 (all of which are manufactured by Dainippon Ink and Chemicals, Incorporated); SURFLON S-382, SURFLON SC101, SURFLON SC102, SURFLON SC103, SURFLON SC104, SURFLON SC105 and SURFLON SC106 (all of which manufactured by Asahi Glass Co., Ltd.); TROYSOL S-366 (manufactured by Troy Chemical Corporation); GF-300 and GF-150 (all of which are manufactured by Toagosei Co., Ltd.); SURFLON S-393 (manufactured by AGC Seimichemical Co., Ltd.); EFTOP EF121, EFTOP EF122A, EFTOP EF122B, EFTOP EF122C, EFTOP EF125M, EFTOP EF135M, EFTOP EF351, EFTOP EF352, EFTOP EF801, EFTOP EF802 and EFTOP EF601 (all of which are manufactured by Jemco Inc.); PF 636, PF 656, PF 6320 and PF 6520 (all of which are manufactured by OMNOVA Solutions Inc.); and FTX-204D, FTX-208G, FTX-218G, FTX-230G, FTX-204D, FTX-208D, FTX-212D, FTX-218 and FTX-222D (all of which are manufactured by NEOS Company Limited). Also, a polysiloxane polymer, KP-341 (manufactured by Shin-Etsu Chemical Co., Ltd.) can also be used as the silicon based surfactant.

Also, as the surfactant, in addition to the foregoing known surfactants, surfactants using a polymer having a fluoro aliphatic group derived from fluoro aliphatic compounds manufactured by a telomerization method (also called a telomer method) or an oligomerization method (also called an oligomer method) can be used. The fluoro aliphatic compound can be synthesized according to the method disclosed in JP-A-2002-90991.

As the polymer having a fluoro aliphatic group, copolymers of a fluoro aliphatic group-containing monomer and a (poly(oxyalkylene)) acrylate and/or a (poly(oxyalkylene)) methacrylate are preferable; and these monomers may be irregularly distributed or block copolymerized. Also, examples of the poly(oxyalkylene) group include a poly(oxyethylene) group, a poly(oxypropylene) group and a poly(oxybutylene) group. A unit containing alkylenes having a different chain length within the same chain length, such as poly(oxyethylene/oxypropylene/oxyethylene block connected body) and poly(oxyethylene/oxypropylene block connected body) may also be used. Furthermore, the copolymer of a fluoro aliphatic group-containing monomer and a (poly(oxyalkylene)) acrylate (or methacrylate) may be not only a binary copolymer but also a ternary or multi-component copolymer obtainable by simultaneous copolymerization of two or more kinds of different fluoro aliphatic group-containing monomers or two or more kinds of different (poly(oxyalkylene)) acrylates (or methacrylates).

Examples of commercially available surfactants include MEGAFAC F178, MEGAFAC F-470, MEGAFAC F-473, MEGAFAC F-475, MEGAFAC F-476 and MEGAFAC F-472 (all of which are manufactured by Dainippon Ink and Chemicals, Incorporated). Furthermore, examples of the surfactant include a copolymer of a C₆F₁₃ group-containing acrylate (or methacrylate) and a (poly(oxyalkylene)) acrylate (or methacrylate); and a copolymer of a C₃F₇ group-containing acrylate (or methacrylate), (poly(oxyethylene)) acrylate (or methacrylate) and (poly(oxypropylene)) acrylate (or methacrylate).

In the invention, other surfactants than the fluorine based and/or silicon based surfactant can also be used. Specific examples thereof include nonionic surfactants such as polyoxyethylene alkyl ethers (for example, polyoxyethylene lauryl ether, polyoxyethylene stearyl ether, polyoxyethylene cetyl ether and polyoxyethylene oleyl ether), polyoxyethylene alkylaryl ethers (for example, polyoxyethylene octylphenyl ether and polyoxyethylene nonylphenyl ether), polyoxyethylene/polyoxypropylene block copolymers, sorbitan fatty acid esters (for example, sorbitan monolaurate, sorbitan monopalmitate, sorbitan monostearate, sorbitan monooleate, sorbitan trioleate and sorbitan tristearate) and polyoxyethylene sorbitan fatty acid esters (for example, polyoxyethylene sorbitan monolaurate, polyoxyethylene sorbitan monopalmitate, polyoxyethylene sorbitan monostearate, polyoxyethylene sorbitan trioleate and polyoxyethylene sorbitan tristearate).

Such a surfactant may be used singly or may be used in combination of several kinds thereof.

The amount of the surfactant to be used is preferably from 0.01 to 10% by mass, and more preferably from 0.1 to 5% by mass relative to the whole amount (excluding the solvent) of the positive working photosensitive composition.

Hydrophobic Resin

In the case where a photosensitive film composed of the positive working photosensitive composition of the invention is exposed through a liquid immersion medium, it is preferable that a hydrophobic resin (HR) is further added in the positive working photosensitive composition. According to this, the hydrophobic resin (HR) is localized in a photosensitive film surface layer, and in the case where the liquid immersion medium is water, when a photosensitive film is formed, it is possible to enhance a receding contact angle of the photosensitive film surface against water and to enhance the follow-up properties of the liquid immersion water. Any resin is useful as the hydrophobic resin (HR) so far as it is able to enhance the receding contact angle of the surface upon addition, and a resin having at least one of a fluorine atom and a silicon atom is preferable. The receding contact angle of the photosensitive film is preferably from 60° to 90°, and more preferably 70° or more. The addition amount of the hydrophobic resin (HR) can be properly adjusted such that the receding contact angle of the photosensitive film falls within the foregoing range and is preferably from 0.1 to 10% by mass, and more preferably from 0.1 to 5% by mass on the basis of the whole of the solids of the positive working photosensitive composition. Though as described above, the hydrophobic resin (HR) is localized at the interface, different from the surfactant, it is not always required that the hydrophobic resin (HR) has a hydrophilic group within the molecule, and the hydrophobic resin (HR) may not contribute to uniform mixing of a polar/non-polar substance.

The fluorine atom or silicon atom in the hydrophobic resin (HR) may exist in the principal chain of the resin or may be substituted on the side chain.

It is preferable that the hydrophobic resin (HR) is a resin having, as a fluorine atom-containing partial structure, a fluorine atom-containing alkyl group, a fluorine atom-containing cycloalkyl group or a fluorine atom-containing aryl group.

The fluorine atom-containing alkyl group (preferably one having from 1 to 10 carbon atoms, and more preferably one having from 1 to 4 carbon atoms) is a linear or branched alkyl group in which at least one hydrogen atom is substituted with a fluorine atom and may further have other substituent.

The fluorine atom-containing cycloalkyl group is a monocyclic or polycyclic cycloalkyl group in which at least one hydrogen atom is substituted with a fluorine atom and may further have other substituent.

The fluorine atom-containing aryl group is an aryl group (for example, a phenyl group and a naphthyl group) in which at least one hydrogen atom is substituted with a fluorine atom and may further have other substituent.

Examples of the fluorine atom-containing alkyl group, the fluorine atom-containing cycloalkyl group and the fluorine atom-containing aryl group include groups represented by the following general formulae (F2) to (F4), but it should not be construed that the invention is limited thereto.

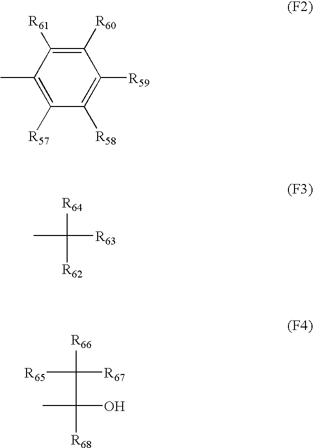

In the general formulae (F2) to (F4),

R₅₇ to R₆₈ each independently represents a hydrogen atom, a fluorine atom or an alkyl group, provided that at least one of R₅₇ to R₆₁, R₆₂ to R₆₄ and R₆₅ to R₆₈ represents a fluorine atom or an alkyl group in which at least one hydrogen atom is substituted with a fluorine atom (preferably one having from 1 to 4 carbon atoms). It is preferable that all of R₅₇ to R₆₁ and R₆₅ to R₆₇ are a fluorine atom. Each of R₆₂, R₆₃ and R₆₈ is preferably an alkyl group in which at least one hydrogen atom is substituted with a fluorine atom (preferably one having from 1 to 4 carbon atoms), and more preferably a perfluoroalkyl group having from 1 to 4 carbon atoms. R₆₂ and R₆₃ may be taken together to form a ring.

Specific examples of the group represented by the general formula (F2) include a p-fluorophenyl group, a pentafluorophenyl group and a 3,5-di(trifluoromethyl)phenyl group.

Specific examples of the group represented by the general formula (F3) include a trifluoromethyl group, a pentafluoropropyl group, a pentafluoroethyl group, a heptafluorobutyl group, a hexafluoroisopropyl group, a heptafluoroisopropyl group, a hexafluoro(2-methyl)isopropyl group, a nonafluorobutyl group, an octafluoroisobutyl group, a nonafluorohexyl group, a nonafluoro-t-butyl group, a perfluoroisopentyl group, a perfluorooctyl group, a perfluoro(trimethyl)hexyl group, a 2,2,3,3-tetrafluorocyclobutyl group and a perfluorocyclohexyl group. Of these, a hexafluoroisopropyl group, a heptafluoroisopropyl group, a hexafluoro(2-methyl)isopropyl group, an octafluoroisobutyl group, a nonafluoro-t-butyl group and a perfluoroisopentyl group are preferable; and a hexafluoroisopropyl group and a heptafluoroisopropyl group are more preferable.

Specific examples of the group represented by the general formula (F4) include —C(CF₃)₂OH, —C(C₂F₅)₂OH, —C(CF₃)(CH₃)OH and —CH(CF₃)OH, with —(CF₃)₂OH being preferable.

Specific examples of the fluorine atom-containing repeating unit are given below, but it should not be construed that the invention is limited thereto.

In the following specific examples, X₁ represents a hydrogen atom, —CH₃, —F or —CF₃; and X₂ represents —F or —CF₃.

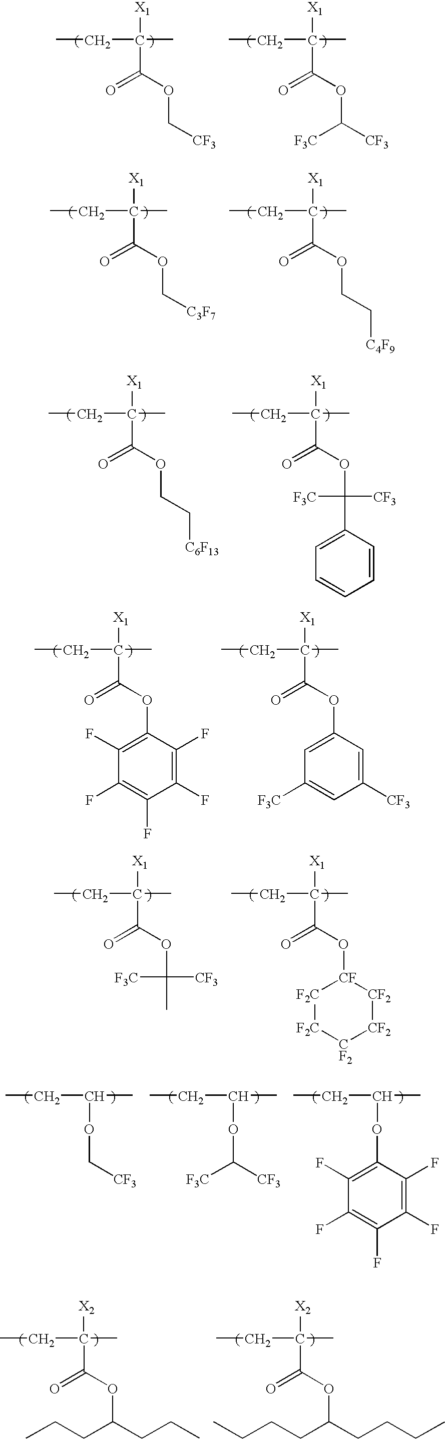

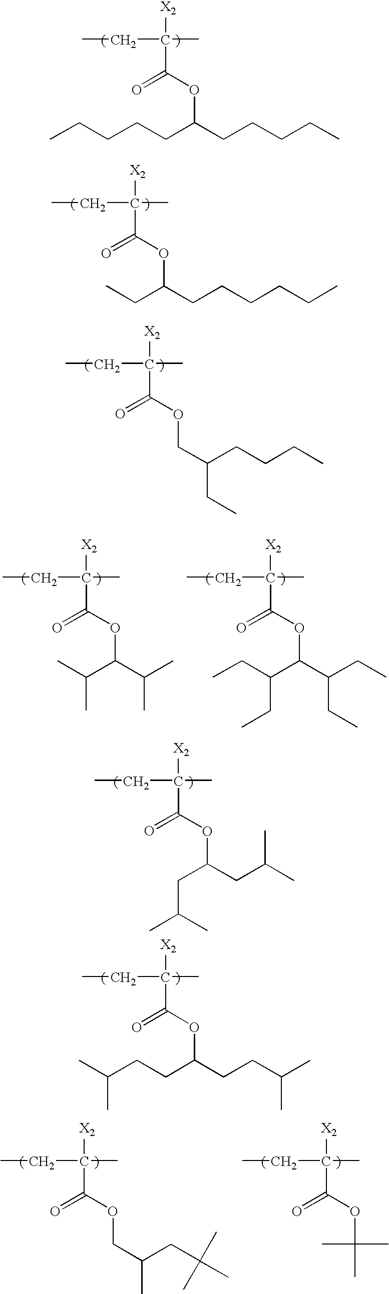

It is preferable that the hydrophobic resin (HR) is a resin having, as a silicon atom-containing partial structure, an alkylsilyl structure (preferably a trialkylsilyl group) or a cyclic cyclohexane structure.

Specific examples of the alkylsilyl structure and the cyclic cyclohexane structure include groups represented by the following general formulae (CS-1) to (CS-3).

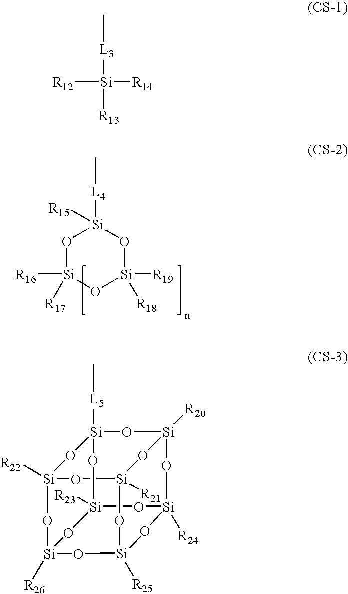

In the general formulae (CS-1) to (CS-3),

R₁₂ to R₂₆ each independently represents a linear or branched alkyl group (preferably one having from 1 to 20 carbon atoms) or a cycloalkyl group (preferably one having from 3 to 20 carbon atoms).

L₃ to L₅ each represents a single bond or a divalent connecting group. Examples of the divalent connecting group include one member selected from the group consisting of an alkylene group, a phenyl group, an ether group, a thioether group, a carbonyl group, an ester group, an amide group, a urethane group and a urea group or a combination of two or more kinds thereof.

Specific examples of the silicon atom-containing repeating unit are given below, but it should not be construed that the invention is limited thereto.

In the following specific examples, X₁ represents a hydrogen atom, —CH₃, —F or —CF₃.

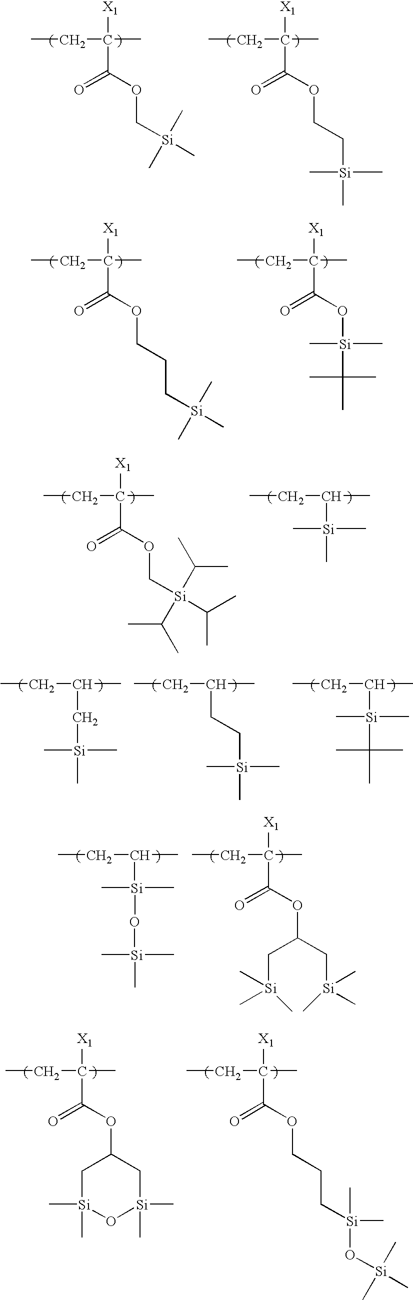

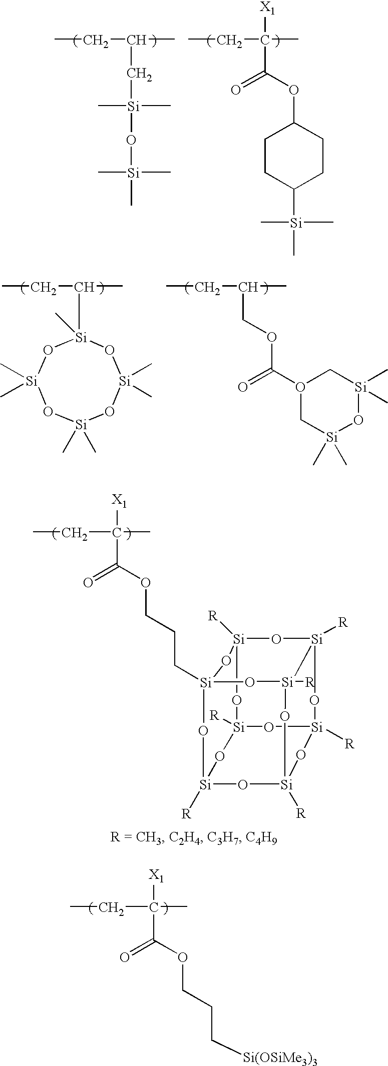

Furthermore, the hydrophobic resin (HR) may have at least one group selected from the group consisting of the following (x) to (z):

(x) an alkali-soluble group,

(y) a group which decomposes by the action of an alkaline developer to increase its solubility in the alkaline developer, and

(z) a group which decomposes by the action of an acid.

Examples of the alkali-soluble group (x) include groups having a phenolic hydroxyl group, a carboxylic group, a fluorinated alcohol group, a sulfonic group, a sulfonamide group, a sulfonylimide group, an (alkylsulfonyl) (alkylcarbonyl)methylene group, an (alkylsulfonyl) (alkylcarbonyl)imide group, a bis(alkylcarbonyl)methylene group, a bis(alkylcarbonyl)imide group, a bis(alkylsulfonyl)methylene group, a bis(alkylsuofonyl)imide group, a tris(alkylcarbonyl)methylene group or a tris(alkylsulfonyl)methylene group.

Preferred examples of the alkali-soluble group include a fluorinated alcohol group (preferably hexafluoroisopropanol), a sulfonimide group and a bis(alkylcarbonyl)methylene group.

As the repeating unit having the alkali-soluble group (x), all of a repeating unit in which an alkali-soluble group is directly bound to the principal chain of a resin, such as a repeating unit by acrylic acid or methacrylic acid; a repeating unit in which an alkali-soluble group is bound to the principal chain of a resin via a connecting group; and a repeating unit in which an alkali-soluble group-containing polymerization initiator or chain transfer agent is used at the time of polymerization and introduced into a terminal end of a polymer chain are preferable.

The content of the repeating unit having the alkali-soluble group (x) is preferably from 1 to 50% by mole, more preferably from 3 to 35% by mole, and further preferably from 5 to 20% by mole relative to the whole of the repeating units in the polymer.

Specific examples of the repeating unit having the alkali-soluble group (x) are given below, but it should not be construed that the invention is limited thereto.

(In the formulae, Rx represents H, CH₃, CF₃ or CH₂OH.)

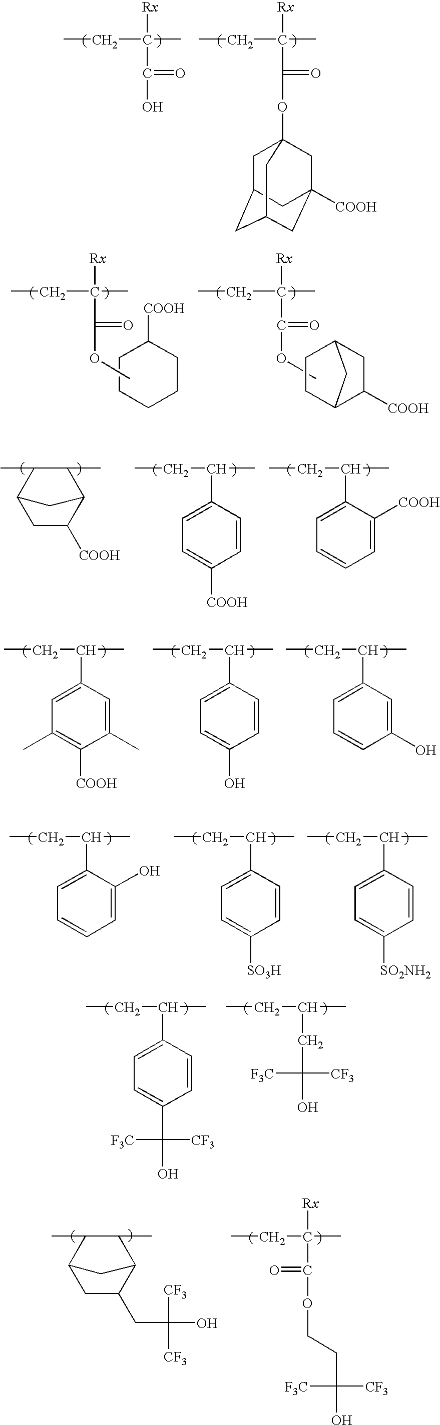

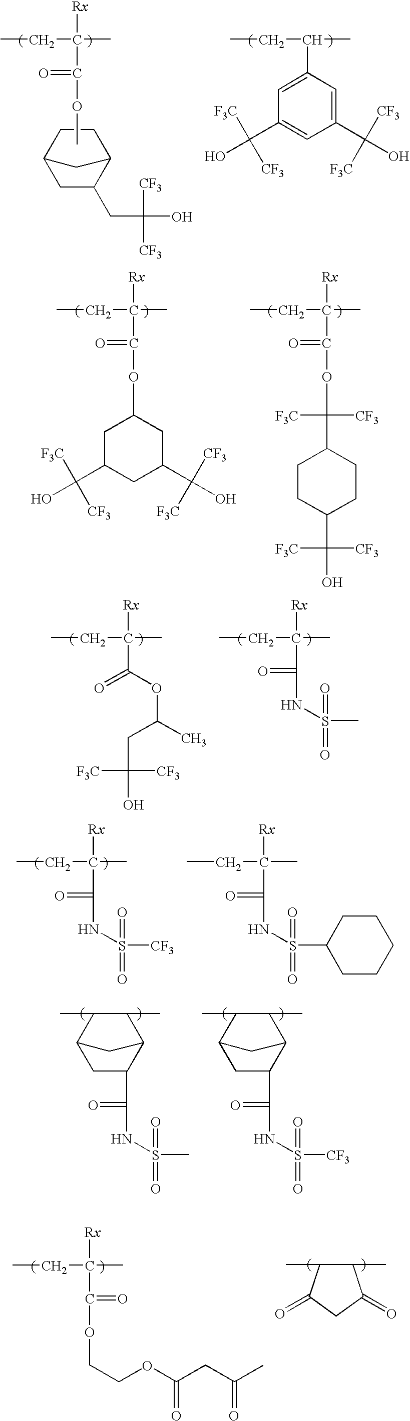

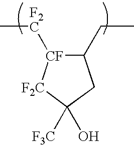

Examples of the group (y) which decomposes by the action of an alkaline developer to increase its solubility in the alkaline developer include a group having a lactone structure, an acid anhydride and an acid imide group. Above all, a lactone group is preferable.

As the repeating unit having the group (y) which decomposes by the action of an alkaline developer to increase its solubility in the alkaline developer, all of a repeating unit in which the group (y) which decomposes by the action of an alkaline developer to increase its solubility in the alkaline developer is directly bound to the principal chain of a resin, such as a repeating unit by an acrylic ester or a methacrylic ester; and a repeating unit in which a polymerization initiator or chain transfer agent having the group (y) which decomposes by the action of an alkaline developer to increase its solubility in the alkaline developer is used at the time of polymerization and introduced into a terminal end of a polymer chain are preferable.

The content of the group (y) which decomposes by the action of an alkaline developer to increase its solubility in the alkaline developer is preferably from 1 to 40% by mole, more preferably from 3 to 30% by mole, and further preferably from 5 to 15% by mole relative to the whole of the repeating units in the polymer.

Specific examples of the group (y) which decomposes by the action of an alkaline developer to increase its solubility in the alkaline developer include the same repeating unit having a lactone structure as exemplified in the resin as the component (A).

In the hydrophobic resin (HR), examples of the repeating unit having the group (z) which decomposes by the action of an acid include the same repeating unit having an acid-decomposable group as exemplified in the component (B). In the hydrophobic resin (HR), the content of the repeating unit having the group (z) which decomposes by the action of an acid is preferably from 1 to 80% by mole, more preferably from 10 to 80% by mole, and further preferably from 20 to 60% by mole relative to the whole of the repeating units in the polymer.

The hydrophobic resin (HR) may further have a repeating unit represented by the following general formula (III).

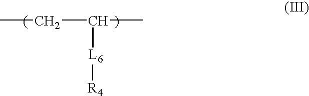

In the general formula (III),

R₄ represents a group having an alkyl group, a cycloalkyl group, an alkenyl group or a cycloalkenyl group, and

L₆ represents a single bond or a divalent connecting group.

In the general formula (III), the alkyl group represented by R₄ is preferably a linear or branched alkyl group having from 3 to 20 carbon atoms.

The cycloalkyl group is preferably a cycloalkyl group having from 3 to 20 carbon atoms.

The alkenyl group is preferably an alkenyl group having from 3 to 20 carbon atoms.

The cycloalkenyl group is preferably a cycloalkenyl group having from 3 to 20 carbon atoms.

The divalent connecting group represented by L₆ is preferably an alkylene group (preferably one having from 1 to 5 carbon atoms) or an oxy group.

In the case where the hydrophobic resin (HR) has a fluorine atom, the content of the fluorine atom is preferably from 5 to 80% by mass, and more preferably from 10 to 80% by mass relative to the molecular weight of the hydrophobic resin (HR). Also, the content of the fluorine atom-containing repeating unit is preferably from 10 to 100% by mass, and more preferably from 30 to 100% by mass in the hydrophobic resin (HR).

In the case where the hydrophobic resin (HR) has a silicon atom, the content of the silicon atom is preferably from 2 to 50% by mass, and more preferably from 2 to 30% by mass relative to the molecular weight of the hydrophobic resin (HR). Also, the content of the silicon atom-containing repeating unit is preferably from 10 to 100% by mass, and more preferably from 20 to 100% by mass in the hydrophobic resin (HR).

A weight average molecular weight, as reduced into standard polystyrene, of the hydrophobic resin (HR) is preferably 1,000 to 100,000, more preferably from 1,000 to 50,000, and further preferably from 2,000 to 15,000.

Similar to the component (B), it is a matter of course that the hydrophobic resin (HR) is low in impurities such as metals. The content of residual monomers or oligomer components is preferably from 0 to 10% by mass, more preferably from 0 to 5% by mass, and further preferably from 0 to 1% by mass. According to this, a resist which is free from foreign substances in the liquid and the change in sensitivity or the like with time is obtained. Also, in view of the resolution, resist shape, side wall of resist pattern, roughness and so on, the molecular weight distribution (Mw/Mn, which is also called “degree of dispersion”) is preferably in the range of from 1 to 5, more preferably in the range of from 1 to 3, and further preferably in the range of from 1 to 2.

As the hydrophobic resin (HR), various commercially available products can be utilized, and the hydrophobic resin (HR) can be synthesized according to the usual way (for example, radical polymerization). Examples of the general synthesis method include a batchwise polymerization method in which a monomer species and an initiator are dissolved in a solvent and the solution is polymerized upon heating; and a dropwise polymerization method in which a solution of a monomer species and an initiator is added dropwise in a heated solvent over from 1 to 10 hours, with a dropwise polymerization method being preferable. Examples of the reaction solvent include ethers (for example, tetrahydrofuran, 1,4-dioxane and diisopropyl ether), ketones (for example, methyl ethyl ketone and methyl isobutyl ketone), ester solvents (for example, ethyl acetate), amide solvents (for example, dimethylformamide and dimethylacetamide) and solvents capable of dissolving the composition of the invention therein as described later (for example, propylene glycol monomethyl ether acetate, propylene glycol monomethyl ether and cyclohexanone). It is more preferable that the polymerization is carried out by using the same solvent as the solvent used in the positive working photosensitive composition of the invention. According to this, it is possible to inhibit the generation of a particle at the preservation.

It is preferable that the polymerization reaction is carried out in an inert gas atmosphere such as nitrogen and argon. The polymerization is initiated by using a commercially available radical initiator (for example, an azo based initiator and a peroxide) as the polymerization initiator. An azo based initiator is preferable as the radical initiator, and an azo based initiator having an ester group, a cyano group or a carboxyl group is preferable. Preferred examples of the initiator include azobisisobutyronitrile, azobisdimethylvaleronitirle and dimethyl 2,2′-azobis(2-methylpropionate). The reaction concentration is from 5 to 50% by mass, and preferably from 30 to 50% by mass. The reaction temperature is usually from 10° C. to 150° C., preferably from 30° C. to 120° C., and more preferably from 60° C. to 100° C.

After completion of the reaction, the reaction mixture is allowed to stand for cooling to room temperature and purified. For the purification, a usual method such as a liquid-liquid extraction method for removing residual monomers and oligomer components by washing with water or combining appropriate solvents; a purification method for achieving purification in a solution state by ultrafiltration for extracting and removing only a substance having a molecular weight of not more than a specified value or other means; a reprecipitation method for removing residual monomers and so on by adding dropwise a resin solution in a poor solvent to solidify the resin in the poor solvent; and a purification method for achieving purification in a solid state by washing a filtered resin slurry with a poor solvent or other means can be applied. For example, by contacting a solvent (poor solvent) in which the foregoing resin is sparingly soluble or insoluble in a volume amount of not more than 10 times, and preferably from 10 to 5 times of the reaction solution, the resin is deposited as a solid.

As the solvent (precipitation or reprecipitation solvent) to be used in the precipitation or reprecipitation operation from the polymer solution, any poor solvent against the polymer is useful and can be properly chosen and used among hydrocarbons, halogenated hydrocarbons, nitro compounds, ethers, ketones, esters, carbonates, alcohols, carboxylic acids, water and mixed solvents containing these solvents and so on depending upon the kind of the polymer. Of these, a solvent containing at least an alcohol (especially, methanol or the like) or water is preferable as the precipitation or reprecipitation solvent.

The amount of the precipitation or reprecipitation solvent to be used can be properly chosen while taking into consideration the efficiency or yield or the like and is generally from 100 to 10,000 parts by mass, preferably from 200 to 2,000 parts by mass, and more preferably from 300 to 1,000 parts by mass based on 100 parts by mass of the polymer solution.

The temperature in the precipitation or reprecipitation can be properly chosen while taking into consideration the efficiency or operability and is usually from about 0 to 50° C., and preferably around room temperature (for example, from about 20 to 35° C.). The precipitation or reprecipitation operation can be achieved by using a customary mixing vessel such as a stirring tank in a known method such as a batchwise mode and a continuous mode.

The precipitated or reprecipitated polymer is usually subjected to customary solid-liquid separation such as filtration and centrifugation, dried and then provided for use. The filtration is carried out preferably under a pressure by using a solvent-resistant filter medium. The drying is carried out at a temperature of from about 30 to 100° C., and preferably from about 30 to 50° C. at atmospheric pressure or under a reduced pressure (preferably under a reduced pressure).

After once depositing the resin and separating it, the resin may be again dissolved in the solvent and then brought into contact with a solvent in which the resin is sparingly soluble or insoluble. That is, a method including a step of, after completion of the foregoing radical polymerization reaction, bringing the reaction mixture into contact with a solvent in which the polymer is sparingly soluble or insoluble to deposit the resin (step a); a step of separating the resin from the solution (step b); a step of again dissolving the resin in the solvent to prepare a resin solution A (step c); a step of thereafter, bringing the resin solution A into contact with a solvent in which the resin is sparingly soluble or insoluble in a volume amount of less than 10 times of the resin solution A (preferably in a volume amount of not more than 5 times of the resin solution A) to deposit a resin solid (step d); and a step of separating the deposited resin (step e) may be employed.

Specific examples of the hydrophobic resin (HR) are given below. Also, molar ratios of repeating units (corresponding to the respective repeating units in the order from the left side), weight average molecular weights and degrees of dispersion in the respective resins are shown in the following Table 1.

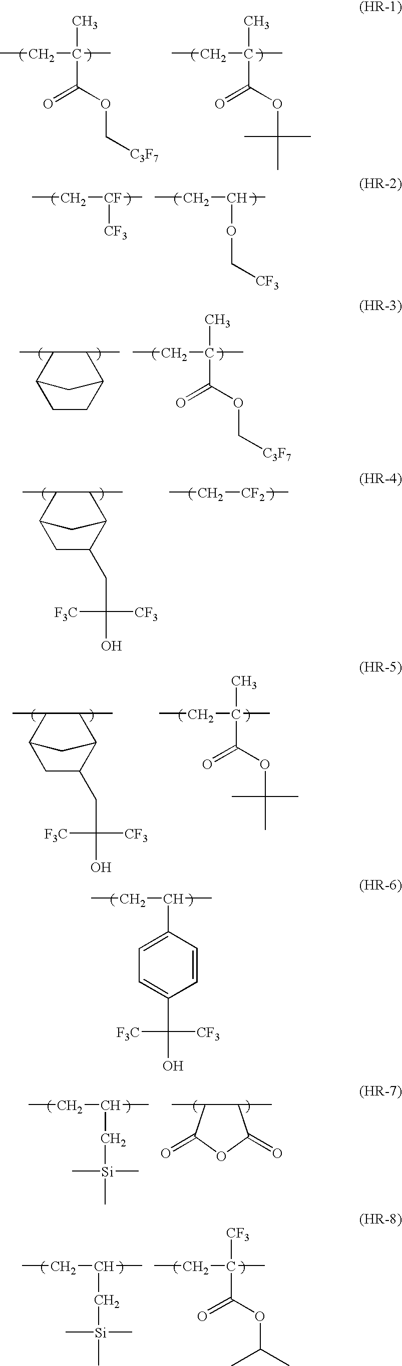

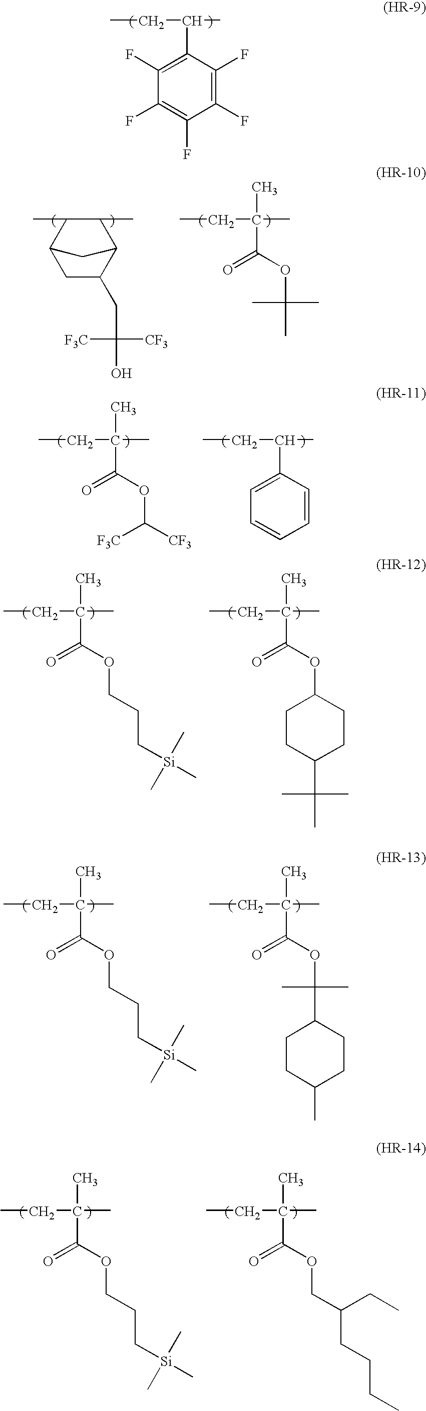

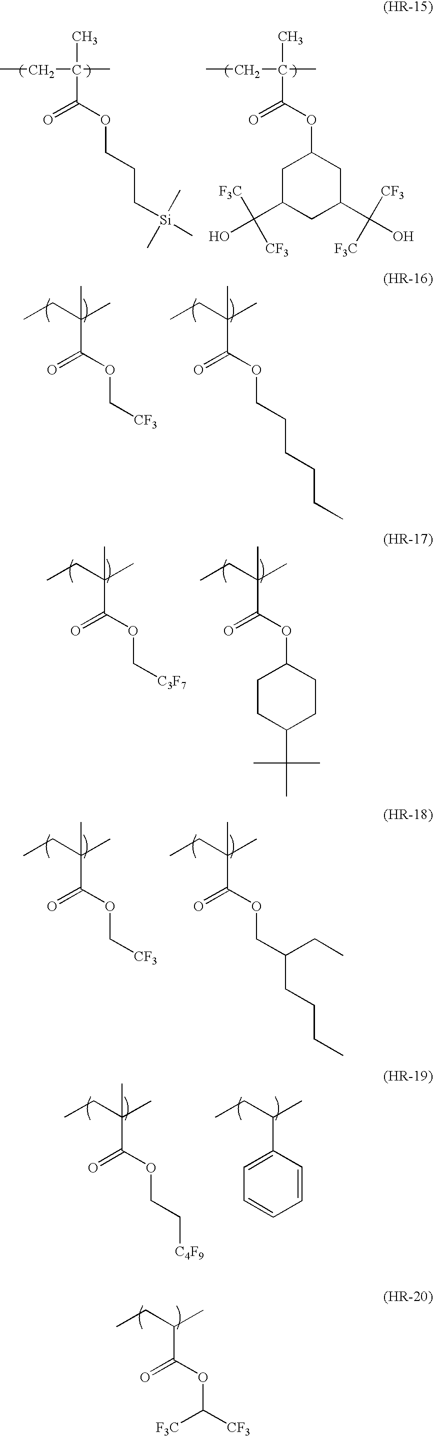

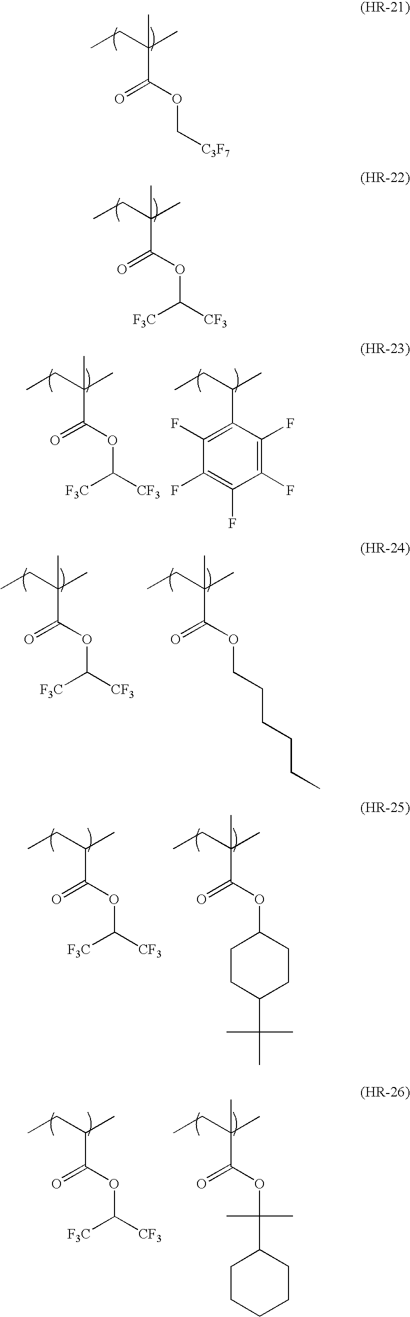

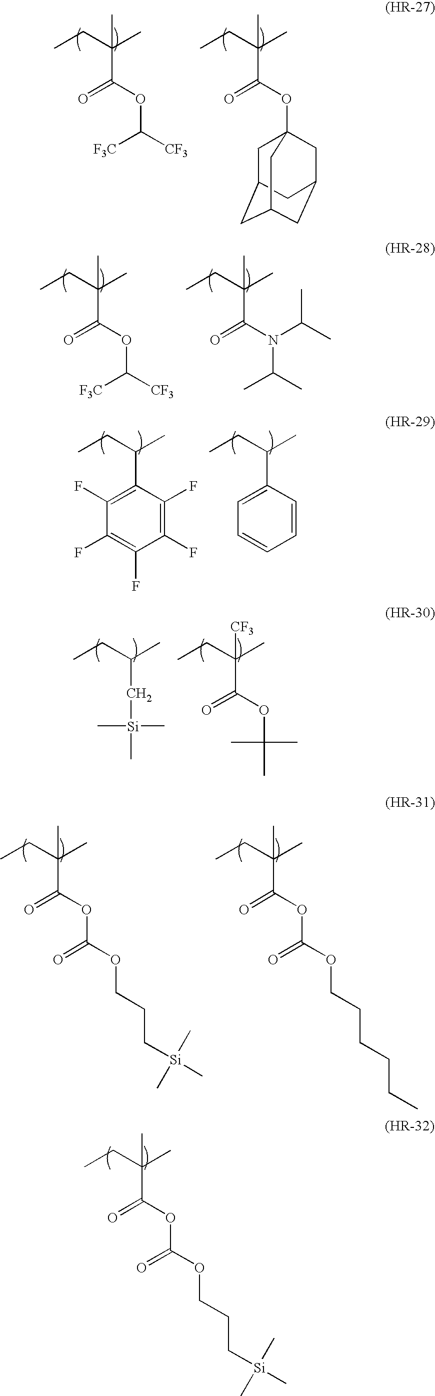

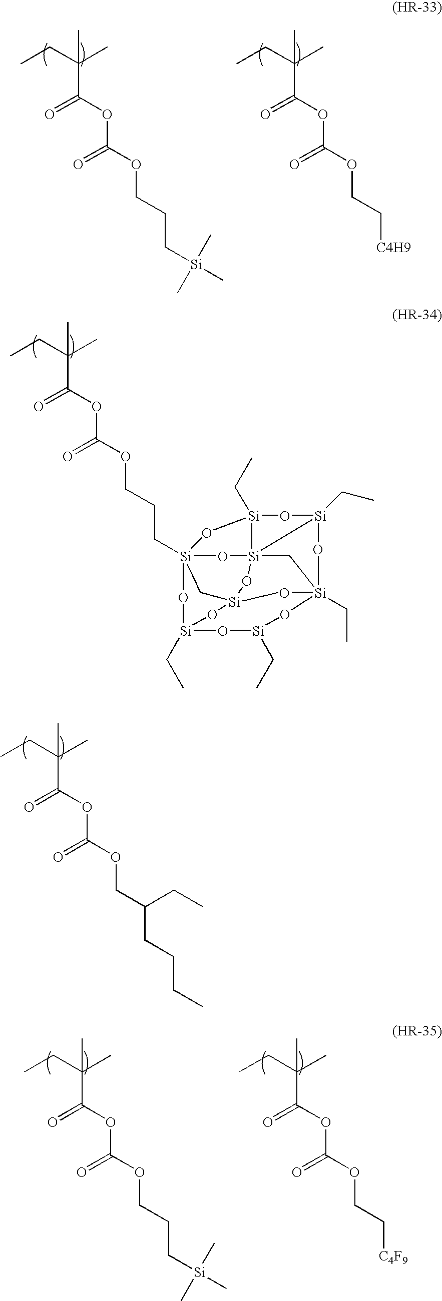

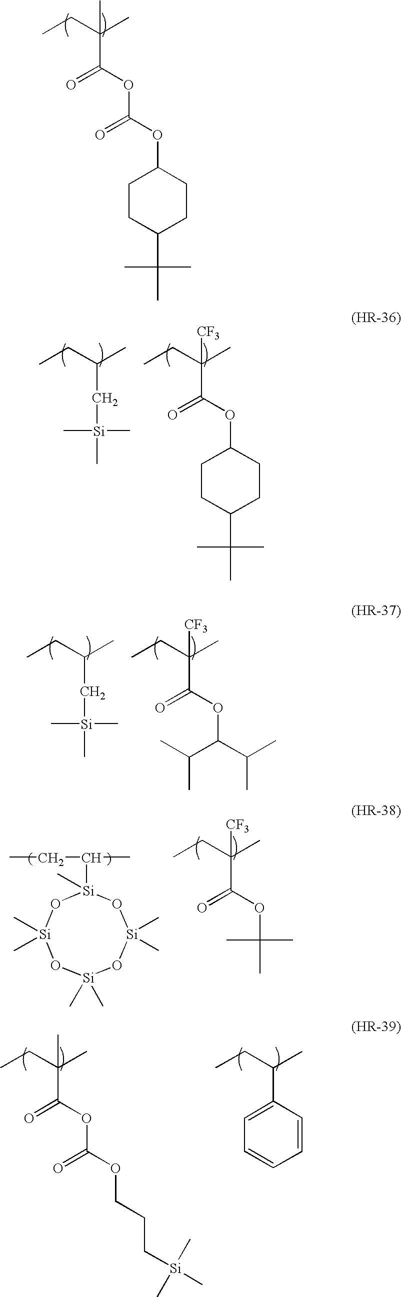

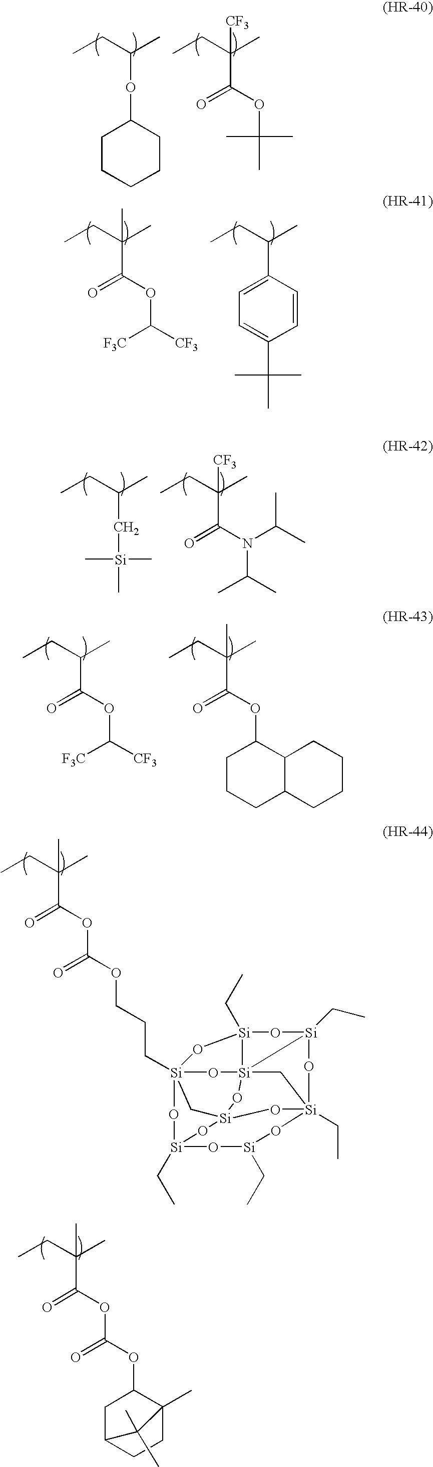

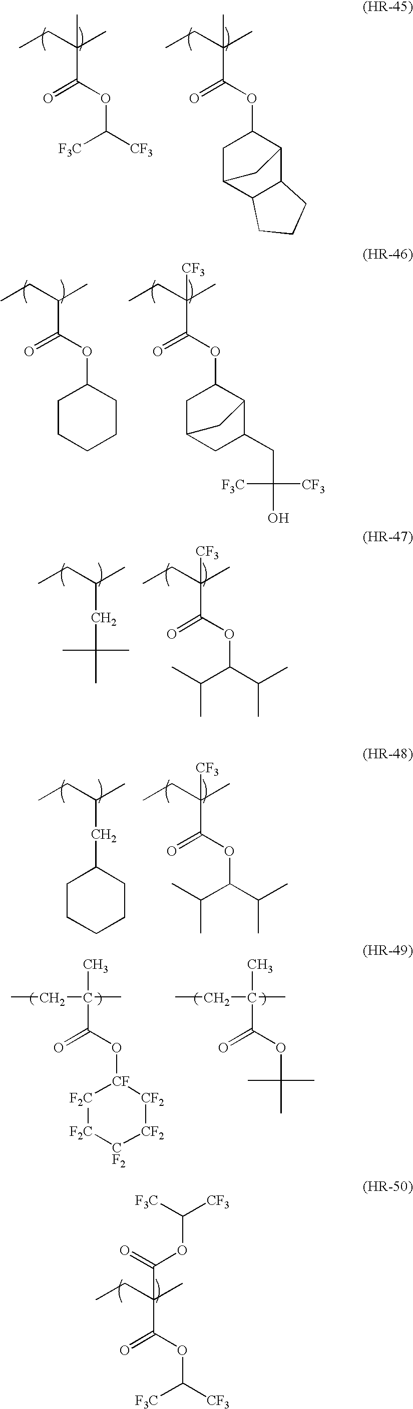

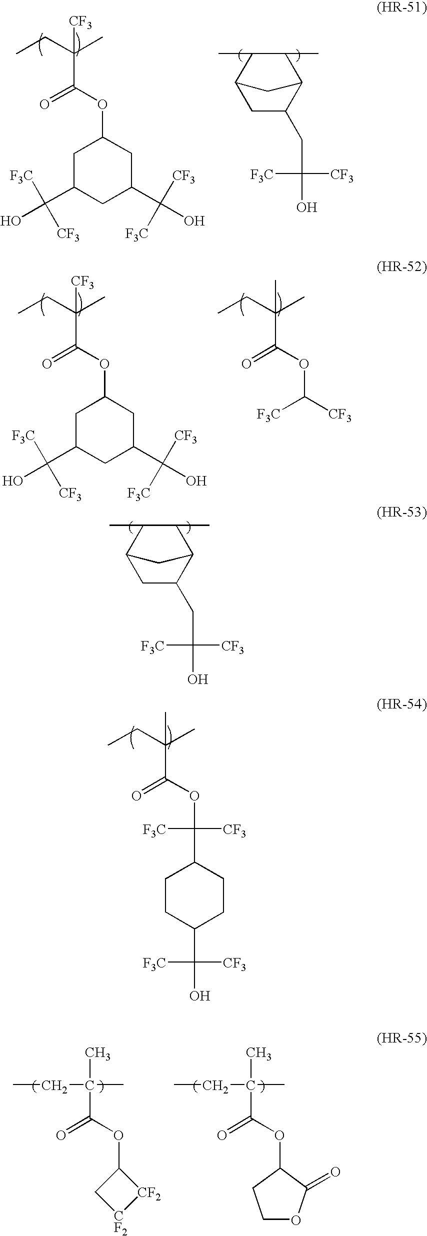

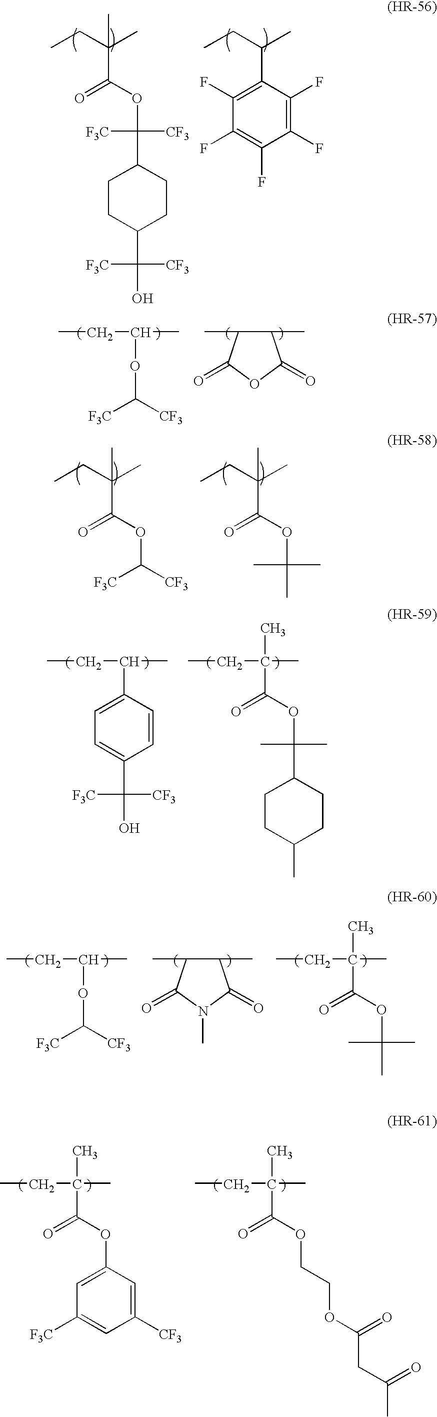

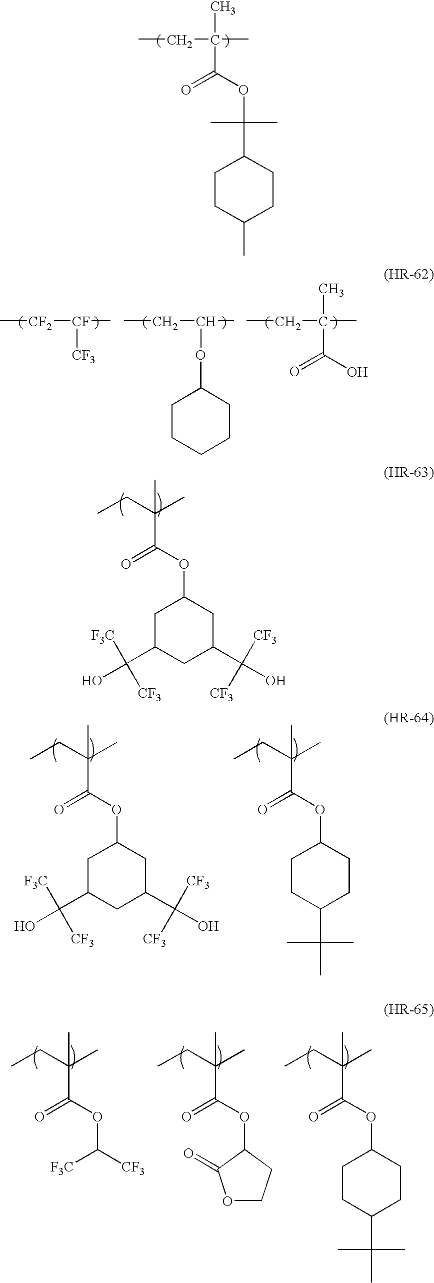

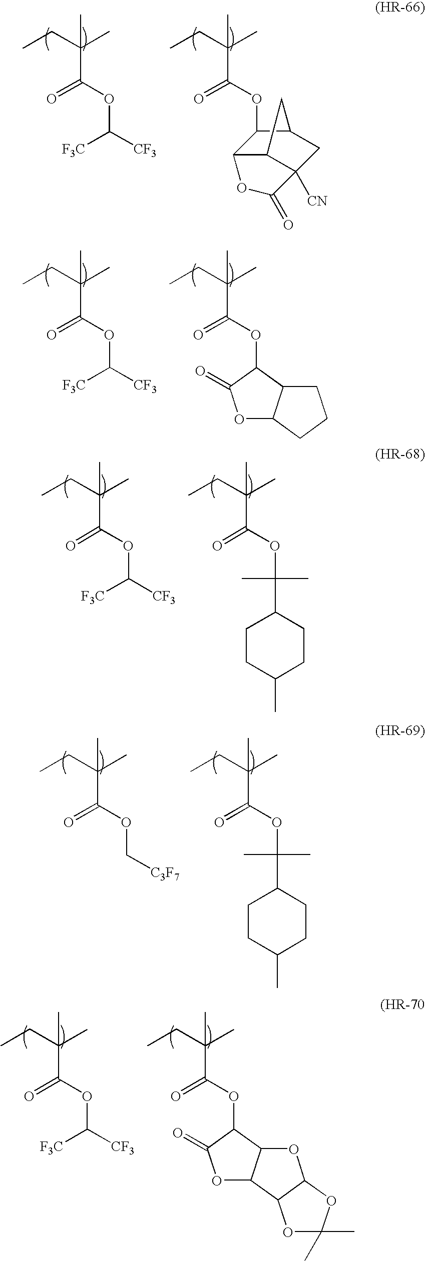

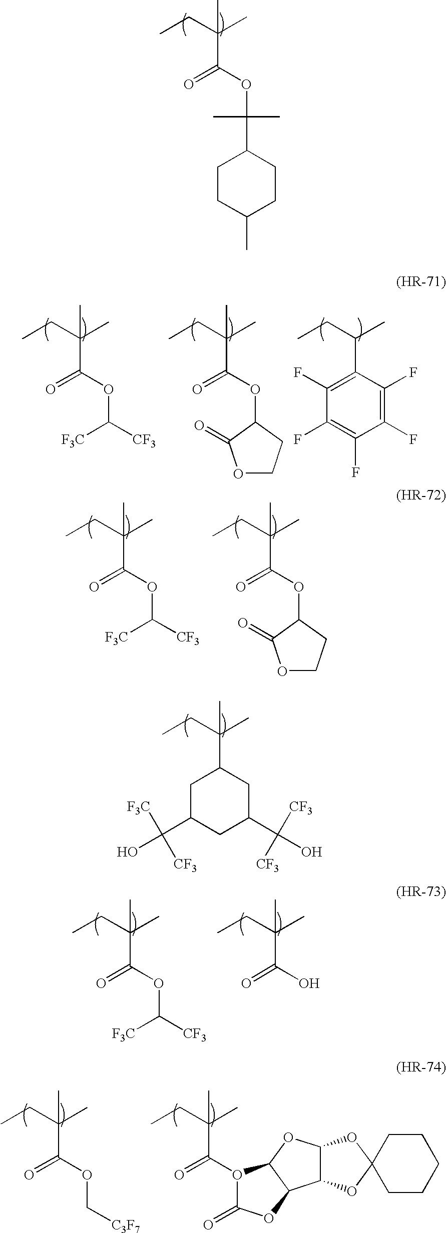

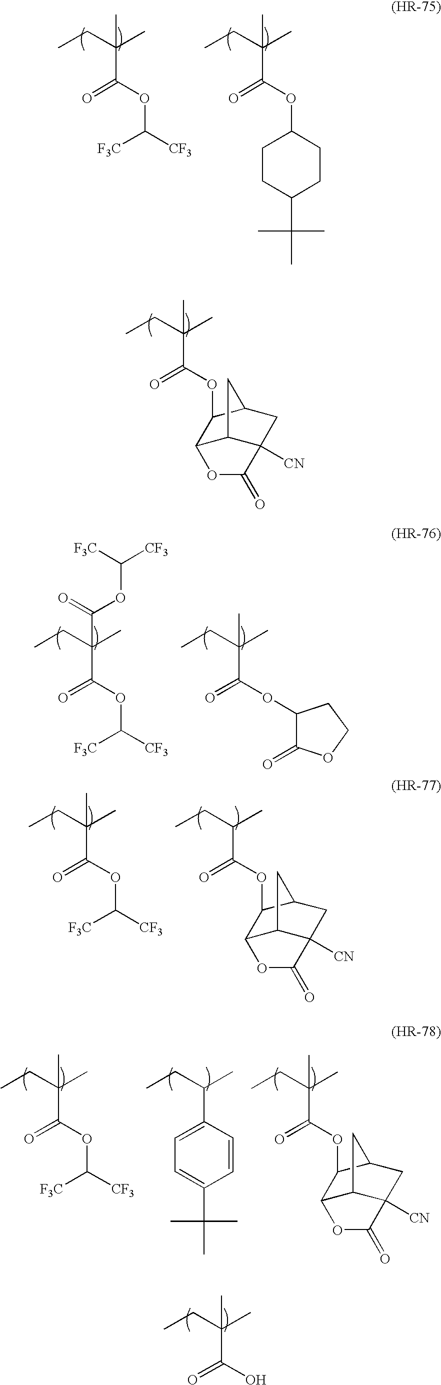

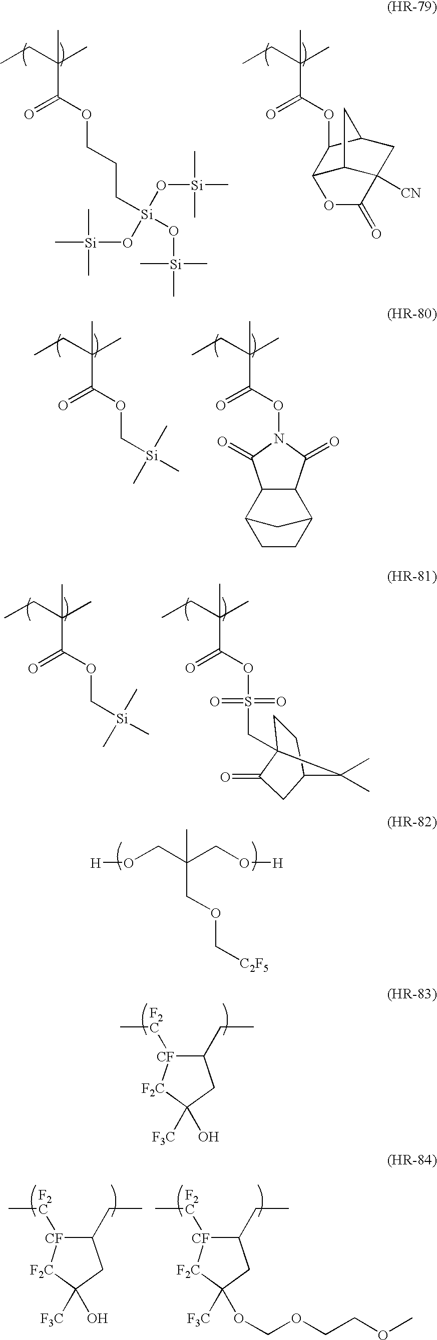

TABLE 1

| Resin | Composition | Mw | Mw/Mn |
|---|---|---|---|
| HR-1 | 50/50 | 8800 | 2.1 |
| HR-2 | 50/50 | 5200 | 1.8 |
| HR-3 | 50/50 | 4800 | 1.9 |
| HR-4 | 50/50 | 5300 | 1.9 |
| HR-5 | 50/50 | 6200 | 1.9 |
| HR-6 | 100 | 12000 | 2.0 |
| HR-7 | 50/50 | 5800 | 1.9 |
| HR-8 | 50/50 | 6300 | 1.9 |
| HR-9 | 100 | 5500 | 2.0 |
| HR-10 | 50/50 | 7500 | 1.9 |
| HR-11 | 70/30 | 10200 | 2.2 |
| HR-12 | 40/60 | 15000 | 2.2 |
| HR-13 | 40/60 | 13000 | 2.2 |
| HR-14 | 80/20 | 11000 | 2.2 |
| HR-15 | 60/40 | 9800 | 2.2 |
| HR-16 | 50/50 | 8000 | 2.2 |
| HR-17 | 50/50 | 7600 | 2.0 |
| HR-18 | 50/50 | 12000 | 2.0 |
| HR-19 | 20/80 | 6500 | 1.8 |
| HR-20 | 100 | 6500 | 1.2 |
| HR-21 | 100 | 6000 | 1.6 |
| HR-22 | 100 | 2000 | 1.6 |
| HR-23 | 50/50 | 6000 | 1.7 |
| HR-24 | 50/50 | 8800 | 1.9 |
| HR-25 | 50/50 | 7800 | 2.0 |
| HR-26 | 50/50 | 8000 | 2.0 |
| HR-27 | 80/20 | 8000 | 1.8 |
| HR-28 | 30/70 | 7000 | 1.7 |
| HR-29 | 50/50 | 6500 | 1.6 |
| HR-30 | 50/50 | 6500 | 1.6 |
| HR-31 | 50/50 | 9000 | 1.8 |
| HR-32 | 100 | 10000 | 1.6 |
| HR-33 | 70/30 | 8000 | 2.0 |
| HR-34 | 10/90 | 8000 | 1.8 |
| HR-35 | 30/30/40 | 9000 | 2.0 |
| HR-36 | 50/50 | 6000 | 1.4 |
| HR-37 | 50/50 | 5500 | 1.5 |
| HR-38 | 50/50 | 4800 | 1.8 |
| HR-39 | 60/40 | 5200 | 1.8 |
| HR-40 | 50/50 | 8000 | 1.5 |
| HR-41 | 20/80 | 7500 | 1.8 |
| HR-42 | 50/50 | 6200 | 1.6 |
| HR-43 | 60/40 | 16000 | 1.8 |
| HR-44 | 80/20 | 10200 | 1.8 |
| HR-45 | 50/50 | 12000 | 2.6 |
| HR-46 | 50/50 | 10900 | 1.9 |
| HR-47 | 50/50 | 6000 | 1.4 |
| HR-48 | 50/50 | 4500 | 1.4 |
| HR-49 | 50/50 | 6900 | 1.9 |
| HR-50 | 100 | 2300 | 2.6 |
| HR-51 | 60/40 | 8800 | 1.5 |
| HR-52 | 68/32 | 11000 | 1.7 |
| HR-53 | 100 | 8000 | 1.4 |
| HR-54 | 100 | 8500 | 1.4 |
| HR-55 | 80/20 | 13000 | 2.1 |
| HR-56 | 70/30 | 18000 | 2.3 |
| HR-57 | 50/50 | 5200 | 1.9 |
| HR-58 | 50/50 | 10200 | 2.2 |
| HR-59 | 60/40 | 7200 | 2.2 |
| HR-60 | 32/32/36 | 5600 | 2.0 |
| HR-61 | 30/30/40 | 9600 | 1.6 |
| HR-62 | 40/40/20 | 12000 | 2.0 |
| HR-63 | 100 | 6800 | 1.6 |
| HR-64 | 50/50 | 7900 | 1.9 |
| HR-65 | 40/30/30 | 5600 | 2.1 |
| HR-66 | 50/50 | 6800 | 1.7 |
| HR-67 | 50/50 | 5900 | 1.6 |
| HR-68 | 49/51 | 6200 | 1.8 |
| HR-69 | 50/50 | 8000 | 1.9 |
| HR-70 | 30/40/30 | 9600 | 2.3 |
| HR-71 | 30/40/30 | 9200 | 2.0 |
| HR-72 | 40/29/31 | 3200 | 2.1 |
| HR-73 | 90/10 | 6500 | 2.2 |
| HR-74 | 50/50 | 7900 | 1.9 |
| HR-75 | 20/30/50 | 10800 | 1.6 |
| HR-76 | 50/50 | 2200 | 1.9 |
| HR-77 | 50/50 | 5900 | 2.1 |
| HR-78 | 40/20/30/10 | 14000 | 2.2 |
| HR-79 | 50/50 | 5500 | 1.8 |
| HR-80 | 50/50 | 10600 | 1.9 |
| HR-81 | 50/50 | 8600 | 2.3 |
| HR-82 | 100 | 15000 | 2.1 |
| HR-83 | 100 | 6900 | 2.5 |
| HR-84 | 50/50 | 9900 | 2.3 |

Dissolution Inhibitor

The positive working photosensitive composition of the invention may contain a dissolution inhibiting compound having a molecular weight of not more than 3,000, which decomposes by the action of an acid to increase its solubility in an alkaline developer.

As the dissolution inhibiting compound having a molecular weight of not more than 3,000, which decomposes by the action of an acid to increase its solubility in an alkaline developer (this compound will also be simply referred to as “dissolution inhibiting compound”), in order that the transmittance to light of not more than 220 nm may not be reduced, an acid-decomposable group-containing alicyclic or aliphatic compound, such as acid-decomposable group-containing cholic acid derivatives as described in Proceeding of SPIE, 2724, 355 (1996), is preferable. With respect to the acid-decomposable group and the alicyclic structure, the same as described above in the component (B) can be referred to herein.

In the invention, the molecular weight of the dissolution inhibiting compound is not more than 3,000, preferably from 300 to 3,000, and more preferably from 500 to 2,500.

The addition amount of the dissolution inhibiting compound is preferably from 1 to 30% by mass, and more preferably from 2 to 20% by mass relative to the solids of the positive working photosensitive composition.

Specific examples of the dissolution inhibiting compound are given below, but it should not be construed that the invention is limited thereto.

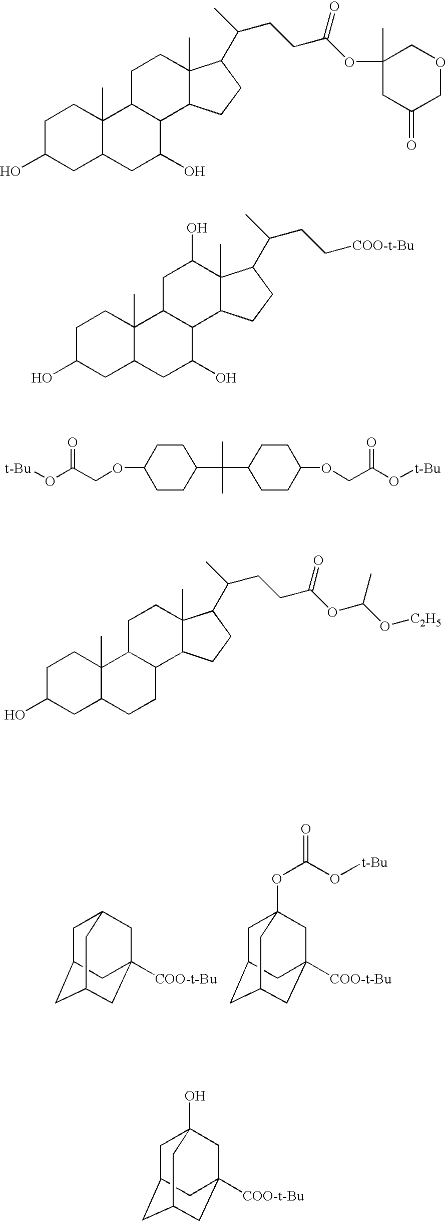

Carboxylic Acid Onium Salt

The positive working photosensitive composition of the invention may contain a carboxylic acid onium salt.

Examples of the carboxylic acid onium salt include a carboxylic acid sulfonium salt, a carboxylic acid iodonium salt and a carboxylic acid ammonium salt. In particular, an iodonium salt and a sulfonium salt are preferable as the carboxylic acid onium salt. Furthermore, it is preferable that a carboxylate residue of the carboxylic acid onium salt of the invention does not contain an aromatic group or a carbon-carbon double bond. In particular, a linear, branched, monocyclic or polycyclic cyclic alkyl carboxylic acid anion having from 1 to 30 carbon atoms is especially preferable as the anion segment. Furthermore, an anion of a carboxylic acid in which a part or all of the alkyl groups are substituted with fluorine is preferable. An oxygen atom may be contained in the alkyl chain. According to this, the transparency to light of not more than 220 nm is ensured, the sensitivity and resolving power are enhanced, and the density distribution dependency and exposure margin are improved.

Examples of the anion of the fluorine-substituted carboxylic acid include anions of fluoroacetic acid, difluoroacetic acid, trifluoroacetic acid, pentafluoropropionic acid, heptafluorobutyric acid, nonafluoropentanoic acid, perfluorododecanoic acid, perfluorotridecanoic acid, perfluorocyclohexanecarboxylic acid or 2,2-bistrifluoro-methylpropionic acid.

Such a carboxylic acid onium salt can be synthesized by allowing sulfonium hydroxide, iodonium hydroxide or ammonium hydroxide and a carboxylic acid to react with silver oxide in an appropriate solvent.

The content of the carboxylic acid onium salt in the composition is generally from 0.1 to 20% by mass, preferably from 0.5 to 10% by mass, and more preferably from 1 to 7% by mass relative to the whole of the solids of the composition.

Organic Solvent

The positive working photosensitive composition of the invention is used by dissolving the foregoing components in a prescribed organic solvent.

Examples of the useful organic solvent include ethylene dichloride, cycloxanone, cyclopentanone, 2-heptanone, γ-butyrolactone, methyl ethyl ketone, ethylene glycol monomethyl ether, ethylene glycol monoethyl ether, 2-methoxyethyl acetate, ethylene glycol monoethyl ether acetate, propylene glycol monomethyl ether, propylene glycol monomethyl ether acetate, toluene, ethyl acetate, methyl lactate, ethyl lactate, methyl methoxypropionate, ethyl ethoxypropionate, methyl pyruvate, ethyl pyruvate, propyl pyruvate, N,N-dimethylformamide, dimethyl sulfoxide, N-methylpyrrolidone, methoxybutanol and tetrahydrofuran.

In the invention, a mixed solvent obtained by mixing a solvent having a hydroxyl group in a structure thereof and a solvent not having a hydroxyl group may be used as the organic solvent.

Examples of the solvent having a hydroxyl group include ethylene glycol, ethylene glycol monomethyl ether, ethylene glycol monoethyl ether, propylene glycol, propylene glycol monomethyl ether, propylene glycol monoethyl ether and ethyl lactate. Of these, propylene glycol monomethyl ether and ethyl lactate are preferable.

Examples of the solvent not having a hydroxyl group include propylene glycol monomethyl ether acetate, ethyl ethoxypropionate, 2-heptanone, γ-butyrolactone, cyclohexanone, butyl acetate, N-methylpyrrolidone, N,N-dimethylacetamide and dimethyl sulfoxide. Of these, propylene glycol monomethyl ether acetate, ethyl ethoxypropionate, 2-heptanone, γ-butyrolactone, cyclohexanone and butyl acetate are preferable; and propylene glycol monomethyl ether acetate, ethyl ethoxypropionate and 2-heptanone are more preferable.

A mixing ratio (mass ratio) of the solvent having a hydroxyl group to the solvent not having a hydroxyl group is preferably from 1/99 to 99/1, more preferably from 10/90 to 90/10, and further preferably from 20/80 to 60/40. A mixed solvent containing 50% by mass or more of the solvent not having a hydroxyl group is especially preferable in view of the coating uniformity.

Other Additives

The positive working photosensitive composition of the invention can contain a dye, a plasticizer, a photosensitizer, a compound capable of accelerating the dissolution in the developing solution and so on as the need arises.

A dissolution accelerating compound in the developing solution which can be used in the invention is a low-molecular weight compound having two or more phenolic OH groups or one or more carboxyl groups and having a molecular weight of not more than 1,000. In the case where the compound has a carboxyl group, the compound is preferably an alicyclic or aliphatic compound.

The addition amount of such a dissolution accelerating compound is preferably from 2 to 50% by mass, and more preferably from 5 to 30% by mass relative to the component (B). What the addition amount of such a dissolution accelerating compound falls within the foregoing range is preferable in view of a development residue and a pattern at the time of development.

The phenol compound having a molecular weight of not more than 1,000 can be easily synthesized by those skilled in the art by referring to a method as described in, for example, JP-A-4-122938, JP-A-2-28531, U.S. Pat. No. 4,916,210 and European Patent No. 219,294.

Specific examples of the carboxyl group-containing alicyclic or aliphatic compound include carboxylic acid derivatives having a steroid structure, such as cholic acid, deoxycholic acid and lithocholic acid, adamantanecarboxylic acid derivatives, adamantanedicarboxylic acid, cyclohexanecarboxylic acid and cyclohexanedicarboxylic acid. However, it should not be construed that the invention is limited thereto.

(Use Method)

From the viewpoint of enhancing the resolving power, the positive working photosensitive composition of the invention is preferably used in a film thickness of from 30 to 250 nm, and more preferably used in a film thickness of from 30 to 200 nm. By setting up the solids concentration in the positive working photosensitive composition at an appropriate range to bring a suitable viscosity and enhance the coating properties and fabrication properties, it is possible to make the positive working photosensitive composition of the invention have the foregoing film thickness.

The concentration of the whole of the solids in the positive working photosensitive composition is generally from 1 to 10% by mass, more preferably from 1 to 8.0% by mass, and further preferably from 1.0 to 6.0% by mass.

The positive working photosensitive composition of the invention is used by dissolving the foregoing components in a prescribed organic solvent, and preferably the foregoing mixed solvent, subjecting the solution to filter filtration and then coating on a prescribed support in the following manner.

A filter which is used for the filter filtration is preferably a filter made of polytetrafluoroethylene, polyethylene or nylon and having an opening of not more than 0.1 micron, more preferably not more than 0.05 microns, and further preferably not more than 0.03 microns.

For example, the positive working photosensitive composition is coated on a substrate to be used for the manufacture of large scale integrated circuits (for example, a silicon/silicon dioxide coating film) in an appropriate coating method using a spinner, a coater or the like and then dried to form a photosensitive film.

The photosensitive film is irradiated with actinic rays or radiation through a prescribed mask, and preferably baked (heated), followed by development and rinsing. A satisfactory pattern can be thus obtained.

Examples of the actinic rays or radiation include infrared light, visible light, ultraviolet light, far ultraviolet light, X-rays and an electron beam. Of these, far ultraviolet light having a wavelength of not more than 250 nm is preferable; far ultraviolet light having a wavelength of not more than 220 nm is more preferable; and far ultraviolet light having a wavelength of from 1 to 200 nm is especially preferable. Specific examples thereof include a KrF excimer laser (248 nm), an ArF excimer laser (193 nm), an F₂ excimer laser (157 nm), X-rays and an electron beam. Of these, an ArF excimer laser, an F₂ excimer laser, EUV (13 nm) and an electron beam are preferable.

Prior to the formation of a photosensitive film, an antireflection film may be provided in advance on the substrate.

As the antireflection film, all of an inorganic film type made of titanium, titanium dioxide, titanium nitride, chromium oxide, carbon, amorphous silicon or the like and an organic film type made of a light absorber and a polymer material can be used. Also, commercially available organic antireflection films, for example, DUV-30 Series and DUV-40 Series (all of which are manufactured by Brewers Science, Ltd.) and AR-2, AR-3 and AR-5 (all of which are manufactured by Shipley Co.) can be used.

Exposure (liquid immersion exposure) may be carried out by filling a liquid (liquid immersion medium) having a higher refractive index than air between a photosensitive film and a lens at the irradiation with actinic rays or radiation. According to this, the resolution can be enhanced. Any liquid having a higher refractive index than air can be used as the liquid immersion medium to be used, and pure water is preferable.

The liquid immersion liquid which is used for the liquid immersion exposure is hereunder described.

The liquid immersion liquid is preferably a liquid which is transparent to the exposure wavelength and which has a temperature coefficient of refractive index as small as possible so as to keep a strain of an optical image to be projected on the resist film to a minimum. In particular, in the case where the exposure light source is an ArF excimer laser (wavelength: 193 nm), it is preferable to use water in view of easiness of availability and easiness of handling in addition to the foregoing viewpoints.

Also, in view of the matter that the refractive index can be further enhanced, a medium having a refractive index of 1.5 or more can be used. This medium may be an aqueous solution or an organic solvent.

In the case where water is used as the liquid immersion liquid, for the purposes of not only reducing the surface tension of water but increasing the surface-active power, an additive (liquid) which does not dissolve the resist film on a wafer therein and in which influences against an optical coating on the lower surface of a lens device are negligible may be added in a slight proportion. An aliphatic alcohol having a refractive index substantially equal to water is preferable as the additive. Specific examples thereof include methyl alcohol, ethyl alcohol and isopropyl alcohol. By adding an alcohol having a refractive index substantially equal to water, even when the content of the alcohol component in water changes due to the vaporization, there is obtained an advantage that the change in refractive index as the whole of the liquid can be made extremely small. On the other hand, in the case where a substance which is opaque to light of 193 nm or an impurity having a largely different refractive index from water is incorporated, since a strain of the optical image to be projected on the resist film is brought, distilled water is preferable as the water to be used. Furthermore, pure water obtained by filtration through an ion exchange filter or other means may be used.

It is desirable that the water has electrical resistance of 18.3 MQcm or more and TOC (total organic carbon) of not more than 20 ppb and is subjected to a deaeration treatment.

Also, by enhancing the refractive index of the liquid immersion liquid, it is possible to enhance the lithography performance. From such a viewpoint, an additive capable of enhancing the refractive index may be added in water, or heavy water (D₂O) may be used in place of the water.

In order that the photosensitive film may not be brought into direct contact with the liquid immersion liquid, a film which is sparingly soluble in the liquid immersion liquid (hereinafter also referred to as “top coat”) may be provided between the photosensitive film composed of the positive working photosensitive composition of the invention and the liquid immersion liquid. Examples of functions necessary for the top coat include coating properness to a resist upper layer part, transparency to radiation, especially light of 193 nm and sparing solubility in the liquid immersion liquid. It is preferable that the top coat does not mix with the resist and can be uniformly coated on the resist upper layer.

From the viewpoint of the transparency to light of 193 nm, a polymer which does not contain an abundant amount of an aromatic moiety is preferable as the top coat. Specific examples thereof include hydrocarbon polymers, acrylic ester polymers, polymethacrylic acid, polyacrylic acid, polyvinyl ether, silicon-containing polymers and fluorine-containing polymers. The foregoing hydrophobic resin (HR) is also suitable as the top coat. From the viewpoint of the matter that when impurities elute from the top coat into the liquid immersion liquid, they stain an optical lens, it is preferable that the amount of residual monomer components of the polymer contained in the top coat is low.

In releasing the top coat, a developing solution may be used, or a release agent may be separately used. A solvent having low penetration into the photosensitive film is preferable as the release agent. In view of the matter that the release step can be carried out simultaneously with the development treatment step of the photosensitive film, it is preferable that the top coat can be released with an alkaline developer. From the viewpoint of releasing the top coat with an alkaline developer, it is preferable that the top coat is acidic. However, from the viewpoint of non-intermix properties with the photosensitive film, the top coat may be neutral or alkaline.

When there is no difference in refractive index between the top coat and the liquid immersion liquid, the resolution is enhanced. In an ArF excimer laser (wavelength: 193 nm), in the case where water is used as the liquid immersion liquid, it is preferable that the top coat for ArF liquid immersion exposure has a refractive index close to the liquid immersion liquid. From the viewpoint of making the top coat have a refractive index close to the liquid immersion liquid, it is preferable that the top coat has a fluorine atom. Also, from the viewpoints of the transparency and refractive index, a thin film is preferable as the top coat.

It is preferable that the top coat neither mixes with the photosensitive film nor mixes with the liquid immersion liquid. From this viewpoint, in the case where the liquid immersion liquid is water, it is preferable that a solvent to be used in the top coat is a medium which is sparingly soluble in the solvent to be used in the positive working photosensitive composition and insoluble in water. Furthermore, in the case where the liquid immersion liquid is an organic solvent, the top coat may be soluble in water or insoluble in water.

The positive working photosensitive composition of the invention may be applied to a multilayered resist process (in particular, a three-layered resist process). The multi-layered resist method includes the following process.

(a) A lower resist layer composed of an organic material is formed on a substrate to be processed.

(b) An interlayer and an upper resist layer composed of an organic material which crosslinks or decomposes upon irradiation with radiation are successively stacked on the lower resist layer.

(c) After forming a prescribed pattern on the upper resist layer, the interlayer, the lower layer and the substrate are successively etched.

An organopolysiloxane (silicone resin) or an SiO₂ coating solution (SOG) is generally used as the interlayer. Though an appropriated organic high-molecular weight film is used as the lower resist layer, various known photoresists may be used. Examples thereof include respective series such as FH Series and FHi Series (all of which are manufactured by Fujifilm Arch Co., Ltd.) or PFI Series (manufactured by Sumitomo Chemical Co., Ltd.).

A film thickness of the lower resist layer is preferably from 0.1 to 4.0 μm, more preferably from 0.2 to 2.0 μm, and especially preferably from 0.25 to 1.5 μm. What the film thickness of the lower resist layer is 0.1 μm or more is preferable from the viewpoints of antireflection and anti-dry etching properties, and what it is not more than 4.0 μm is preferable from the viewpoints of the aspect ratio and pattern collapse of a formed fine pattern.

In a development step, the alkaline developer is used in the following manner. Examples of the alkaline developer of the positive working photosensitive composition which can be used include alkaline aqueous solutions of an inorganic alkali (for example, sodium hydroxide, potassium hydroxide, sodium carbonate, sodium silicate, sodium metasilicate and ammonia water), a primary amine (for example, ethylamine and n-propylamine), a secondary amine (for example, diethylamine and di-n-butylamine), a tertiary amine (for example, triethylamine and methyldiethylamine), an alcoholamine (for example, dimethylethanolamine and triethanolamine), a quaternary ammonium salt (for example, tetramethylammonium hydroxide and tetraethylammonium hydroxide) or a cyclic amine (for example, pyrrole and piperidine).

Furthermore, suitable amounts of an alcohol and a surfactant can be added and used in the foregoing alkaline developer.

An alkali concentration of the alkaline developer is usually from 0.1 to 20% by mass.

A pH of the alkaline developer is usually from 10.0 to 15.0.

Furthermore, suitable amounts of an alcohol and a surfactant can also be added and used in the foregoing alkaline aqueous solution.

Pure water can be used as a rinse solution, and a suitable amount of a surfactant can also be added and used.

Also, after the development treatment and rinse treatment, the developing solution or rinse solution deposited on the pattern can be subjected to a removal treatment with a supercritical fluid.

### EXAMPLES

The invention is hereunder described with reference to the following Examples, but it should not be construed that the invention is limited thereto.

### Synthesis Examples 1

### Synthesis of Resin (1)

10 g of cyclohexanone was charged into a three-necked flask under a nitrogen gas stream and heated at 80° C. A solution of 1.8 g of Polymerizable Compound (I-1), 9.9 g of 2-methyl-2-adamantyl methacrylate, 3.8 g of monohydroxyadamantyl methacrylate, 9.4 g of norbornane lactone methacrylate and 13% by mole relative to the monomer of a polymerization initiator, V-601 (manufactured by Wako Pure Chemical Industries, Ltd.) in 90 g of cyclohexanone was added dropwise thereto over 6 hours. After completion of the dropwise addition, the mixture was further allowed to react at 80° C. for 2 hours. The reaction mixture was allowed to stand for cooling, and a mixed solution of 900 mL of methanol and 100 mL of water was then added dropwise thereto over 20 minutes. A deposited powder was collected by filtration and dried to obtain 20.4 g of Resin (1). The resulting Resin (1) had a weight average molecular weight as reduced into standard polystyrene of 8,600 and a degree of dispersion (Mw/Mn) of 1.8.

Resins (2) to (14) were synthesized in the same procedures. The weight average molecular weight was adjusted by changing the amount of the polymerization initiator. Polymerizable Compounds (I-1) to (I-4) necessary for the synthesis were each synthesized in conformity with a method described in Seriya Khimicheskaya, Volume 10, page 2339 (1978). Next, Polymerizable Compounds (I-5) and (I-6) were synthesized by allowing 1,4-dithianyl methanol as described in J. Am. Chem. Soc., Volume 71, page 1582 (1949) to react with methacrylic acid and acrylic acid, respectively in the presence of a base.

Polymerizable Compound (I-1): FAB-MS (M-H)⁺=347

Polymerizable Compound (I-2): FAB-MS (M-H)⁺=377

Polymerizable Compound (I-3): FAB-MS (M-H)⁺=333

Polymerizable Compound (I-4): FAB-MS (M-H)⁺=363

Polymerizable Compound (I-5): FAB-MS (M-H)⁺=217

Polymerizable Compound (I-6): FAB-MS (M-H)⁺=203

With respect to the Resins (2) to (14), composition ratios (molar ratios corresponding to the respective repeating units in the order from the left side), weight average molecular weights and degrees of dispersion are shown in the following Table 2.

TABLE 2

| Resin | Composition ratio (molar ratio) | Mw | Mw/Mn |
|---|---|---|---|
| 1 | 40/15/40/5 | 8600 | 1.8 |
| 2 | 40/15/40/5 | 8700 | 1.8 |
| 3 | 40/15/40/5 | 6700 | 1.9 |
| 4 | 40/15/40/5 | 7300 | 1.8 |
| 5 | 40/15/40/5 | 6800 | 1.9 |
| 6 | 40/20/35/5 | 7500 | 1.9 |
| 7 | 40/10/40/40 | 11300 | 2.0 |
| 8 | 50/15/30/5 | 6700 | 2.1 |
| 9 | 50/15/30/5 | 6400 | 1.9 |
| 10 | 40/15/40/5 | 9200 | 1.8 |
| 11 | 40/15/40/5 | 7500 | 1.7 |
| 12 | 40/15/40/5 | 8300 | 1.9 |
| 13 | 40/15/40/5 | 6900 | 1.7 |
| 14 | 40/15/40/5 | 7200 | 1.9 |

### Examples 1 to 14 and Comparative Examples 1 to 2

### Resist Preparation

Components as shown in the following Table 3 were dissolved in a solvent to prepare a solution having a solids concentration of 6% by mass, which was then filtered through a 0.1-μm polyethylene filter to prepare a positive working resist solution. The prepared positive working resist composition was evaluated in the following method, and the results are shown in Table 3.

<Image Performance Test>

Exposure Condition (1)

An organic antireflection film, ARC29A (manufactured by Nissan Chemical Industries, Ltd.) was coated on a silicon wafer and baked at 205° C. for 60 seconds to form a 78 nm-thick antireflection film. The prepared positive working resist composition was coated thereon and baked at 130° C. for 60 seconds to form a 250 nm-thick resist film. The obtained wafer was pattern exposed by using an ArF excimer laser scanner (PAS 5500/1100, manufactured by ASML, NA: 0.75, σo/σi=0.85/0.55). Thereafter, the resulting wafer was heated at 130° C. for 60 seconds, developed with a tetramethylammonium hydroxide aqueous solution (2.38% by mass) for 30 seconds, rinsed with pure water and then spin dried to obtain a resist pattern.

Exposure Condition (2)

This condition is one for forming a resist pattern by a liquid immersion exposure method using pure water.

An organic antireflection film, ARC29A (manufactured by Nissan Chemical Industries, Ltd.) was coated on a silicon wafer and baked at 205° C. for 60 seconds to form a 78 nm-thick antireflection film. The prepared positive working resist composition was coated thereon and baked at 130° C. for 60 seconds to form a 250 nm-thick resist film. The obtained wafer was pattern exposed by using an ArF excimer laser liquid immersion scanner (NA: 0.85). Extrapure water was used as the liquid immersion liquid. Thereafter, the resulting wafer was heated at 130° C. for 60 seconds, developed with a tetramethylammonium hydroxide aqueous solution (2.38% by mass) for 30 seconds, rinsed with pure water and then spin dried to obtain a resist pattern.

In the exposure condition (1) and exposure condition (2), the obtained resist patterns were evaluated with respect to the line edge roughness.

Evaluation Method of Line Edge Roughness:

With respect to the measurement of line edge roughness, a line-and-space of 80 nm (1/1) was observed by using a metrological scanning electron microscope (SEM); and a distance of an edge in the longitudinal direction of a line pattern within a range of 2 μm from a standard line where the edge should be localized was measured at 10 points by using a metrological SEM (S-8840, manufactured by Hitachi, Ltd.), to determine a standard deviation, from which was then calculated 3σ. The smaller the value, the better the performance is.

TABLE 3

| | | Acid | | Basic | | | |
|---|---|---|---|---|---|---|---|
| | Resin | generator | Solvent | compound | Surfactant | Exposure | LWR |
| | (2 g) | (0.3 mg) | (mass ratio) | (4 mg) | (5 mg) | condition | (nm) |
| Example | | | | | | | |
| 1 | 1 | Z2 | S1/S5 = 80/20 | DIA | W1 | 1 | 4.8 |
| 2 | 2 | Z2 | S1/S5 = 80/20 | DIA | W1 | 1 | 5.2 |
| 3 | 3 | Z2 | S1/S5 = 80/20 | DIA | W2 | 1 | 5.4 |
| 4 | 4 | Z2 | S1/S5 = 80/20 | DIA | W2 | 2 | 4.9 |
| 5 | 5 | Z3 | S2/S5 = 80/20 | TMEA | W3 | 1 | 5.3 |
| 6 | 6 | Z3 | S2/S5 = 80/20 | TMEA | W3 | 1 | 5.5 |
| 7 | 7 | Z3 | S3/S5 = 80/20 | DIA | W4 | 1 | 4.9 |
| 8 | 8 | Z68 | S3/S5 = 80/20 | DIA | W4 | 2 | 5.2 |
| 9 | 9 | Z68 | S1/S5 = 80/20 | DIA | W5 | 1 | 5.6 |
| 10 | 10 | Z68 | S1/S5 = 80/20 | DIA | W5 | 1 | 5.3 |
| 11 | 11 | Z66 | S1/S5 = 80/20 | TMEA | W6 | 1 | 5.3 |
| 12 | 12 | Z66 | S1/S5 = 80/20 | TMEA | W6 | 2 | 5.4 |
| 13 | 13 | Z66 | S1/S5 = 80/20 | TMEA | W6 | 1 | 5.3 |
| 14 | 14 | Z66 | S1/S5 = 80/20 | TMEA | W6 | 1 | 5.3 |
| Comparative | | | | | | | |
| Example | | | | | | | |
| 1 | Q1 | Z2 | S1/S5 = 80/20 | DIA | W1 | 1 | 6.4 |
| 2 | Q2 | Z2 | S1/S5 = 80/20 | DIA | W2 | 2 | 6.3 |

The abbreviations in Table 3 are hereunder described.
[Basic compound]
DIA: 2,6-Diisopropylaniline
TMEA: Tris(methoxyethoxyethyl)amine
[Surfactant]
W1: MEGAFAC F176 (manufactured by Dainippon Ink and Chemicals, Incorporated) (fluorine based surfactant)
W2: MEGAFAC R08 (manufactured by Dainippon Ink and Chemicals, Incorporated) (fluorine and silicon based surfactant)
W3: Polysiloxane polymer, KP-341 (manufactured by Shin-Etsu Chemical Co., Ltd.) (silicon based surfactant)
W4: TROYSOL S-366 (manufactured by Troy Chemical Corporation) (silicon based surfactant)
W5: PF656 (manufactured by OMNOVA Solutions Inc.) (fluorine based surfactant)
W6: PF6320 (manufactured by OMNOVA Solutions Inc.) (fluorine based surfactant)
[Solvent]
S1: Propylene glycol methyl ether acetate
S2: 2-Heptanone
S3: Cyclohexanone
S4: γ-Butyrolactone
S5: Propylene glycol methyl ether
S6: Ethyl lactate
S7: Propylene carbonate

[Comparative Resin]

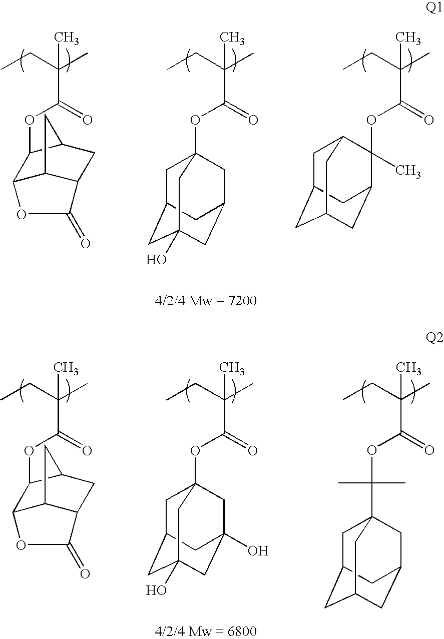

It is clear from Table 3 that the positive working photosensitive composition of the invention is excellent with respect to the line edge roughness in the usual exposure and liquid immersion exposure.

According to the invention, a positive working photosensitive composition having improved line edge roughness in the formation of a fine pattern of not more than 100 nm and a pattern forming method using the same can be provided. Also, since a resist film with high refractive index can be formed, a positive working photosensitive composition which is especially suitable for the liquid immersion exposure and a pattern forming method using the same can be provided.

The entire disclosure of each and every foreign patent application from which the benefit of foreign priority has been claimed in the present application is incorporated herein by reference, as if fully set forth.

What is claimed is:

1. A positive working photosensitive composition comprising:
(A) a resin having a heterocyclic group containing plural sulfur atoms in a cyclic structure of the heterocyclic group, the resin decomposing by action of an acid to increase its solubility in an alkaline developer; and
(B) a compound capable of generating an acid upon irradiation with actinic rays or radiation.

2. The positive working photosensitive composition according to claim 1,
wherein the heterocyclic group is a polycyclic heterocyclic group.

3. The positive working photosensitive composition according to claim 2,
wherein the resin (A) has at least one repeating unit selected from a repeating unit represented by general formula (I) and a repeating unit represented by general formula (II): 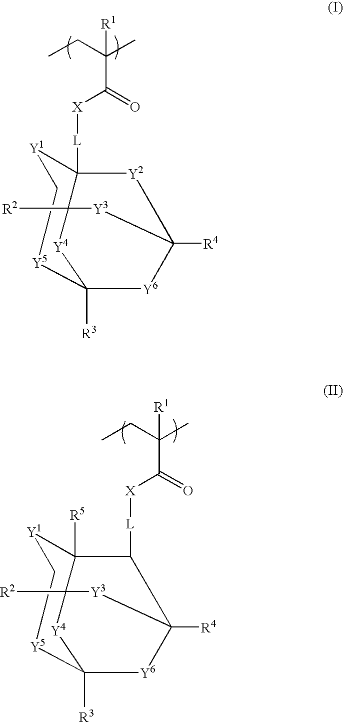
wherein
X represents an oxygen atom or a sulfur atom,
L represents a single bond or a divalent connecting group,
Y¹ to Y⁶ each independently represents —CH₂—, —CH(R⁶)—, —C(R⁶)₂—, an oxygen atom or a sulfur atom, provided that at least two of Y¹ to Y⁶ represent a sulfur atom,
R¹ represents a hydrogen atom, an alkyl group or a halogen atom,
R² to R⁵ each independently represents a hydrogen atom or an alkyl group, and
R⁶ represents an alkyl group.

4. A pattern forming method comprising:
forming a photosensitive film by the positive working photosensitive composition according to claim 1; and
exposing and developing the photosensitive film.
